(19) United States
(12) Patent Application Publication
(10) Pub. No.: US 2025/0299705 A1
(43) Pub. Date: Sep. 25, 2025

(54) SEMICONDUCTOR MEMORY DEVICE

(71) Applicant: Kioxia Corporation, Tokyo (JP)

(72) Inventors: Mamoru JOKO, Yokohama (JP); Kazuma KOHDA, Yokkaichi (JP)

(73) Assignee: Kioxia Corporation, Tokyo (JP)

(21) Appl. No.: 19/055,711

(22) Filed: Feb. 18, 2025

(30) Foreign Application Priority Data
Mar. 22, 2024 (JP) 2024-046480

(51) Int. Cl. G11C 5/06; G11C 16/04; H10B 43/10; H10B 43/20; H10B 43/35

(52) U.S. Cl. CPC G11C 5/063; G11C 16/0483; H10B 43/10; H10B 43/20; H10B 43/35

(57) ABSTRACT

In general, according to one embodiment, a semiconductor memory device includes: a plurality of second and third interconnect layers apart from each other in a first direction, wherein each of the second interconnect layers includes a plurality of first terrace portions, each of the third interconnect layers includes a plurality of second terrace portions overlapping the first terrace portions in the first direction, the second terrace portions include a plurality of third and fourth terrace portions provided at a same interconnect layer of the third interconnect layers are electrically insulated from each other; and a first contact passes through one of the fourth terrace portions, and is electrically coupled to one of the first terrace portions, wherein each of the third and fourth terrace portions is thicker in the first direction than a portion of the third interconnect layers where the third or fourth terrace portions are not provided.

### CROSS-REFERENCE TO RELATED APPLICATIONS

This application is based upon and claims the benefit of priority from Japanese Patent Application No. 2024-046480, filed Mar. 22, 2024, the entire contents of which are incorporated herein by reference.

### FIELD

Embodiments described herein relate generally to a semiconductor memory device.

### BACKGROUND

A NAND flash memory is known as a semiconductor memory device that can store data in a non-volatile manner. In the NAND flash memory, a three-dimensional memory structure may be adopted for increasing the level of integration and capacity.

### BRIEF DESCRIPTION OF DRAWINGS

FIG. 1 is a block diagram illustrating an example of a configuration of a memory system according to a first embodiment.

FIG. 2 is a circuit diagram illustrating an example of a circuit configuration of a memory cell array included in a semiconductor memory device according to the first embodiment.

FIG. 3 is a plan view illustrating an example of a planar layout of the memory cell array included in the semiconductor memory device according to the first embodiment.

FIG. 4 is a plan view illustrating an example of a planar layout in a memory area of the memory cell array included in the semiconductor memory device according to the first embodiment.

FIG. 5 is a sectional view taken along line V-V in FIG. 4, illustrating an example of a sectional structure in the memory area of the memory cell array included in the semiconductor memory device according to the first embodiment.

FIG. 6 is a sectional view taken along line VI-VI in FIG. 5, illustrating an example of a sectional structure of a memory pillar included in the semiconductor memory device according to the first embodiment.

FIG. 7 is a schematic view schematically illustrating an example of a sectional structure of a stacked interconnect in a hookup area of the memory cell array included in the semiconductor memory device according to the first embodiment.

FIG. 8 is a sectional view illustrating an example of a sectional structure in the hookup area of the memory cell array included in the semiconductor memory device according to the first embodiment.

FIG. 9 is an enlarged view of area IX in FIG. 8, illustrating an example of a sectional structure in the hookup area of the memory cell array included in the semiconductor memory device according to the first embodiment.

FIG. 10 is a plan view illustrating an example of a planar layout of an upper stacked interconnect in the hookup area of the memory cell array included in the semiconductor memory device according to the first embodiment.

FIG. 11 is a plan view illustrating an example of a plane taken along line XI-XI in FIG. 8 in the hookup area of the memory cell array included in the semiconductor memory device according to the first embodiment.

FIG. 12 is a flowchart illustrating an example of a manufacturing method of the hookup area of the memory cell array included in the semiconductor memory device according to the first embodiment.

FIG. 13 is a sectional view illustrating an example of a sectional structure in the hookup area of the memory cell array included in the semiconductor memory device according to the first embodiment in the middle of manufacturing.

FIG. 14 is a sectional view illustrating an example of a sectional structure in the hookup area of the memory cell array included in the semiconductor memory device according to the first embodiment in the middle of manufacturing.

FIG. 15 is a sectional view illustrating an example of a sectional structure in the hookup area of the memory cell array included in the semiconductor memory device according to the first embodiment in the middle of manufacturing.

FIG. 16 is a sectional view illustrating an example of a sectional structure in the hookup area of the memory cell array included in the semiconductor memory device according to the first embodiment in the middle of manufacturing.

FIG. 17 is a sectional view illustrating an example of a sectional structure in the hookup area of the memory cell array included in the semiconductor memory device according to the first embodiment in the middle of manufacturing.

FIG. 18 is a sectional view illustrating an example of a sectional structure in the hookup area of the memory cell array included in the semiconductor memory device according to the first embodiment in the middle of manufacturing.

FIG. 19 is a sectional view illustrating an example of a sectional structure in the hookup area of the memory cell array included in the semiconductor memory device according to the first embodiment in the middle of manufacturing.

FIG. 20 is a sectional view illustrating an example of a sectional structure in the hookup area of the memory cell array included in the semiconductor memory device according to the first embodiment in the middle of manufacturing.

FIG. 21 is a sectional view illustrating an example of a sectional structure in the hookup area of the memory cell array included in the semiconductor memory device according to the first embodiment in the middle of manufacturing.

FIG. 22 is a sectional view illustrating an example of a sectional structure in the hookup area of the memory cell array included in the semiconductor memory device according to the first embodiment in the middle of manufacturing.

FIG. 23 is a plan view illustrating an example of a planar layout in the hookup area of the memory cell array included in the semiconductor memory device according to the first embodiment in the middle of manufacturing.

FIG. 24 is a sectional view illustrating an example of a sectional structure in the hookup area of the memory cell array included in the semiconductor memory device according to the first embodiment in the middle of manufacturing.

FIG. 25 is a plan view illustrating an example of a planar layout in the hookup area of the memory cell array included in the semiconductor memory device according to the first embodiment in the middle of manufacturing.

FIG. 26 is a sectional view illustrating an example of a sectional structure in the hookup area of the memory cell array included in the semiconductor memory device according to the first embodiment in the middle of manufacturing.

FIG. 27 is a sectional view illustrating an example of a sectional structure in the hookup area of the memory cell array included in the semiconductor memory device according to a first modification of the first embodiment.

FIG. 28 is a sectional view illustrating an example of a sectional structure in the hookup area of the memory cell array included in the semiconductor memory device according to a second modification of the first embodiment.

FIG. 29 is a schematic view schematically illustrating an example of a sectional structure of the stacked interconnect in the hookup area of the memory cell array included in the semiconductor memory device according to a third modification of the first embodiment.

FIG. 30 is a plan view illustrating an example of a planar layout of the upper stacked interconnect in the hookup area of the memory cell array included in the semiconductor memory device according to a fourth modification of the first embodiment.

FIG. 31 is a plan view illustrating an example of a planar layout in a memory area of a memory cell array included in a semiconductor memory device according to a second embodiment.

FIG. 32 is a schematic view schematically illustrating an example of a sectional structure of a stacked interconnect in a hookup area of the memory cell array included in the semiconductor memory device according to the second embodiment.

FIG. 33 is a sectional view illustrating an example of a sectional structure in the hookup area of the memory cell array included in the semiconductor memory device according to the second embodiment.

FIG. 34 is an enlarged view of area XXXIV in FIG. 33, illustrating an example of a sectional structure in the hookup area of the memory cell array included in the semiconductor memory device according to the second embodiment.

FIG. 35 is a plan view illustrating an example of a planar layout of an upper stacked interconnect in the hookup area of the memory cell array included in the semiconductor memory device according to the second embodiment.

FIG. 36 is a plan view illustrating an example of a planar layout of a lower stacked interconnect in the hookup area of the memory cell array included in the semiconductor memory device according to the second embodiment.

FIG. 37 is a plan view illustrating an example of a plane taken along line XXXVII-XXXVII in FIG. 33 in the hookup area of the memory cell array included in the semiconductor memory device according to the second embodiment.

FIG. 38 is a sectional view illustrating an example of a sectional structure in the hookup area of the memory cell array included in the semiconductor memory device according to the second embodiment in the middle of manufacturing.

FIG. 39 is a sectional view illustrating an example of a sectional structure in the hookup area of the memory cell array included in the semiconductor memory device according to the second embodiment in the middle of manufacturing.

FIG. 40 is a sectional view illustrating an example of a sectional structure in the hookup area of the memory cell array included in the semiconductor memory device according to the second embodiment in the middle of manufacturing.

FIG. 41 is a sectional view illustrating an example of a sectional structure in the hookup area of the memory cell array included in the semiconductor memory device according to the second embodiment in the middle of manufacturing.

FIG. 42 is a sectional view illustrating an example of a sectional structure in the hookup area of the memory cell array included in the semiconductor memory device according to the second embodiment in the middle of manufacturing.

FIG. 43 is a sectional view illustrating an example of a sectional structure in the hookup area of the memory cell array included in the semiconductor memory device according to the second embodiment in the middle of manufacturing.

FIG. 44 is a sectional view illustrating an example of a sectional structure in the hookup area of the memory cell array included in the semiconductor memory device according to the second embodiment in the middle of manufacturing.

FIG. 45 is a sectional view illustrating an example of a sectional structure in the hookup area of the memory cell array included in the semiconductor memory device according to the second embodiment in the middle of manufacturing.

FIG. 46 is a plan view illustrating an example of a planar layout of the upper stacked interconnect in the hookup area of the memory cell array included in the semiconductor memory device according to a first modification of the second embodiment.

FIG. 47 is a plan view illustrating an example of a planar layout of the upper stacked interconnect in the hookup area of the memory cell array included in the semiconductor memory device according to a second modification of the second embodiment.

FIG. 48 is a schematic view schematically illustrating an example of a sectional structure of the stacked interconnect in the hookup area of the memory cell array included in the semiconductor memory device according to a third modification of the second embodiment.

FIG. 49 is a plan view illustrating an example of a planar layout of the upper stacked interconnect in the hookup area of the memory cell array included in the semiconductor memory device according to a fourth modification of the second embodiment.

FIG. 50 is a sectional view illustrating an example of a sectional structure in the hookup area of the memory cell array included in the semiconductor memory device according to a fifth modification of the first embodiment.

### DETAILED DESCRIPTION

In general, according to one embodiment, a semiconductor memory device includes: a first interconnect layer; a plurality of second interconnect layers that are provided above the first interconnect layer and apart from each other in a first direction, wherein the second interconnect layers are provided over a first area and a second area that are arranged in a second direction intersecting the first direction as viewed in the first direction, and each of the second interconnect layers includes a plurality of first terrace portions that are provided not overlapping any of the second interconnect layers at a respective upper layer in the first direction in the first area; a plurality of third interconnect layers that are provided above the second interconnect layers and apart from each other in the first direction, wherein the third interconnect layers are provided over the first area and the second area, each of the third interconnect layers includes a plurality of second terrace portions that are provided not overlapping any of the third interconnect layers at a respective upper layer in the first direction in the first area and a part of which is provided overlapping the first terrace portions in the first direction, each of the second terrace portions includes a plurality of third terrace portions that are provided descending in a direction away from the second area in the second direction in a first stepped area, and a plurality of fourth terrace portions that are provided ascending in the direction away from the second area in the second direction in a second stepped area, and each of the third terrace portions and each of the fourth terrace portions that are provided at a same interconnect layer of the third interconnect layers are electrically insulated from each other; a first memory pillar that extends in the first direction in the second area, includes an end in contact with the first interconnect layer, and passes through the second interconnect layers and the third interconnect layers; and a first contact that extends in the first direction in the first area, passes through one of the fourth terrace portions, and is electrically coupled to one of the first terrace portions, wherein each of the third terrace portions and the fourth terrace portions is thicker in the first direction than a portion of the third interconnect layers where the third terrace portions or the fourth terrace portions are not provided. Hereinafter, embodiments will be described with reference to the drawings. The drawings are schematic, and dimensions and ratios of the drawings are not necessarily the same as actual ones. In the following description, constituent elements having substantially the same function and configuration are denoted by the same reference numerals or signs. In a case where elements having similar configurations are particularly distinguished from each other, different characters or numbers may be added to the end of the same reference numerals or signs.

In the following description, a first element being “coupled” to a different second element encompasses the first element being coupled to the second element indirectly through the intervention of an intermediate element that is conductive constantly or selectively, or directly without any intervention of such an intermediate element.

### 1. First Embodiment

### 1.1 Configurations

### 1.1.1 Memory System

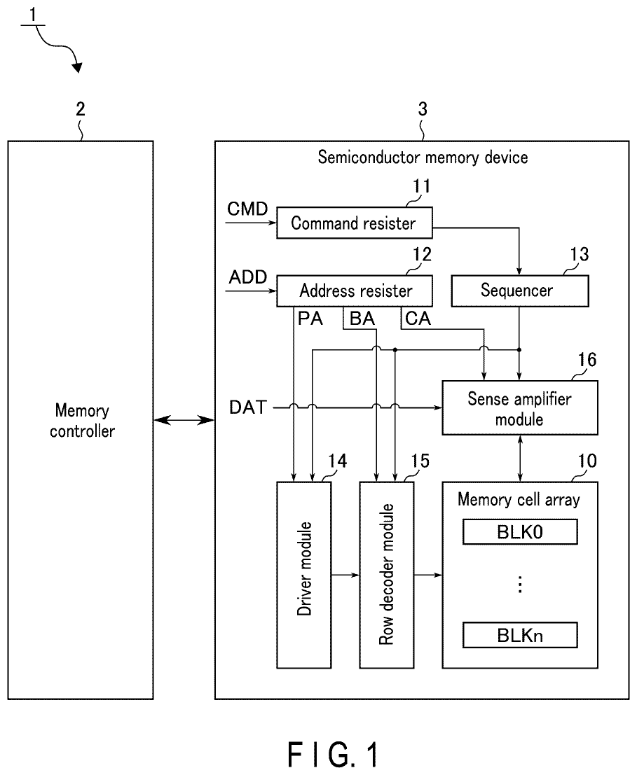

A semiconductor memory device according to a first embodiment will be described. FIG. 1 is a block diagram illustrating an example of a configuration of a memory system 1 according to the first embodiment. The memory system 1 is a memory device configured to be coupled to an external host device (not illustrated). The memory system 1 is, for example, a memory card such as an SD™ card, a universal flash storage (UFS), or a solid state drive (SSD). The memory system 1 includes a memory controller 2 and a semiconductor memory device 3.

The memory controller 2 includes, for example, an integrated circuit such as a system on a chip (SoC). The memory controller 2 controls the semiconductor memory device 3 based on a request from an external host device. Specifically, the memory controller 2 writes data requested to be written by an external host device to the semiconductor memory device 3. The memory controller 2 reads, from the semiconductor memory device 3, data requested to be read by an external host device and outputs the data to the external host device.

The semiconductor memory device 3 is, for example, a NAND flash memory that can store data in a non-volatile manner.

Communication between the memory controller 2 and the semiconductor memory device 3 conforms to, for example, a single data rate (SDR) interface, a toggle double data rate (DDR) interface, or an open NAND flash interface (ONFI).

### 1.1.2 Semiconductor Memory Device

Subsequently, an internal configuration of the semiconductor memory device 3 according to the first embodiment will be described with reference to the block diagram provided in FIG. 1. The semiconductor memory device 3 includes, for example, a memory cell array 10, a command register 11, an address register 12, a sequencer 13, a driver module 14, a row decoder module 15, and a sense amplifier module 16.

The memory cell array 10 is an aggregate of a set of memory cell transistors and constituent elements coupled to the memory cell transistors. The memory cell array 10 includes a plurality of blocks BLK0 to BLKn (n is an integer of 1 or more). The block BLK is an aggregate of a plurality of memory cell transistors that can store data in a non-volatile manner. The block BLK is used as, for example, an erase unit at the time of erasing data stored in the memory cell transistor. The memory cell array 10 includes a plurality of bit lines and a plurality of word lines. Each memory cell transistor is associated with, for example, a combination of one bit line and one word line. A detailed configuration of the memory cell array 10 will be described later.

The command register 11 stores a command CMD received by the semiconductor memory device 3 from the memory controller 2. The command CMD includes, for example, an order for causing the sequencer 13 to execute a read operation, a write operation, an erase operation, and the like.

The address register 12 stores address information ADD received by the semiconductor memory device 3 from the memory controller 2. The address information ADD includes, for example, a block address BA, a page address PA, and a column address CA. For example, the block address BA, the page address PA, and the column address CA are used to select the block BLK, the word line, and the bit line, respectively.

The sequencer 13 controls the operation of the whole semiconductor memory device 3. For example, the sequencer 13 controls the driver module 14, the row decoder module 15, the sense amplifier module 16, and the like based on the command CMD stored in the command register 11 and executes a read operation, a write operation, an erase operation, and the like.

The driver module 14 generates a plurality of voltages that have different magnitudes and are used in a read operation, a write operation, an erase operation, and the like. The driver module 14 applies the generated voltage to, for example, the signal line corresponding to the word line selected based on the page address PA stored in the address register 12.

The row decoder module 15 selects the corresponding one block BLK in the memory cell array 10 based on the block address BA stored in the address register 12. The row decoder module 15 transfers, for example, the voltage of the signal line applied by the driver module 14 to the selected word line in the selected block BLK.

In the write operation, the sense amplifier module 16 applies a desired voltage to each bit line in accordance with write data DAT received from the memory controller 2. In addition, in the read operation, the sense amplifier module 16 determines the data stored in the memory cell transistor based on the magnitude of the voltage of the bit line. Then, the determination result is transferred to the memory controller 2 as read data DAT.

### 1.1.3 Circuit Configuration of Memory Cell Array

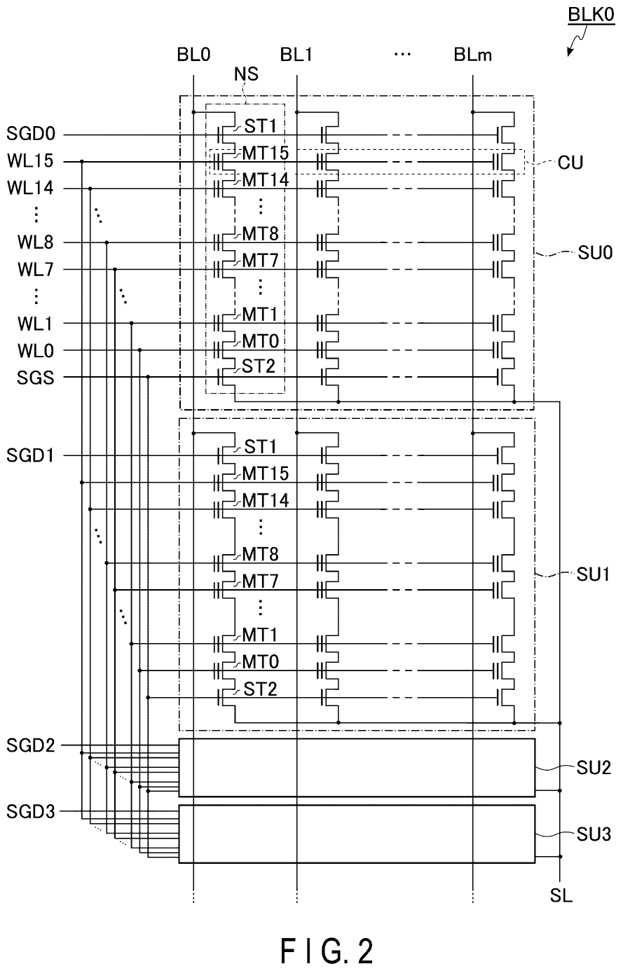

FIG. 2 is a circuit diagram illustrating an example of a circuit configuration of the memory cell array 10 included in the semiconductor memory device 3 according to the first embodiment. FIG. 2 illustrates a block BLK0. The block BLK0 includes, for example, four string units SU0 to SU3.

Each string unit SU includes a plurality of NAND strings NS respectively associated with bit lines BL0 to BLm (m is an integer of 1 or more). Each NAND string NS includes, for example, 16 memory cell transistors MT0 to MT15 and select transistors ST1 and ST2. Each memory cell transistor MT includes a control gate and a charge storage film and stores data in a non-volatile manner based on the amount of charges in the charge storage film. Each of the select transistors ST1 and ST2 is used to select the string unit SU during various operations.

In each NAND string NS, the memory cell transistors MT0 to MT15 are coupled in series in this order. The drain of the select transistor ST1 is coupled to the associated bit line BL, and the source of the select transistor ST1 is coupled to the drain of the memory cell transistor MT15. The drain of the select transistor ST2 is coupled to the source of the memory cell transistor MT0, and the source of the select transistor ST2 is coupled to a source line SL.

The control gates of the memory cell transistors MT0 to MT15 in the same block BLK are coupled to word lines WL0 to WL15, respectively. Gates of the select transistors ST1 in the string units SU0 to SU3 are coupled to select gate lines SGD0 to SGD3, respectively. Gates of the select transistors ST2 in the same block BLK are coupled to a select gate line SGS.

Different column addresses CA are allocated to the bit lines BL0 to BLm. Each bit line BL is shared by the NAND string NS to which the same column address CA is allocated among the plurality of blocks BLK. Each of the word lines WL0 to WL15 is provided for each block BLK. The source line SL is shared among the plurality of blocks BLK, for example.

An aggregate of a plurality of the memory cell transistors MT coupled to the common word line WL in one string unit SU is referred to as, for example, a cell unit CU. For example, the memory capacity of the cell unit CU including the memory cell transistors MT each storing 1-bit data is defined as “one-page data”. The cell unit CU may have a memory capacity of two-page data or more in accordance with the number of bits of data stored in the memory cell transistor MT.

Note that the circuit configuration of the memory cell array 10 included in the semiconductor memory device 3 according to the first embodiment is not limited to the above description. For example, the number of the string units SU included in each block BLK can be designed to be any number. The number of the memory cell transistors MT and the select transistors ST1 and ST2 included in each NAND string NS can be designed to be any number.

### 1.1.4 Structure of Memory Cell Array

Hereinafter, an example of a structure of the memory cell array 10 included in the semiconductor memory device 3 according to the first embodiment will be described. In the drawings referred to below, a three-dimensional orthogonal coordinate system is used. An X direction corresponds to the extending direction of the word line WL. A Y direction corresponds to the extending direction of the bit line BL. A Z direction corresponds to the vertical direction with respect to the surface of a semiconductor substrate 20 used for forming the semiconductor memory device 3. The Z direction toward a side on which a semiconductor circuit is formed as viewed from the semiconductor substrate 20 is defined as an upward direction, and a direction opposite to the upward direction is defined as a downward direction. In the plan view, hatching is added as necessary in order to enhance the visibility of the drawing. The hatching added to the plan view is not necessarily related to the material or characteristics of the constituent element to which hatching is added. In the sectional view, illustration of the configuration is omitted as necessary in order to enhance the visibility of the drawing.

### 1.1.4.1 Outline of Planar Layout

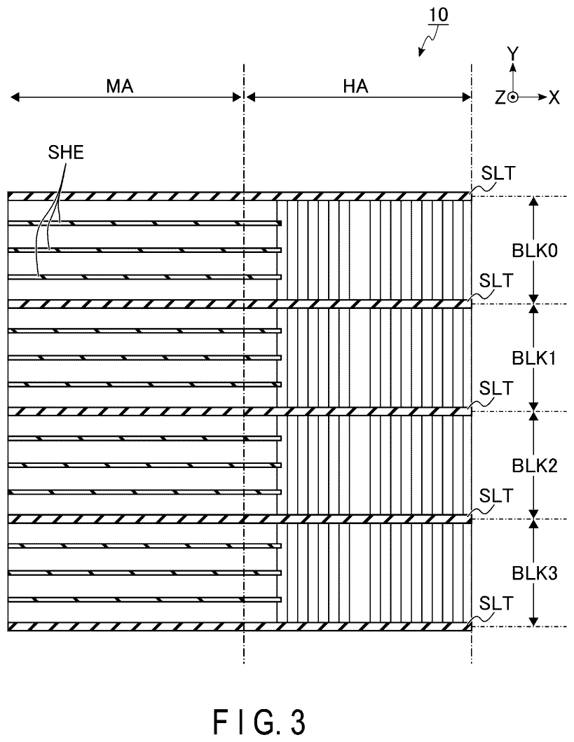

FIG. 3 is a plan view illustrating an example of a planar layout of the memory cell array 10 included in the semiconductor memory device 3 according to the first embodiment. FIG. 3 illustrates areas corresponding to four blocks BLK0 to BLK3. The sequence numbers at the ends for distinguishing the blocks BLK are assigned in ascending order from the upper side of the page. In the memory cell array 10, for example, the layout illustrated in FIG. 3 is repeatedly disposed in the Y direction. As illustrated in FIG. 3, the memory cell array 10 includes a plurality of members SLT and a plurality of members SHE. The planar layout of the memory cell array 10 is divided into, for example, a memory area MA and a hookup area HA in the X direction.

The memory area MA is an area that includes a plurality of the NAND strings NS. The hookup area HA is an area used for coupling between the row decoder module 15 and a stacked interconnect formed by stacking a plurality of interconnect layers (e.g., the word lines WL0 to WL15 and the select gate lines SGS and SGD) apart from each other in the Z direction.

The plurality of members SLT each extend along the X direction and are arranged in the Y direction. Each member SLT crosses the memory area MA and the hookup area HA in the X direction in the boundary area between the adjacent blocks BLK. In other words, each of the areas partitioned by the member SLT corresponds to one block BLK in the memory cell array 10. Each member SLT has, for example, a structure filled with an insulator and a plate-shaped contact. Each member SLT divides the stacked interconnects adjacent to each other with the member SLT interposed therebetween.

The plurality of members SHE are disposed in the memory area MA and a part of the hookup area HA. The plurality of members SHE are each provided to cross the memory area MA in the X direction and are arranged in the Y direction. The end portion on the right side of the page of each member SHE is included in the hookup area HA. For example, three members SHE are disposed for each space between the members SLT adjacent to each other in the Y direction. Each of the areas partitioned by the members SLT and SHE of the memory area MA corresponds to one string unit SU in the memory cell array 10. Each member SHE has, for example, a structure filled with an insulator. Each member SHE divides the adjacent select gate lines SGD with the member SHE interposed therebetween.

Note that the planar layout of the memory cell array 10 included in the semiconductor memory device 3 according to the first embodiment is not limited to the layout described above. For example, the number of the members SHE disposed between the adjacent members SLT can be designed to be any number. The number of the string units SU formed between the adjacent members SLT can be changed based on the number of the members SHE disposed between the adjacent members SLT.

### 1.1.4.2 Memory Area

### (Planar Layout)

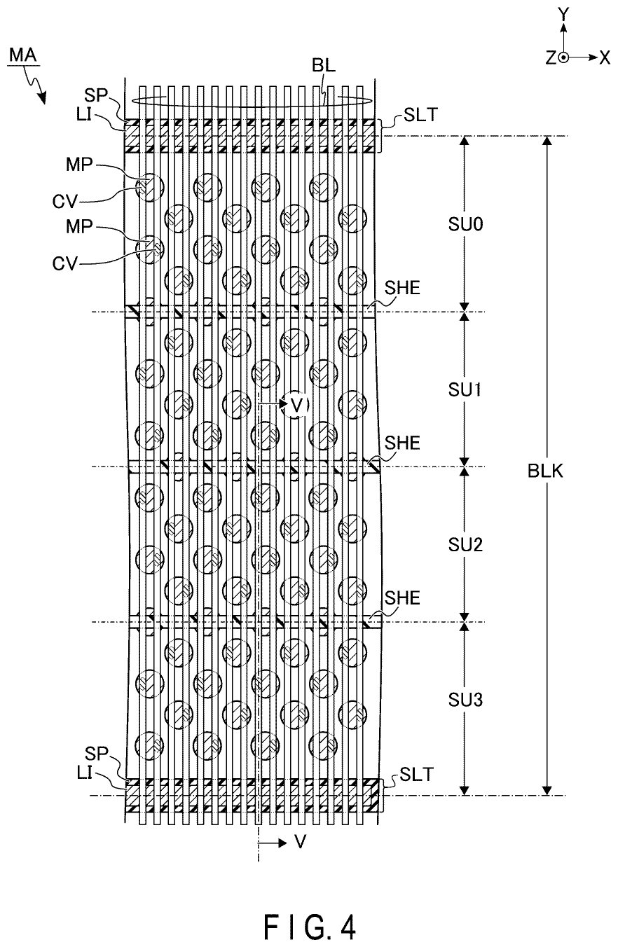

FIG. 4 is a plan view illustrating an example of a planar layout in the memory area MA of the memory cell array 10 included in the semiconductor memory device 3 according to the first embodiment. As illustrated in FIG. 4, in the memory area MA, the memory cell array 10 includes a plurality of memory pillars MP, a plurality of contacts CV, and a plurality of the bit lines BL. Each member SLT includes a contact LI and a spacer SP.

Each memory pillar MP functions as, for example, one NAND string NS. The plurality of memory pillars MP are disposed in such a staggered manner as to have, for example, 19 rows in the Y direction in an area between two adjacent members SLT. In the example illustrated in FIG. 4, one member SHE overlaps each memory pillar MP of the fifth row, the tenth row, and the 15th row as counted from the upper side of the page.

The plurality of bit lines BL each extend in the Y direction and are arranged in the X direction. Each bit line BL is disposed so as to overlap at least one memory pillar MP for each string unit SU. In the example illustrated in FIG. 4, two bit lines BL are disposed so as to overlap one memory pillar MP. In the case where the plurality of bit lines BL overlap the memory pillar MP, one bit line BL among the plurality of bit lines BL and the corresponding one memory pillar MP are electrically coupled via the contact CV. Note that, in the case where only one bit line BL overlaps the memory pillar MP, the relevant bit line BL and the corresponding one memory pillar MP are electrically coupled via the contact CV.

For example, the contact CV between the memory pillar MP in contact with the member SHE and the corresponding bit line BL is omitted. In other words, the contact CV between the memory pillar MP in contact with different two of the select gate lines SGD and the bit line BL is omitted. Neither the number nor arrangement of the memory pillars MP, the members SHE, or the like between the adjacent members SLT is limited to the configuration illustrated in FIG. 4 and these can be suitably changed. For example, the number of the bit lines BL overlapping each memory pillar MP can be designed to be any number.

The contact LI is a conductor extending in an XZ plane. The lower surface of the contact LI is in contact with the source line SL (not illustrated). The spacer SP is an insulator provided on a side surface of the contact LI. In other words, the spacer SP is provided in contact with the contact LI so as to sandwich the contact LI in the Y direction.

### (Sectional Structure)

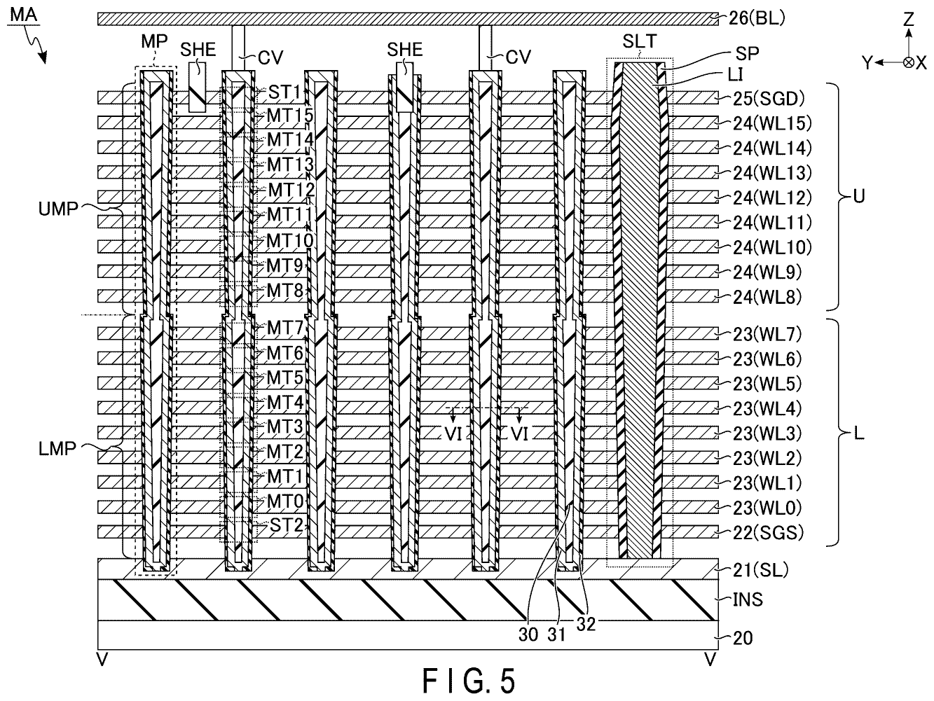

FIG. 5 is a sectional view taken along line V-V in FIG. 4, illustrating an example of a sectional structure in the memory area MA of the memory cell array 10 included in the semiconductor memory device 3 according to the first embodiment. As illustrated in FIG. 5, the memory cell array 10 further includes interconnect layers 21 to 26.

The stacked interconnect included in the memory cell array 10 includes an upper stacked interconnect U and a lower stacked interconnect L. The lower stacked interconnect L includes the interconnect layer 22 corresponding to the select gate line SGS and a plurality of the interconnect layers 23 corresponding to the word lines WL0 to WL7. The upper stacked interconnect U includes the interconnect layers 24 corresponding to the word lines WL8 to WL15 and the interconnect layer 25 corresponding to the select gate line SGD.

The interconnect layer 21 is provided above the semiconductor substrate 20 with an insulating layer INS interposed therebetween. The interconnect layer 21 is formed in, for example, a plate shape extending along the X direction on an XY plane. The interconnect layer 21 is used as the source line SL. The interconnect layer 21 contains, for example, phosphorus-doped silicon.

The interconnect layer 22 is provided above the interconnect layer 21 with an insulating layer (not illustrated) interposed therebetween. The interconnect layer 22 is formed in, for example, a plate shape extending along the X direction on the XY plane. The interconnect layer 22 is used as the select gate line SGS. The interconnect layer 22 contains, for example, tungsten.

A plurality of insulating layers (not illustrated) and a plurality of the interconnect layers 23 are alternately stacked one by one above the interconnect layer 22. Each of the interconnect layers 23 is formed in, for example, a plate shape extending along the X direction on the XY plane. The stacked interconnect layers 23 are used as the word lines WL0 to WL7 in order from the semiconductor substrate 20 side. Each of the interconnect layers 23 contains, for example, tungsten.

A plurality of insulating layers (not illustrated) and a plurality of the interconnect layers 24 are alternately stacked one by one above the uppermost interconnect layer 23. Each of the interconnect layers 24 is formed in, for example, a plate shape extending along the X direction on the XY plane. The stacked interconnect layers 24 are used as the word lines WL8 to WL15 in order from the semiconductor substrate 20 side. Each of the interconnect layers 24 contains, for example, tungsten.

The interconnect layer 25 is provided above the uppermost interconnect layer 24 with an insulating layer (not illustrated) interposed therebetween. The interconnect layer 25 is formed in, for example, a plate shape extending along the X direction on the XY plane. The interconnect layer 25 is used as the select gate line SGD. The interconnect layer 25 contains, for example, tungsten.

The plurality of interconnect layers 26 are provided above the interconnect layer 25 with an insulating layer interposed therebetween. Each of the interconnect layers 26 is formed in, for example, a line shape extending along the Y direction. Each of the interconnect layers 26 is used as the bit line BL. In an area (not illustrated), the plurality of interconnect layers 26 are arranged along the X direction. Each of the interconnect layers 26 contains, for example, copper.

Each memory pillar MP is provided extending along the Z direction. Each memory pillar MP includes an upper pillar UMP and a lower pillar LMP. The lower pillar LMP extends through the lower stacked interconnect L, that is, the interconnect layers 22 and 23 and the insulating layers provided between the interconnect layer 21 and the uppermost interconnect layers 23. The upper pillar UMP extends through the upper stacked interconnect U, that is, the interconnect layers 24 and 25 and the insulating layers provided between the interconnect layers 24 and the uppermost interconnect layer 25. The upper end of the lower pillar LMP and the lower end of the upper pillar UMP are in contact with each other at a position between the uppermost interconnect layer 23 and the lowermost interconnect layer 24. For example, each of the lower pillar LMP and the upper pillar UMP has a larger sectional area (XY sectional area) along the XY plane from the lower side to the upper side.

In addition, each memory pillar MP includes, for example, a core film 30, a semiconductor film 31, and a stacked film 32. The core film 30 is provided extending along the Z direction. For example, the upper end of the core film 30 is positioned at an upper layer with respect to the interconnect layer 25, and the lower end of the core film 30 is positioned in the interconnect layer 21. The core film 30 includes, for example, an insulator such as silicon oxide. The semiconductor film 31 covers the periphery of the core film 30, for example. At the lower end of the memory pillar MP, a part of the semiconductor film 31 is in contact with the interconnect layer 21. The semiconductor film 31 contains, for example, silicon. The stacked film 32 covers the side surface and the bottom surface of the semiconductor film 31 except for a portion where the semiconductor film 31 and the interconnect layer 21 are in contact with each other.

In the structure of the memory pillar MP illustrated in FIG. 5, a portion where the memory pillar MP and the interconnect layer 22 intersect each other functions as the select transistor ST2. Portions where the memory pillars MP and each of the interconnect layers 23 and 24 intersect each other function as the memory cell transistors MT0 to MT15, respectively. A portion where the memory pillar MP and the interconnect layer 25 intersect each other functions as the select transistor ST1.

The columnar contact CV is provided on the upper surface of the semiconductor film 31 in the memory pillar MP. In the area illustrated in FIG. 5, two contacts CV respectively corresponding to two memory pillars MP among six memory pillars MP are displayed. To the memory pillar MP that does not overlap the member SHE in this area and is not coupled to the contact CV, another contact CV is coupled in an area (not illustrated).

One interconnect layer 26, that is, one bit line BL is in contact with the upper surface of each contact CV. One contact CV is coupled to one interconnect layer 26 in each of the spaces partitioned by the members SLT and SHE. That is, for example, one memory pillar MP in each area between the adjacent members SLT and SHE and one memory pillar MP in a respective one area between adjacent two of the members SHE are electrically coupled to a respective one of the interconnect layers 26.

The member SLT is formed so as to extend along the XZ plane, for example, and divides the interconnect layers 22 to 25 and insulating layers (not illustrated) provided between the interconnect layer 21 and the interconnect layer 25.

In the member SLT, the contact LI is provided so as to extend along the XZ plane, and the spacer SP is provided between the contact LI and the interconnect layers 22 to 25. The upper end of the contact LI is positioned, for example, in an insulating layer (not illustrated) between the interconnect layer 25 and the interconnect layer 26. The lower end of the contact LI is in contact with, for example, the interconnect layer 21. Note that the contact LI may be omitted depending on the structure of the memory cell array 10.

The member SHE is formed in, for example, a plate shape extending along the XZ plane and divides the interconnect layer 25. The upper end of the member SHE is positioned, for example, in the insulating layer (not illustrated) between the interconnect layer 25 and the interconnect layer 26. The lower end of the member SHE is positioned, for example, in the insulating layer (not illustrated) between the uppermost interconnect layer 24 and the interconnect layer 25. The member SHE includes, for example, an insulator such as silicon oxide. Note that the upper end of the member SHE and the upper end of the member SLT may be aligned or may not be aligned. In addition, the upper end of the member SHE and the upper end of the memory pillar MP may be aligned or may not be aligned.

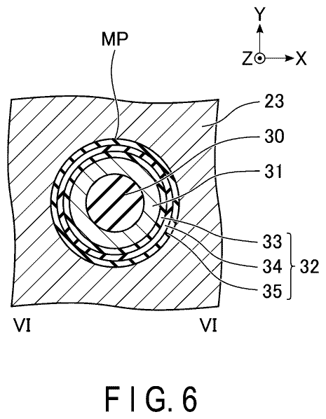

FIG. 6 is a sectional view taken along line VI-VI in FIG. 5, illustrating an example of a sectional structure of the memory pillar MP included in the semiconductor memory device 3 according to the first embodiment. More specifically, FIG. 6 illustrates a sectional structure of the memory pillar MP in a layer being parallel to the surface of the semiconductor substrate 20 and including the interconnect layer 23. As illustrated in FIG. 6, the stacked film 32 includes, for example, a tunnel insulating film 33, a charge storage film 34, and a block insulating film 35.

In the section including the interconnect layer 23, the core film 30 is provided, for example, at the central portion of the memory pillar MP. The semiconductor film 31 surrounds the side surface of the core film 30. The tunnel insulating film 33 surrounds the side surface of the semiconductor film 31. The charge storage film 34 surrounds the side surface of the tunnel insulating film 33. The block insulating film 35 surrounds the side surface of the charge storage film 34. The interconnect layer 23 surrounds the side surface of the block insulating film 35.

The semiconductor film 31 is used as a channel (current path) of the memory cell transistors MT0 to MT15 and the select transistors ST1 and ST2. Each of the tunnel insulating film 33 and the block insulating film 35 contains, for example, silicon oxide. The charge storage film 34 has a function of storing charges and contains, for example, silicon nitride. With this structure, each memory pillar MP can function as, for example, one NAND string NS.

### 1.1.4.3 Hookup Area

### (Sectional Structure)

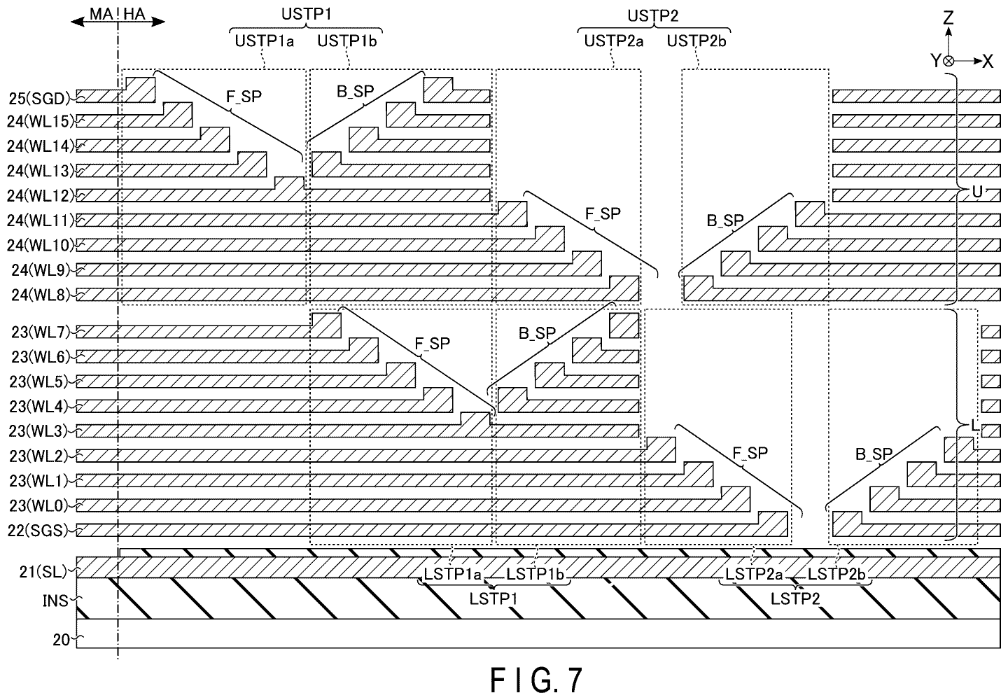

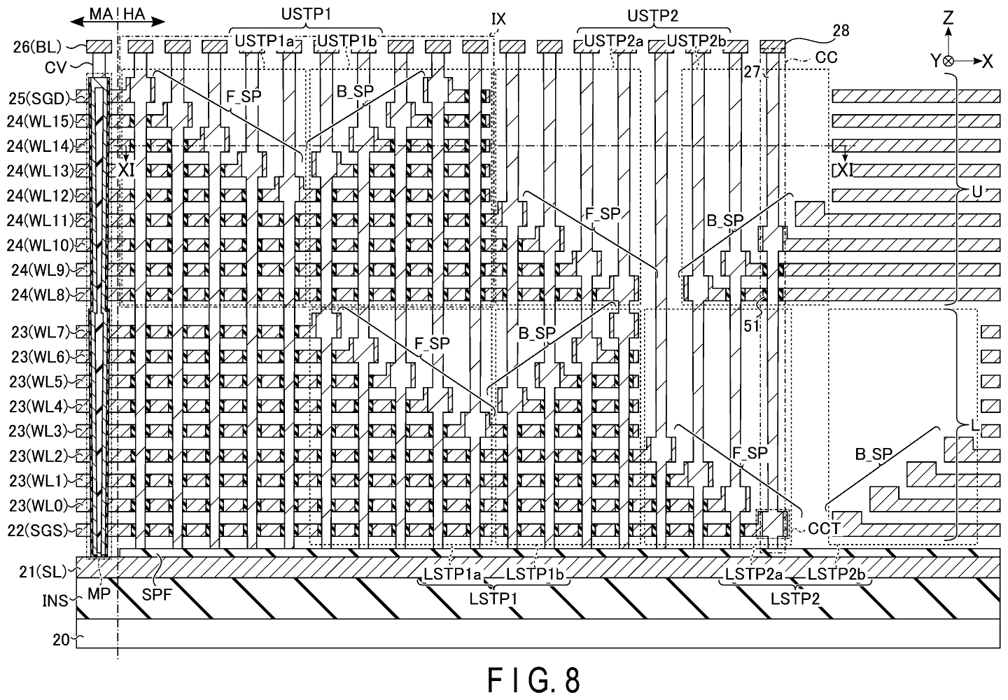

FIG. 7 is a schematic view schematically illustrating an example of a sectional structure of a stacked interconnect in the hookup area HA of the memory cell array 10 included in the semiconductor memory device 3 according to the first embodiment. FIG. 8 is a sectional view illustrating an example of a sectional structure in the hookup area HA of the memory cell array 10 included in the semiconductor memory device 3 according to the first embodiment. In FIGS. 7 and 8, in addition to the hookup area HA corresponding to one block BLK, a part of the memory area MA near the hookup area HA is also illustrated. FIG. 7 illustrates a plurality of areas included in the stacked interconnect. In FIG. 7, for simplification of description, the memory pillar MP, the contact CV and the interconnect layer provided above the stacked interconnect, a contact CC to be described later, and the like are omitted. FIG. 8 illustrates details of a sectional structure in the hookup area HA of the memory cell array.

First, the sectional structure of the stacked interconnect in the hookup area HA will be described with reference to FIG. 7.

As illustrated in FIG. 7, the hookup area HA includes, for example, four stepped areas USTP1, USTP2, LSTP1, and LSTP2.

The stepped areas USTP1 and USTP2 are provided in the upper stacked interconnect U. The stepped areas USTP1 and USTP2 are areas where the respective ends of the interconnect layers 24 and 25 are extended to form a step shape.

The stepped areas LSTP1 and LSTP2 are provided in the lower stacked interconnect L. The stepped areas LSTP1 and LSTP2 are areas where the respective ends of the interconnect layers 22 and 23 are extended to form a step shape.

Note that the upper stacked interconnect U and the lower stacked interconnect L may include any number of stepped areas. In the case where any of the stepped area USTP1, USTP2, LSTP1, and LSTP2 is not specified, it is hereinafter referred to as a “stepped area STP”.

The stepped area STP includes a two-sided stepped structure. The two-sided stepped structure is a stepped structure in which front steps F_SP and back steps B_SP are disposed side by side in the X direction. The front steps F_SP has a stepped structure in which a part of the plurality of interconnect layers is extended so as to form descending steps in a direction away from the memory area MA side in the X direction. The back steps B_SP has a stepped structure in which a part of the plurality of interconnect layers is extended so as to form ascending steps in a direction away from the memory area MA side in the X direction. The front steps F_SP and the back steps B_SP are similar to steps, terraces, rimstone, and the like. The front steps F_SP and the back steps B_SP are disposed opposing each other such that the lowest stepped portion is disposed at the center of the two-sided stepped structure in the X direction. Note that the lowest stepped portion of the two-sided stepped structure is included in the front steps F_SP. Hereinafter, in the stepped area STP, an area including the front steps F_SP is referred to as a front stepped area, and an area including the back steps B_SP is referred to as a back stepped area. The front stepped area and the back stepped area are arranged in the X direction. The front stepped area is provided on the side of the stepped area STP close to the memory area MA. The back stepped area is provided on the side of the stepped area STP far from the memory area MA. Hereinafter, the front stepped area and the back stepped area are collectively referred to as sub-stepped areas.

Specifically, the stepped area USTP1 includes a front stepped area USTP1a and a back stepped area USTP1b. The front stepped area USTP1a and the back stepped area USTP1b are arranged in the X direction. The front stepped area USTP1a is provided on the memory area MA side with respect to the back stepped area USTP1b. The stepped area USTP1 has, for example, a two-sided stepped structure provided in four of the interconnect layers 24 respectively corresponding to the word lines WL12 to WL15 and the interconnect layer 25 corresponding to the select gate line SGD. The front steps F_SP of the front stepped area USTP1a is provided in the four interconnect layers 24 respectively corresponding to the word lines WL12 to WL15 and the interconnect layer 25 corresponding to the select gate line SGD. The back steps B_SP of the back stepped area USTP1b is provided in three of the interconnect layers 24 respectively corresponding to the word lines WL13 to WL15 and the interconnect layer 25 corresponding to the select gate line SGD.

The stepped area USTP2 includes a front stepped area USTP2a and a back stepped area USTP2b. The front stepped area USTP2a and the back stepped area USTP2b are arranged in the X direction. The front stepped area USTP2a is provided on the memory area MA side with respect to the back stepped area USTP2b. The stepped area USTP2 has, for example, a two-sided stepped structure provided in four of the interconnect layers 24 respectively corresponding to the word lines WL8 to WL11. The front steps F_SP of the front stepped area USTP2a is provided in the four interconnect layers 24 respectively corresponding to the word lines WL8 to WL11. The back steps B_SP of the back stepped area USTP2b is provided in four of the interconnect layers 24 respectively corresponding to the word lines WL8 to WL11.

The stepped area LSTP1 includes a front stepped area LSTP1a and a back stepped area LSTP1b. The front stepped area LSTP1a and the back stepped area LSTP1b are arranged in the X direction. The front stepped area LSTP1a is provided on the memory area MA side with respect to the back stepped area LSTP1b. The stepped area LSTP1 has, for example, a two-sided stepped structure provided at the end portions of five of the interconnect layers 23 respectively corresponding to the word lines WL3 to WL7. The front steps F_SP of the front stepped area LSTP1a is provided in the five interconnect layers 23 respectively corresponding to the word lines WL3 to WL7. The back steps B_SP of the back stepped area LSTP1b is provided in four of the interconnect layers 24 respectively corresponding to the word lines WL4 to WL7.

The stepped area LSTP2 includes a front stepped area LSTP2a and a back stepped area LSTP2b. The front stepped area LSTP2a and the back stepped area LSTP2b are arranged in the X direction. The front stepped area LSTP2a is provided on the memory area MA side with respect to the back stepped area LSTP2b. The stepped area LSTP2 has, for example, a two-sided stepped structure provided at the end portions of the interconnect layer 22 corresponding to the select gate line SGS and three of the interconnect layers 23 respectively corresponding to the word lines WL0 to WL2. The front steps F_SP of the front stepped area USTP2a is provided in the interconnect layer 22 corresponding to the select gate line SGS and three of the interconnect layers 23 respectively corresponding to the word lines WL0 to WL2. The back steps B_SP of the back stepped area LSTP2b is provided in the interconnect layer 22 corresponding to the select gate line SGS and the three interconnect layers 23 respectively corresponding to the word lines WL0 to WL2.

The front stepped area and the back stepped area of each stepped area STP are disposed so as to be staggered between the upper stacked interconnect U and the lower stacked interconnect L as viewed in the Z direction. The front stepped areas USTP1a and USTP2a corresponding to the upper stacked interconnect U are not provided above the front stepped areas LSTP1a and LSTP2a corresponding to the lower stacked interconnect L. For example, the front stepped area USTP1a is provided above an area where the two-sided stepped structure of the lower stacked interconnect L is not formed. The front stepped area USTP2a is provided above the back stepped area LSTP1b. The front stepped area LSTP1a is provided below the back stepped area USTP1b. The front stepped area LSTP2a is provided below the back stepped area USTP2b. The two-sided stepped structure of the upper stacked interconnect U is not formed above the back stepped area LSTP2b.

As illustrated in FIG. 8, in the hookup area HA, the memory cell array 10 further includes a plurality of the contacts CC, interconnect layers 28 and a stop member SPF.

The plurality of contacts CC are provided corresponding to the select gate lines SGS and SGD and the word lines WL0 to WL15, respectively. In the example illustrated in FIG. 8, the plurality of contacts CC correspond to the select gate line SGD, the word lines WL15, WL14, WL13, WL12, WL7, WL6, WL5, WL4, WL3, WL11, WL10, WL9, WL8, WL2, WL1, and WL0, and the select gate line SGS in order from the memory area MA side. Each contact CC extends in the Z direction. Each contact CC extends (passes) through an interconnect layer provided at a position where the contact CC is provided in plan view among the interconnect layers 22, 23, 24, and 25 and insulating layers (not illustrated) in the Z direction. The lower surface of each contact CC is in contact with the stop member SPF. The contact provided extending through the stacked interconnects in the Z direction in this manner is referred to as a “through contact”.

Each contact CC extends through at least one stepped area STP in the Z direction. Each contact CC is coupled to any one or more of the interconnect layers 22, 23, 24, and 25 in each of one or more stepped areas STP through which the contact CC passes in the Z direction. That is, each of the interconnect layers 22, 23, 24, and 25 includes a coupling portion electrically coupled to the contact CC in the corresponding stepped area STP. Hereinafter, a coupling portion with the contact CC in each of the interconnect layers 22, 23, 24, and 25 is referred to as a CC coupling portion CCT.

Each contact CC is provided so as to extend through one of the CC coupling portions CCT formed in the front stepped area in the Z direction, and is coupled to the interconnect layer on the side surface. In addition, some contacts CC are provided so as to further extend through one of the CC coupling portions CCT formed in the back stepped area in the Z direction, and are coupled to the interconnect layers corresponding to the respective CC coupling portions CCT on the side surface. Each contact CC corresponds to the interconnect layer 22, 23, 24, or 25 coupled at the CC coupling portion CCT formed in the front stepped area.

Specifically, the front stepped area USTP1a of the stepped area USTP1 includes the CC coupling portions CCT of the four interconnect layers 24 respectively corresponding to the word lines WL12 to WL15 and the interconnect layer 25 corresponding to the select gate line SGD. Different contacts CC are coupled to the respective CC coupling portions CCT. In the front stepped area USTP1a, five of the contacts CC each coupled to the CC coupling portion CCT correspond to the word lines WL12 to WL15 and the select gate line SGD, respectively. The back stepped area USTP1b of the stepped area USTP1 includes the CC coupling portions CCT of the interconnect layers 24 respectively corresponding to the word lines WL13 to WL15 and the interconnect layer 25 corresponding to the select gate line SGD. Different contacts CC are coupled to the respective CC coupling portions CCT. In the back stepped area USTP1b, four of the contacts CC each coupled to the CC coupling portion CCT are also each coupled to the CC coupling portion CCT formed in the front stepped area LSTP1a on the lower side.

The front stepped area USTP2a of the stepped area USTP2 includes the CC coupling portions CCT of the interconnect layers 24 respectively corresponding to the word lines WL8 to WL11. Different contacts CC are coupled to the respective CC coupling portions CCT. In the front stepped area USTP2a, four of the contacts CC each coupled to the CC coupling portion CCT correspond to the word lines WL8 to WL11, respectively. In the front stepped area USTP2a, four of the contacts CC each coupled to the CC coupling portion CCT are also each coupled to the CC coupling portion CCT formed in the back stepped area LSTP1b on the lower side. The back stepped area USTP2b of the stepped area USTP2 includes the CC coupling portions CCT of the interconnect layers 24 respectively corresponding to the word lines WL8 to WL10. Different contacts CC are coupled to the respective CC coupling portions CCT. In the back stepped area USTP2b, three of the contacts CC each coupled to the CC coupling portion CCT are also each coupled to the CC coupling portion CCT formed in the front stepped area LSTP2a on the lower side.

The front stepped area LSTP1a of the stepped area LSTP1 includes the CC coupling portions CCT of the interconnect layers 23 respectively corresponding to the word lines WL3 to WL7. Different contacts CC are coupled to the respective CC coupling portions CCT. In the front stepped area LSTP1a, five of the contacts CC each coupled to the CC coupling portion CCT correspond to the word lines WL3 to WL7, respectively. The back stepped area LSTP1b of the stepped area LSTP1 includes the CC coupling portions CCT of the interconnect layers 23 respectively corresponding to the word lines WL4 to WL7. Different contacts CC are coupled to the respective CC coupling portions CCT.

The front stepped area LSTP2a of the stepped area LSTP2 includes the CC coupling portions CCT of the interconnect layer 22 corresponding to the select gate line SGS and the interconnect layers 23 respectively corresponding to the word lines WL0 to WL2. In the front stepped area LSTP2a, four of the contacts CC each coupled to the CC coupling portion CCT correspond to the select gate line SGS and the word lines WL0 to WL2, respectively. Different contacts CC are coupled to the respective CC coupling portions CCT.

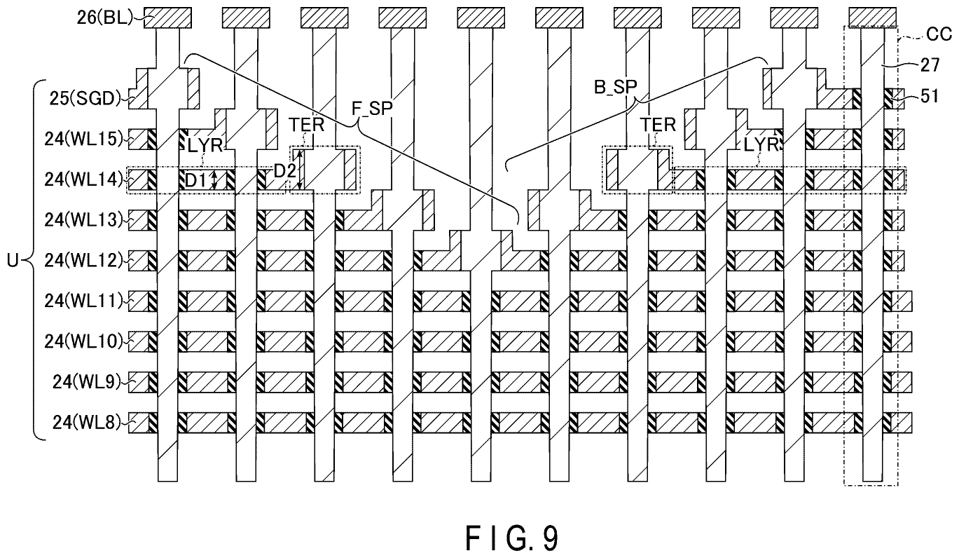

FIG. 9 is an enlarged view of area IX in FIG. 8. FIG. 9 corresponds to a sectional view of the stepped area USTP1. Details of coupling between the contact CC and the CC coupling portion CCT will be described with reference to FIG. 9.

As illustrated in FIG. 9, each interconnect layer of the stacked interconnect includes a stacked portion LYR and a terrace portion TER. The stacked portion LYR extends in the X direction and has, for example, a first thickness D1 in the Z direction. The terrace portion TER has, for example, a second thickness D2 greater than the first thickness D1 in the Z direction. Note that the terrace portion TER may have a thickness equal to or smaller than the first thickness D1 in the Z direction depending on the configuration of the contact CC to be described later.

The terrace portion TER of each interconnect layer is provided on a respective one tread of the front steps F_SP and the back steps B_SP formed in the stepped area STP. The terrace portion TER of each of the interconnect layers 24 and 25 included in the upper stacked interconnect U does not overlap the upper interconnect layers 24 and 25 in the Z direction. Similarly, as illustrated in FIG. 8, the terrace portion TER of each of the interconnect layers 22 and 23 included in the lower stacked interconnect L does not overlap the interconnect layers 23 of the lower stacked interconnect L provided at an upper layer of the terrace portion TER in the Z direction. Note that the terrace portion TER of each of the interconnect layers 22 and 23 included in the lower stacked interconnect L can overlap the interconnect layers 24 and 25 included in the upper stacked interconnect U in the Z direction.

As illustrated in FIG. 9, in each stepped area STP, the plurality of terrace portions TER provided in the respective interconnect layers are provided side by side in the X direction. Each terrace portion TER is spaced apart in the X direction from the side surface portion of the terrace portion TER provided one layer above. That is, the plurality of terrace portions TER provided in one stepped area STP are disposed apart from each other in the X direction.

As illustrated in FIG. 8, in each stepped area STP, each terrace portion TER of the interconnect layers 22, 23, 24, and 25, excluding the terrace portions TER of the interconnect layers 22 and 23 formed in the back steps B_SP of the back stepped area LSTP2b and interconnect layer 24 corresponding to word line WL11 formed in the back steps B_SP of the back stepped area USTP2b, functions as the CC coupling portion CCT.

Specifically, in the example illustrated in FIG. 9, the interconnect layer 24 corresponding to the word line WL14 includes two stacked portions LYR and two terrace portions TER in the illustrated stepped area USTP1. As to the two terrace portions TER, one terrace portion TER is provided for each of the front steps F_SP and the back steps B_SP. Each of the two stacked portions LYR is coupled to a respective one terrace portion TER. Among them, the stacked portion LYR coupled to the terrace portion TER provided in the front steps F_SP extends to the memory area MA. On the other hand, the stacked portion LYR coupled to the terrace portion TER provided in the back steps B_SP is not coupled to the memory area MA.

Each contact CC includes a conductor 27 and a plurality of insulators 51. The conductor 27 has a shape extending in the Z direction. In a portion extending through the terrace portion TER, the conductor 27 is coupled to any of the interconnect layers 22, 23, 24, or 25 in which the terrace portion TER is provided. At this time, there are a case where the conductor 27 is coupled to the terrace portion TER formed in the front steps F_SP and a case where the conductor is coupled to both the terrace portion TER formed in the front steps F_SP and the terrace portion TER formed in the back steps B_SP. The conductor 27 contains, for example, tungsten. The plurality of insulators 51 are provided so as to surround the side surface of the conductor 27 in a portion where the conductor 27 extends through the stacked portion LYR in the interconnect layers 22, 23, 24, and 25. The plurality of insulators 51 insulate the conductor 27 from the stacked portions LYR in the interconnect layers 22, 23, 24, and 25 through which the corresponding contact CC extends. That is, each contact CC is coupled to the interconnect layer extending through the terrace portion TER among the interconnect layers 22, 23, 24, and 25 and is insulated from the interconnect layer extending through the stacked portions LYR. Note that the configuration of the contact CC is not limited to the above configuration as long as the contact CC is coupled to the corresponding CC coupling portion CCT of a respective one interconnect layer and is insulated from other interconnect layers.

A plurality of the interconnect layers 28 are provided on the plurality of contacts CC, respectively. The plurality of interconnect layers 28 are positioned, for example, in the same layer as the plurality of interconnect layers 26. Each contact CC is electrically coupled to the row decoder module 15 via the interconnect layer 28.

As illustrated in FIG. 8, in the hookup area HA, the stop member SPF is provided on the interconnect layer 21. At the time of forming holes corresponding to the plurality of contacts CC in the manufacturing process of the hookup area HA, the stop member SPF functions as an etching stopper layer for ensuring that the lower surface of the hole does not reach the interconnect layer 21.

### (Planar Layout)

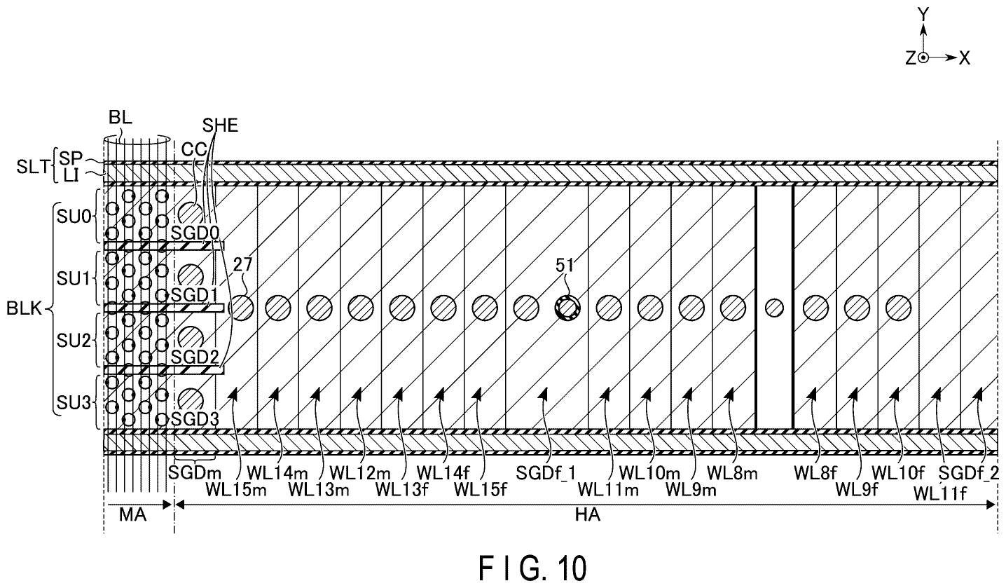

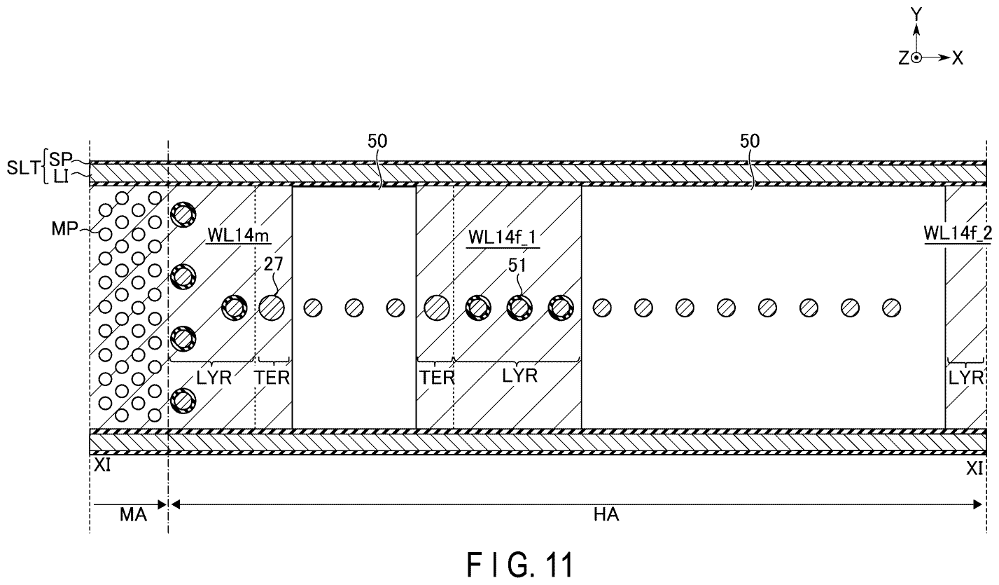

FIG. 10 is a plan view illustrating an example of a planar layout of the upper stacked interconnect U in the hookup area HA of the memory cell array 10 included in the semiconductor memory device 3 according to the first embodiment. FIG. 11 is a plan view illustrating an example of a plane taken along line XI-XI in FIG. 8 in the hookup area HA of the memory cell array 10 included in the semiconductor memory device 3 according to the first embodiment. FIGS. 10 and 11 illustrate the hookup area HA and a part of the memory areas MA near the hookup area HA. FIG. 11 corresponds to the planar structure of the interconnect layer 24 corresponding to the word line WL14. Note that FIG. 10 omits the stacked portion LYR and the terrace portion TER of each interconnect layer for simplification of description. In FIG. 11, the interconnect layer 24 corresponding to the word line WL14 is hatched, and the boundary between the stacked portion LYR and the terrace portion TER is indicated by a broken line.

As illustrated in FIG. 10, the select gate line SGD and the word lines WL8 to WL15 include a plurality of portions divided in the X direction by forming steps. Among the plurality of portions, a portion coupled to the memory area MA is referred to as a first portion and is distinguished by adding m to the end. A portion not coupled to the memory area MA is referred to as a second portion and is distinguished by adding f to the end. Note that there may be a plurality of the second portions. In this case, these second portions are distinguished by adding f_1, f_2, . . . to the ends in order from the memory area MA side.

The select gate line SGD includes a first portion SGDm coupled to the memory area MA and second portions SGDf_1 and SGDf_2 not coupled to the memory area MA. The interconnect layer 25 corresponding to the first portion SGDm of the select gate line SGD is divided in the Y direction by the plurality of members SHE. For example, in one block BLK, the interconnect layers 25 divided by three of the members SHE are defined as the select gate lines SGD0 to SGD3 from the upper side of the page. The select gate lines SGD0 to SGD3 are insulated from each other by the plurality of members SHE. As to the plurality of contacts CC, one contact CC is provided corresponding to each of the four select gate lines SGD0 to SGD3.

The word line WL15 includes a first portion WL15m coupled to the memory area MA, a second portion WL15f_1 not coupled to the memory area MA, and a second portion WL15f_2 in an area not illustrated.

The word line WL14 includes a first portion WL14m coupled to the memory area MA, a second portion WL14f_1 not coupled to the memory area MA, and a second portion WL14f_2 in an area not illustrated.

The word line WL13 includes a first portion WL13m coupled to the memory area MA, a second portion WL13f_1 not coupled to the memory area MA, and a second portion WL13f_2 in an area not illustrated.

The word line WL12 includes a first portion WL12m coupled to the memory area MA, and a second portion WL12f not coupled to the memory area MA in an area not illustrated.

The word line WL11 includes a first portion WL11m coupled to the memory area MA, and a second portion WL11f not coupled to the memory area MA.

The word line WL10 includes a first portion WL10m coupled to the memory area MA, and a second portion WL10f not coupled to the memory area MA.

The word line WL9 includes a first portion WL9m coupled to the memory area MA, and a second portion WL9f not coupled to the memory area MA.

The word line WL8 includes a first portion WL8m coupled to the memory area MA, and a second portion WL8f not coupled to the memory area MA.

Although not illustrated, the select gate line SGS and the word lines WL0 to WL7 similarly include a first portion coupled to the memory area MA and a second portion not coupled to the memory area MA, which are divided in the X direction by forming steps.

As illustrated in FIG. 11, the word line WL14 includes one stacked portion LYR and one terrace portion TER in each of the first portion WL14m and the second portion WL14f_1. The second portion WL14f_2 includes the stacked portion LYR.

In the first portion WL14m of the word line WL14, the terrace portion TER corresponding to the front steps F_SP of the stepped area USTP1 is formed. The terrace portion TER of the first portion WL14m is coupled to the conductor 27 of the contact CC corresponding to the word line WL14. That is, a voltage corresponding to the word line WL14 is applied from the row decoder module 15 to the first portion WL14m via the contact CC.

In the second portion WL14f_1, the terrace portion TER corresponding to the back steps B_SP of the stepped area USTP1 is formed. The terrace portion TER of the second portion WL14f_1 is coupled to the conductor 27 of the contact CC corresponding to another interconnect layer different from the word line WL14. The first portion WL14m and the second portion WL14f_1 of the word line WL14 are not in contact with each other, and are disposed apart from each other in the X direction with an insulating layer (not illustrated) interposed therebetween. Therefore, the contact CC coupled to the terrace portion TER of the second portion WL14f_1 is not electrically coupled to the first portion WL14m of the word line WL14.

In addition, the second portion WL14f_2 of the word line WL14 is not coupled to the contact CC and is in a floating state.

Therefore, for example, the contact CC supplies a voltage (current) to the memory area MA via the terrace portion TER of the first portion WL14m (front steps F_SP). The second portions WL14f_1 (back steps B_SP) and WL14f_2 do not contribute to the supply of the voltage (current) from the contact CC to the memory area MA. That is, the back steps B_SP do not function as a current path of the contact CC. Therefore, even if another contact CC and the back steps B_SP are coupled to each other, the characteristics of the memory cell array 10 are not affected.

Although not illustrated, for example, for the select gate lines SGS and SGD and the other word lines WL0 to WL13 and WL15, the terrace portions TER corresponding to the front steps F_SP are formed in the respective first portions similarly to the word line WL14. Each of the plurality of contacts CC supplies a voltage (current) to the memory area MA via the terrace portion TER of the corresponding select gate line SGS or SGD or the corresponding first portion (front steps F_SP) of one of the word lines WL0 to WL13 and WL15. In the select gate line SGS and SGD and the word lines WL0 to WL2, WL4 to WL11, WL13, and WL15, as well as in the word line WL14, the terrace portion TER corresponding to the back steps B_SP is formed in each one second portion thereof. Each of the second portions (back steps B_SP) does not contribute to the supply of the voltage (current) from the contact CC to the memory area MA. That is, the terrace portions TER corresponding to the back steps B_SP formed in the select gate line SGS and SGD and the word lines WL0 to WL2, WL4 to WL11, WL13, and WL15 do not function as a current path of the contact CC as well as the one formed in the word line WL14. Therefore, even if the contact CC and the terrace portion TER corresponding to the back steps B_SP are coupled to each other, the characteristics of the memory cell array 10 are not affected.

### 1.2 Manufacturing Method of Hookup Area

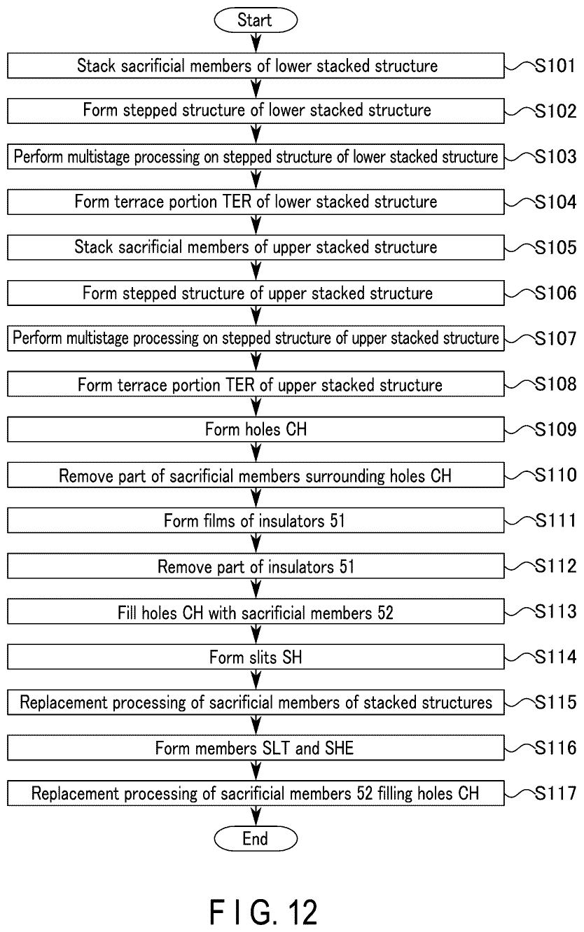

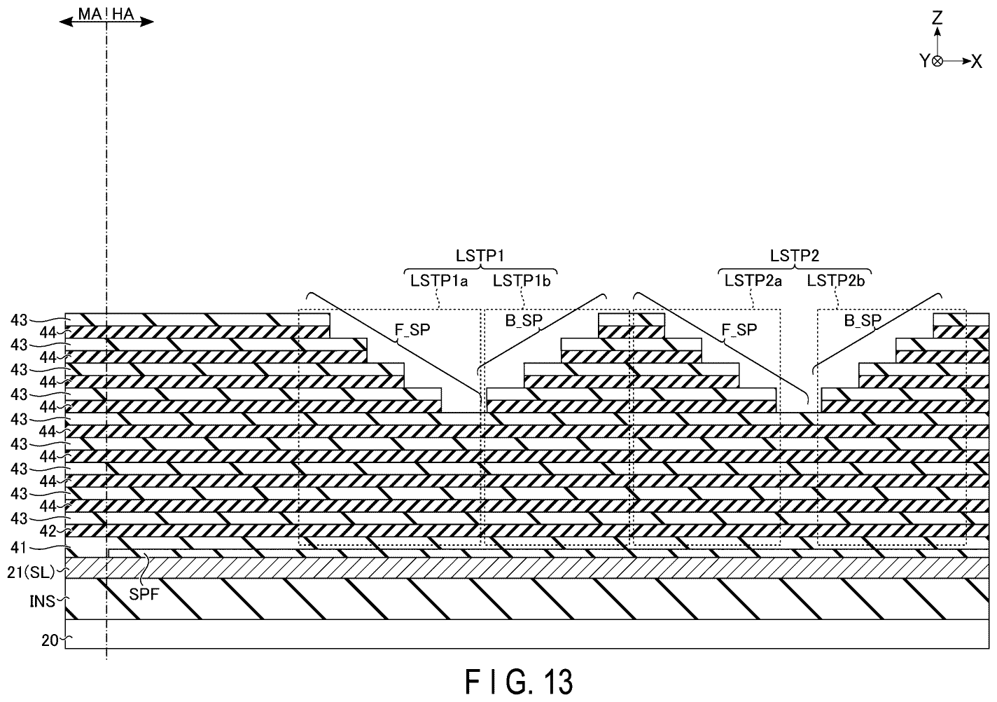

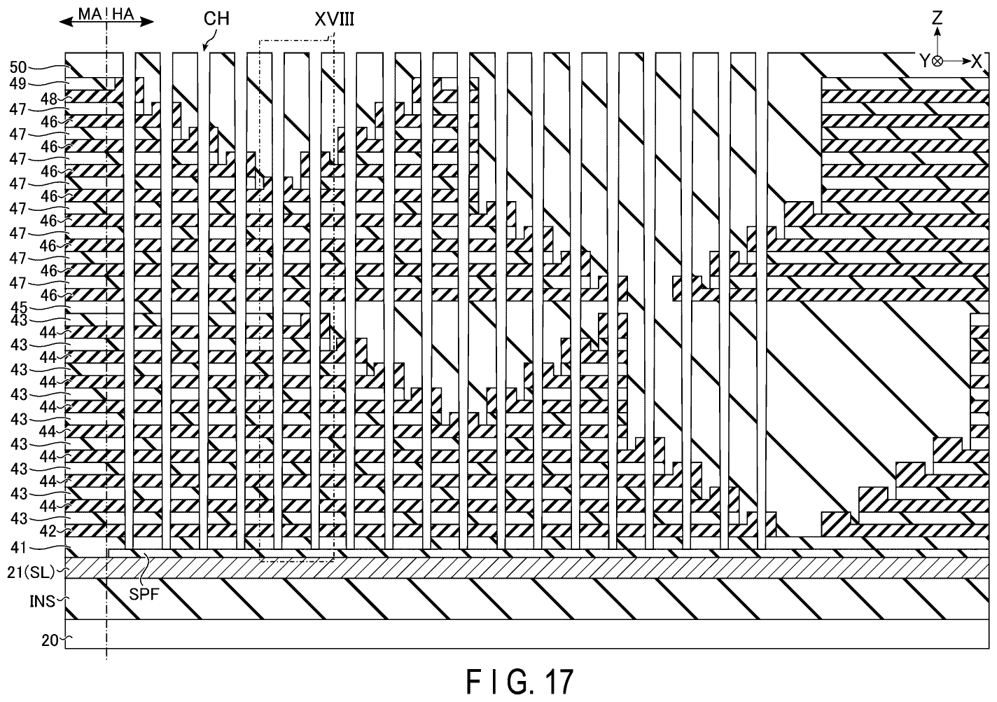

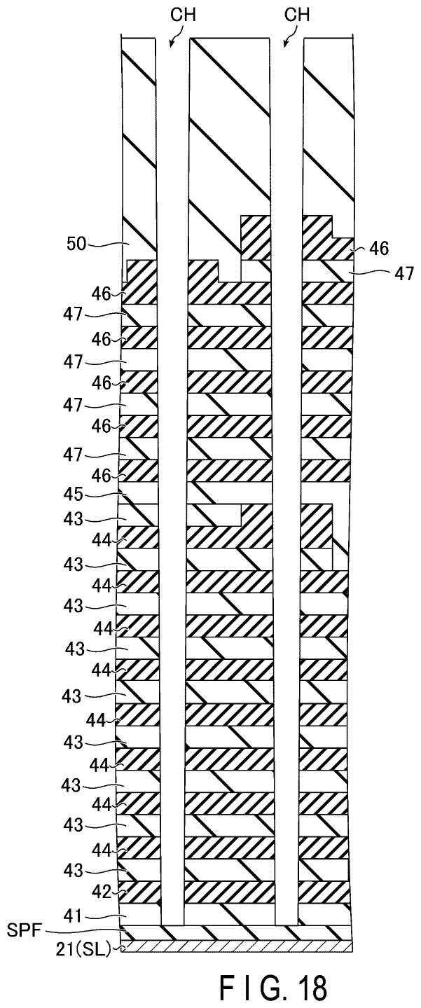

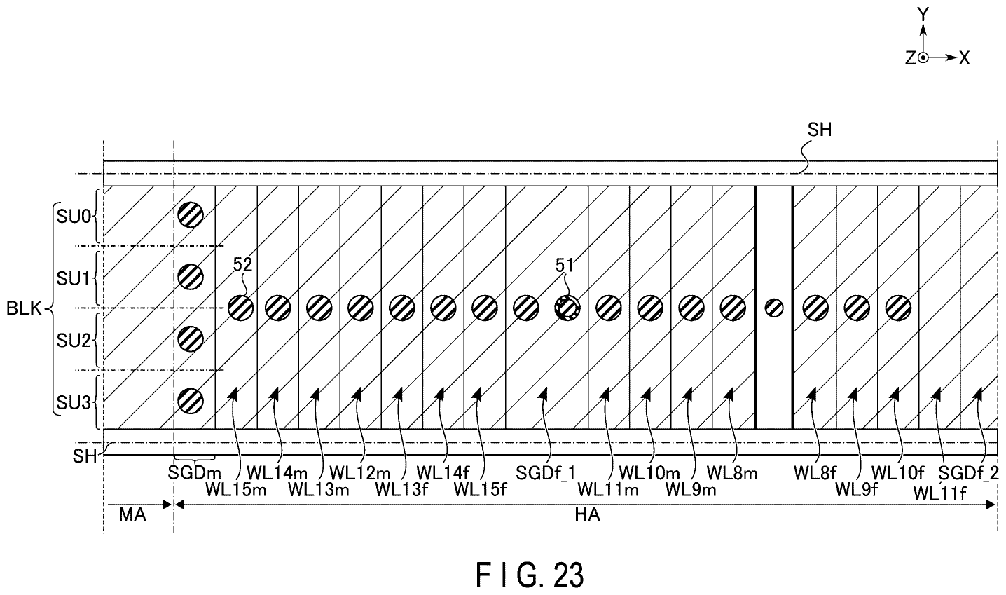

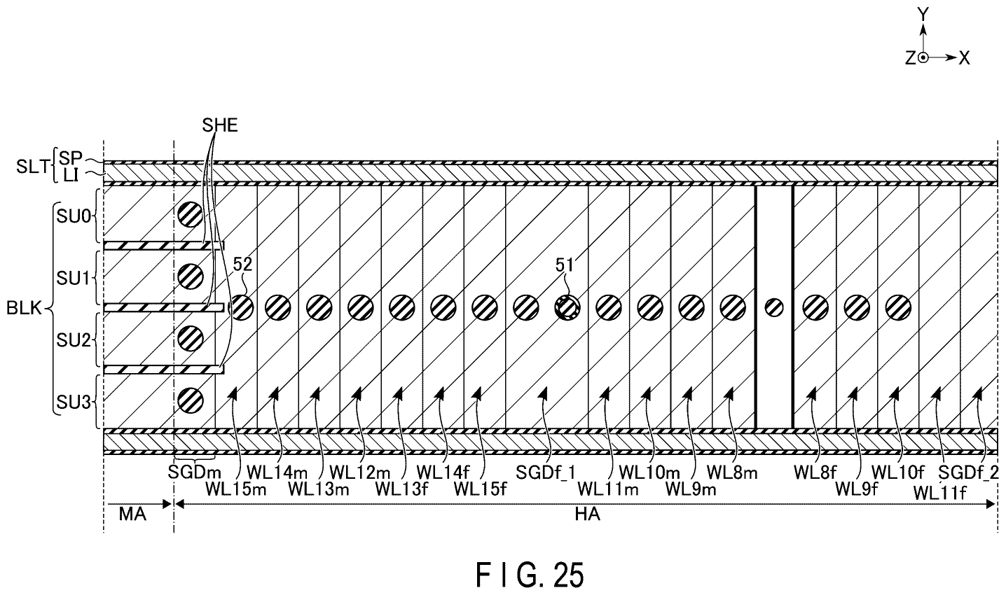

FIG. 12 is a flowchart illustrating an example of a manufacturing method of the hookup area HA of the memory cell array 10 included in the semiconductor memory device 3 according to the first embodiment. Each of FIGS. 13 to 22, 24, and 26 is a sectional view illustrating an example of a sectional structure of the hookup area HA in the manufacturing process of the memory cell array 10 included in the semiconductor memory device 3 according to the first embodiment. The sectional structures illustrated in FIGS. 13 to 17, 22, 24, and 26 each present an area corresponding to FIG. 8. The sectional structures illustrated in FIGS. 18 to 21 each present an area corresponding to area XVIII in FIG. 17. FIGS. 23 and 25 is a plan view illustrating an example of a planar layout of the hookup area HA in the manufacturing process of the memory cell array 10 included in the semiconductor memory device 3 according to the first embodiment. The planar layouts illustrated in FIGS. 23 and 25 each present an area corresponding to FIG. 10. Note that, in FIGS. 23 and 25, the stacked portion LYR, the terrace portion TER, and the insulating layer are omitted.

As illustrated in FIG. 12, in the manufacturing process of the hookup area HA, the processing of S101 to S117 is sequentially performed. Hereinafter, an example of a manufacturing process of the hookup area HA will be described with reference to FIGS. 13 to 26 as necessary.

Note that, in the present embodiment, the following case is described as an example: a method of forming structures corresponding to the interconnect layers 22, 23, 24, and 25 by using sacrificial members 42, 44, 46, and 48, respectively, and then forming the interconnect layers 22, 23, 24, and 25 by replacing the sacrificial members with the conductive material (hereinafter, referred to as “replacement”) is adopted as a method of forming the plurality of interconnect layers 22, 23, 24, and 25 respectively corresponding to the select gate lines SGS and SGD and the word lines WL0 to WL15.

First, the processing of S101 and S103 is sequentially performed, and the two-sided stepped structure of the lower stacked interconnect L including the sacrificial members 42 and 44 is formed.

Specifically, first, as illustrated in FIG. 13, the insulating layer INS and the interconnect layer 21 are stacked in this order on the semiconductor substrate 20. Next, in the hookup area HA, the stop member SPF is provided on the interconnect layer 21. An insulating layer 41 and the sacrificial member 42 are stacked in this order on the interconnect layer 21 and the stop member SPF. On the sacrificial member 42, for example, nine insulating layers 43 and eight layers of the sacrificial members 44 are alternately stacked one by one (S101). The uppermost layer is the insulating layer 43. The thickness of each of the sacrificial members 42 and 44 in the Z direction is equal to the first thickness D1. The insulating layers 41 and 43 contain, for example, silicon oxide (SiO). The sacrificial members 42 and 44 contain, for example, silicon nitride (SiN).

Thereafter, in areas respectively corresponding to the stepped areas LSTP1 and LSTP2, four insulating layers 43 and four layers of the sacrificial members 44 from the upper layer are processed in a step shape with a set of one insulating layer 43 and one layer of the sacrificial member 44 as one stage (S102). At this time, the front steps F_SP are formed in the front stepped areas LSTP1a and LSTP2a, and the back steps B_SP are formed in the back stepped areas LSTP1b and LSTP2b. Specifically, first, a mask in which a portion corresponding to the lowest stepped portion is open is formed by photolithography or the like. Then, the insulating layer 43 and the sacrificial member 44 corresponding to one stage are removed by anisotropic etching using the mask. Next, a portion of the mask corresponding to the second lowest stage is removed. Thereafter, the insulating layer 43 and the sacrificial member 44 corresponding to one stage are removed by anisotropic etching using the mask. In this way, by repeating the reduction in size of the masked area and the anisotropic etching, the insulating layer 43 and the sacrificial member 44 are processed in a step shape. Such processing is called “slimming”. This forms a two-sided stepped structure.

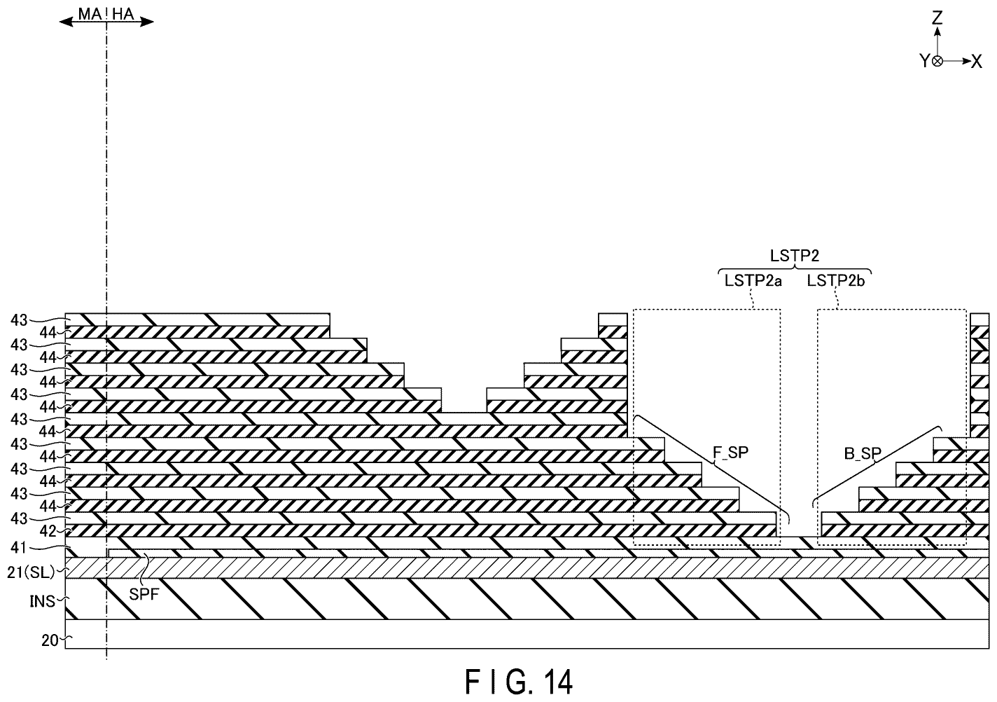

Thereafter, as illustrated in FIG. 14, multistage processing is performed on the two-sided stepped structure formed in the stepped area LSTP2, and the two-sided stepped structure is processed so as to correspond to the interconnect layer below the two-sided stepped structure formed in the stepped area LSTP1 (S103). The multistage processing is the processing of removing a plurality of insulating layers and a plurality of sacrificial members in the process area at a time.

Specifically, first, a mask in which an area corresponding to the stepped area LSTP2 is open is formed by photolithography or the like. Then, for example, the insulating layers 43 and the sacrificial members 44 corresponding to five stages are removed by anisotropic etching using the mask. This process forms, in the stepped area LSTP2, a two-sided stepped structure in which four of the insulating layers 43 and the sacrificial member 42 from the lower layer and three layers of the sacrificial members 44 from the lower layer are processed in a step shape with a set of one insulating layer 43 and one layer of the sacrificial member 42 or 44 as one stage.

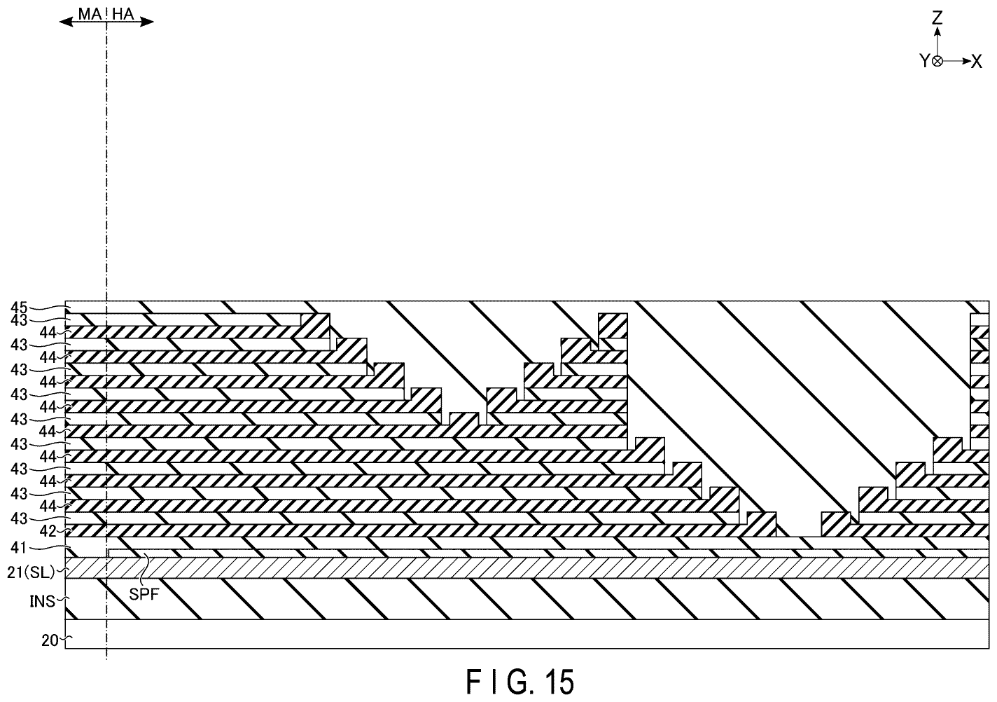

Next, the processing of S104 is performed, and as illustrated in FIG. 15, in each stepped area, a portion corresponding to the terrace portion TER of each interconnect layer included in the lower stacked interconnect L is formed in the sacrificial members 42 and 44.

Specifically, in the stepped areas LSTP1 and LSTP2, the insulating layer 43 exposed on the upper surface of the two-sided stepped structure is removed. Thereafter, sacrificial members respectively corresponding to the sacrificial members 42 and 44 are formed, and the films of the sacrificial members in the stepped portion are thickened. Thereafter, removal is performed on the sacrificial member formed on the uppermost insulating layer 43 and a portion in contact with the side surface portion of the sacrificial member 44 provided one layer above the sacrificial member 42 or 44 with the insulating layer 43 interposed therebetween in the sacrificial members of the film-thickened stepped portion of the sacrificial members 42 and 44. In this way, a portion of the sacrificial member 42 or 44 where the film thereof is thickened and that corresponds to the terrace portion TER is formed. The thickness in the Z direction of the sacrificial members 42 or 44 corresponding to the terrace portion TER is equal to the second thickness D2.

Thereafter, the stepped areas LSTP1 and LSTP2 of the lower stacked interconnect L are filled with an insulating layer 45. The insulating layer 45 contains, for example, SiO. For example, the surface of the insulating layer 45 is planarized by chemical mechanical polishing (CMP).

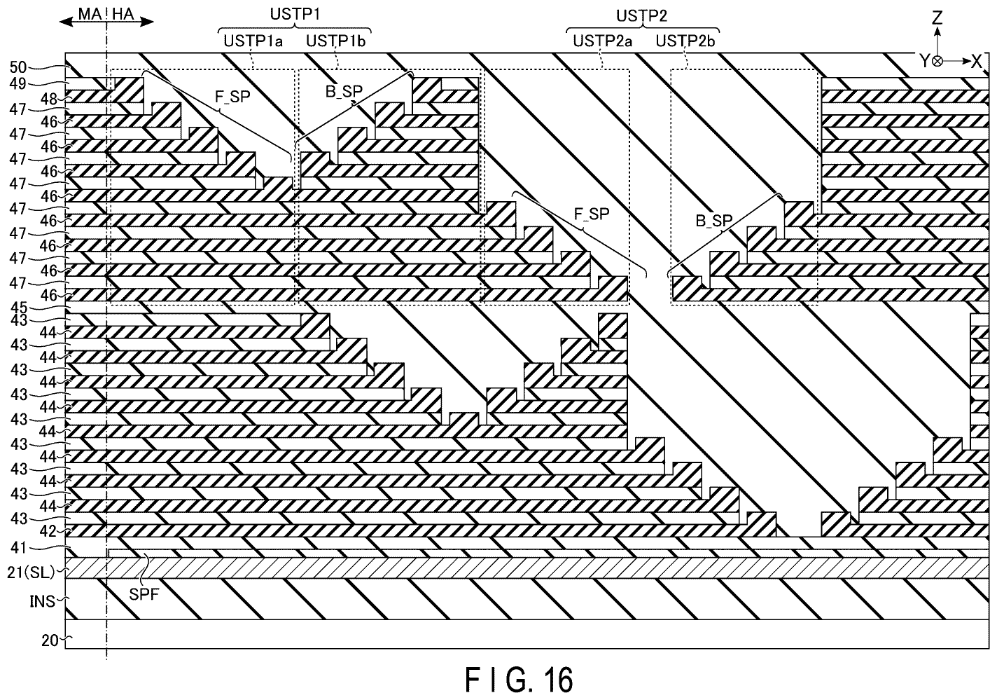

Next, the processing of S105 to S108 is performed, and as illustrated in FIG. 16, an upper stacked interconnect including the sacrificial members 46 and 48 is formed, a two-sided stepped structure of the upper stacked interconnect U is formed, and a portion corresponding to the terrace portion TER of each interconnect layer included in the upper stacked interconnect U.

Specifically, first, for example, eight layers of the sacrificial members 46 and eight insulating layers 47 are alternately stacked one by one on the stacked structure. The sacrificial member 48 and an insulating layer 49 are stacked in this order on the uppermost insulating layer 47 (S105). The thickness of each of the sacrificial members 46 and 48 in the Z direction is equal to the first thickness D1. The insulating layers 47 and 49 contain, for example, SiO. The sacrificial members 46 and 48 contain, for example, SiN.

Next, in the areas respectively corresponding to the stepped areas USTP1 and USTP2, the insulating layer 49 and three of the insulating layers 47 from the upper layer as well as the sacrificial member 48 and three layers of the sacrificial members 46 from the upper layer are processed in a step shape with a set of one insulating layer 47 or 49 and one layer of the sacrificial member 46 or 48 set as one stage by, for example, slimming (S106). At this time, the front steps F_SP are formed in the front stepped areas USTP1a and USTP2a, and the back steps B_SP are formed in the back stepped areas USTP1b and USTP2b.

Thereafter, multistage processing is performed on the two-sided stepped structure formed in the stepped area USTP2, and the two-sided stepped structure is processed so as to correspond to the interconnect layer below the two-sided stepped structure formed in the stepped area USTP1 (S107). This process forms, in the stepped area USTP2, a step-shaped structure in which four of the insulating layers 47 and four layers of the sacrificial members 46 from the lower layer are processed in a step shape with a set of one insulating layer 47 and one layer of the sacrificial member 46 as one stage.

Next, in the stepped areas USTP1 and USTP2, the insulating layers 47 and 49 exposed on the upper surface of the two-sided stepped structure is removed. Thereafter, sacrificial members respectively corresponding to the sacrificial members 46 and 48 are formed, and the films of the sacrificial members in the stepped portion are thickened. Subsequently, removal is performed on the sacrificial member formed on the uppermost insulating layer 49 and a portion in contact with the side surface portion of the sacrificial member 46 or 48 provided one layer above the sacrificial member 46 with the insulating layer 47 interposed therebetween in the sacrificial members of the film-thickened stepped portion of the sacrificial member 46 (S108). In this way, a portion of the sacrificial member 46 or 48 where the film thereof is thickened and that corresponds to the terrace portion TER are formed. The thickness in the Z direction of the sacrificial members 46 or 48 corresponding to the terrace portion TER is equal to the second thickness D2.

Thereafter, the stepped areas USTP1 and USTP2 of the upper stacked interconnect U are filled with an insulating layer 50. The insulating layer 50 contains, for example, SiO. For example, the surface of the insulating layer 50 is planarized by CMP.

Next, the processing of S109 is performed, and as illustrated in FIGS. 17 and 18, a plurality of holes CH corresponding to the plurality of contacts CC are formed.

Specifically, first, a mask in which an area corresponding to each contact CC is open is formed by photolithography or the like. Then, the plurality of holes CH corresponding to the respective contacts CC are formed by anisotropic etching using the mask. Each hole CH extends through each of the insulating layers 41, 43, 45, 47, 49, and 50 and the sacrificial members 42, 44, 46, and 48, and extends through at least one or more of the thickened portions of the sacrificial members 42, 44, 46, and 48. A part of the stop member SPF is exposed at the bottom portion of each hole CH.

Next, the processing of S110 to S113 is performed, and configurations corresponding to the plurality of contacts CC are formed.

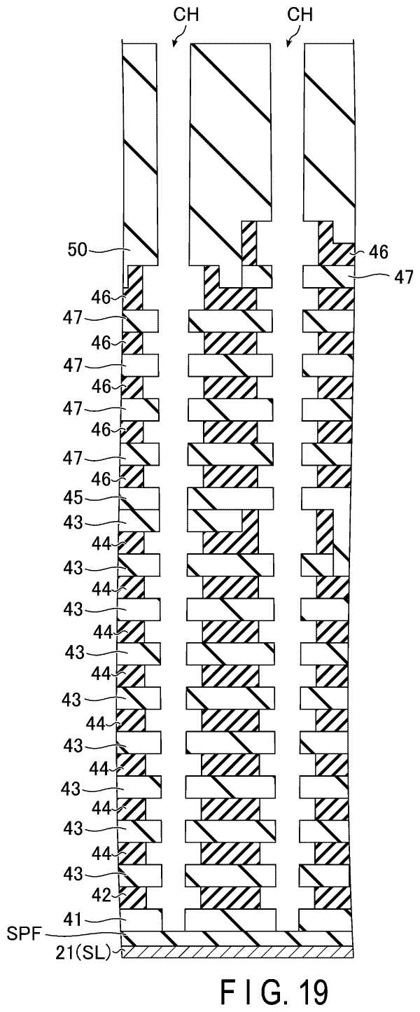

Specifically, first, as illustrated in FIG. 19, the peripheral portions of the sacrificial members 42, 44, 46, and 48 exposed on the side surfaces of the holes CH are removed by wet etching through the holes CH (S110). In this way, a plurality of grooves in which the sacrificial members 42, 44, 46, and 48 are recessed in the XY plane direction with respect to the insulating layers 41, 43, 45, and 47 are formed on the side surface of each hole CH.

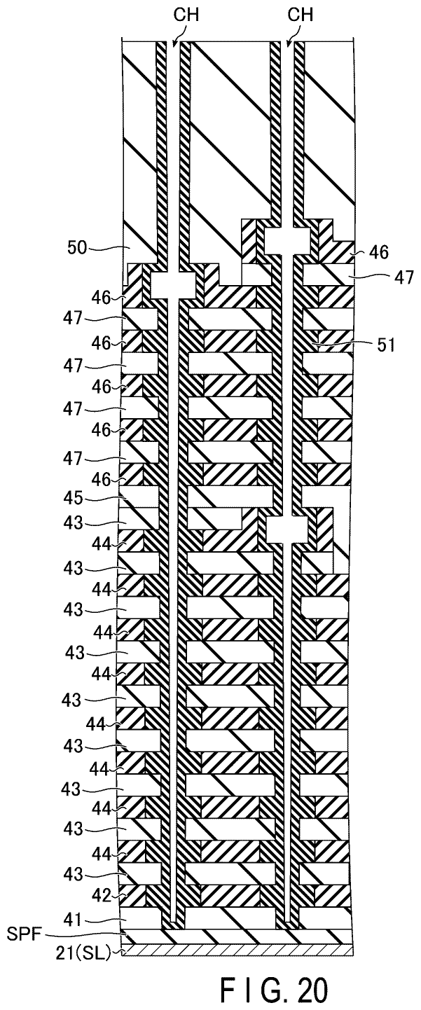

Thereafter, as illustrated in FIG. 20, the film of the insulator 51 is formed on the inner wall of each hole CH (S111). For a portion of the sacrificial member 42, 44, 46, or 48 where the film thereof is not thickened, the film of the insulator 51 is formed so as to fill the plurality of grooves formed in S108. On the other hand, in portions of the sacrificial members 42, 44, 46, and 48 where films thereof are thickened, the film of the insulator 51 is formed so as to cover the side surface portion of the groove while leaving a portion recessed at the central portion. The insulator 51 contains, for example, Sio.

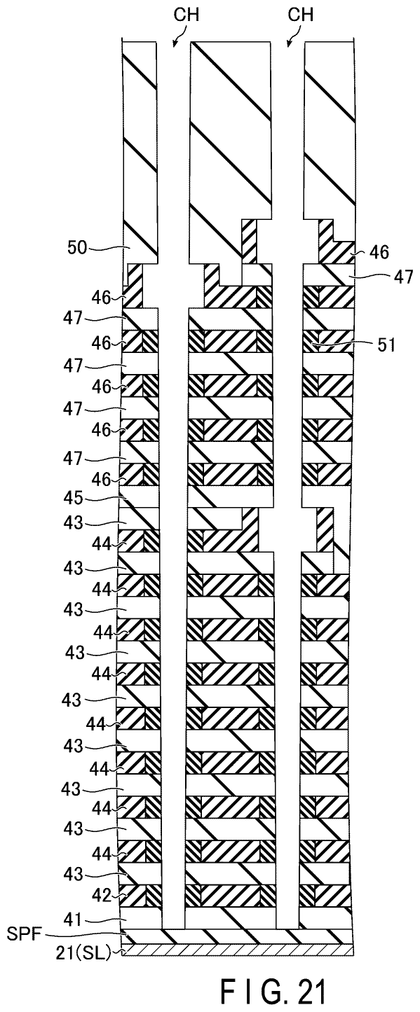

Thereafter, as illustrated in FIG. 21, a part of the insulator 51 in the hole CH is removed by wet etching (S112). At this time, in a portion of the sacrificial member 42, 44, 46, or 48 where a film thereof is not thickened, the insulators 51 filling the plurality of grooves are not completely removed, and none of the sacrificial members 42, 44, 46, and 48 is exposed on the side surface portion of each hole CH. On the other hand, in portions of the sacrificial members 42, 44, 46, and 48 where films thereof are thickened, the insulator 51 provided so as to cover the side surface portion of the groove is removed, and the sacrificial members 42, 44, 46, and 48 are exposed on the side surface portion of each hole CH.

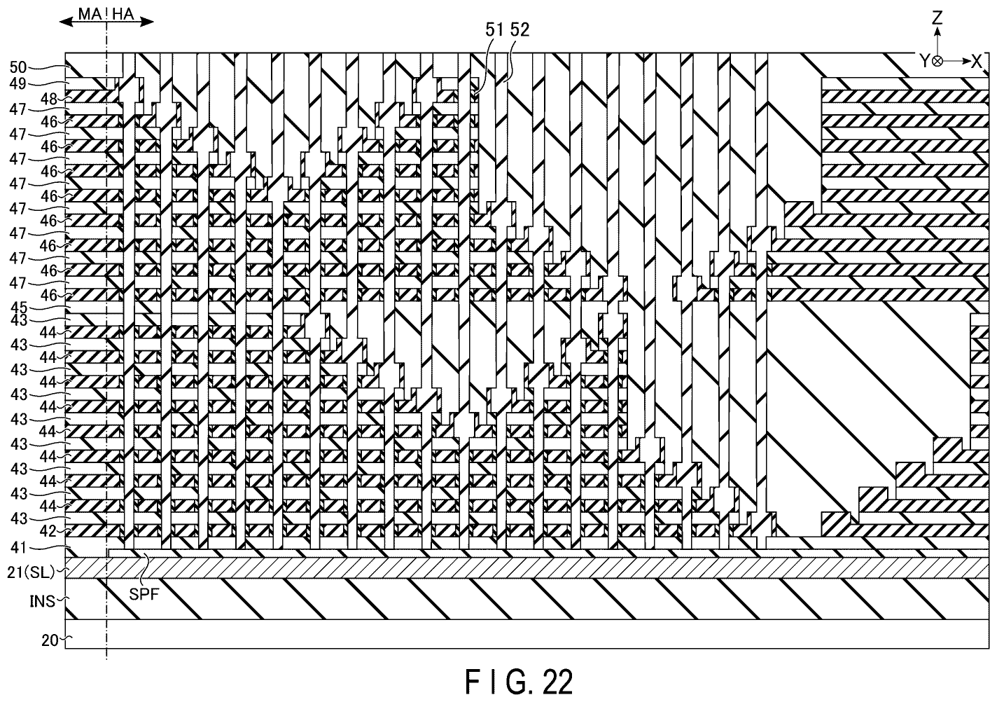

Thereafter, as illustrated in FIG. 22, each hole CH is filled with a sacrificial member 52 (S113). Each filling sacrificial member 52 is horizontally in contact with the sacrificial members 42, 44, 46, and 48 in grooves formed at portions where the films of the sacrificial members 42, 44, 46, and 48 are thickened. In addition, each sacrificial member 52 is in contact with the stop member SPF on the lower surface. The sacrificial member 52 contains, for example, amorphous silicon.

Next, the processing of S114 is performed, and a plurality of slits SH are formed as illustrated in FIG. 23.

Specifically, first, a mask in which an area corresponding to the member SLT is open is formed by photolithography or the like. Then, the slits SH extending through, for example, the insulating layers 41, 43, 45, 47, 49, and 50 and the sacrificial members 42, 44, 46, and 48 are formed by anisotropic etching using the mask.

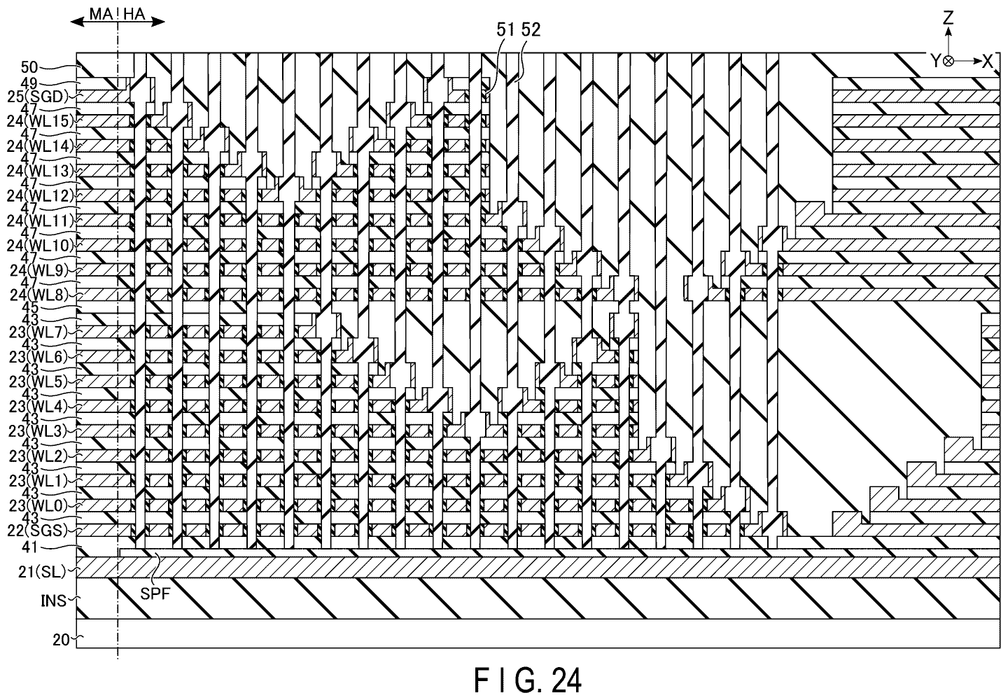

Next, the processing of S115 is performed, and a stacked interconnect structure is formed by replacement as illustrated in FIG. 24.

Specifically, first, the sacrificial members 42, 44, 46, and 48 are removed through the slits SH by wet etching. At this time, the three-dimensional structure of the structural body from which the sacrificial members 42, 44, 46, and 48 were removed is sustained by the plurality of memory pillars MP (not illustrated) and a plurality of support pillars (not illustrated). Then, the space from which the sacrificial members 42, 44, 46, and 48 were removed is filled with the conductor through the slit SH. For the formation of the conductor in this step, for example, chemical vapor deposition (CVD) is used. Thereafter, the conductor formed inside the slit SH is removed by etch-back processing, and the interconnect layers adjacent in the Z direction and the conductor are separated. In this way, the interconnect layer 22 functioning as the select gate line SGS, the plurality of interconnect layers 23 functioning as the word lines WL0 to WL7, the plurality of interconnect layers 24 functioning as the word lines WL8 to WL15, and the interconnect layer 25 functioning as the select gate line SGD are formed. Note that the interconnect layers 22, 23, 24, and 25 formed in this step may contain a barrier metal. In this case, in the formation of the conductor after removing the sacrificial members 42, 44, 46, and 48, for example, titanium nitride is deposited as a barrier metal, and then tungsten is formed.

Next, the processing of S116 is performed, and the member SLT is formed in each slit SH as illustrated in FIG. 25. In addition, the member SHE is formed in the terrace portion TER of the first portion SGDm of the select gate line SGD.

Specifically, first, an insulating portion (spacer SP) is formed so as to cover the side surface and the bottom surface of the slit SH. Then, a part of the spacer SP provided at the bottom portion of the slit SH is removed, and a part of the interconnect layer 21 is exposed at the bottom portion of the slit SH. Then, a conductor (contact LI) is formed in the slit SH, and the conductor formed outside the slit SH is removed by, for example, CMP. Thereafter, a plurality of grooves are formed in an area corresponding to the member SHE between the members SLT adjacent in the Y direction so that the plurality of grooves are parallel to the member SLT. Then, the inside of each groove is filled with an insulating film, and thus the member SHE dividing the interconnect layer 25 in the Y direction is formed.

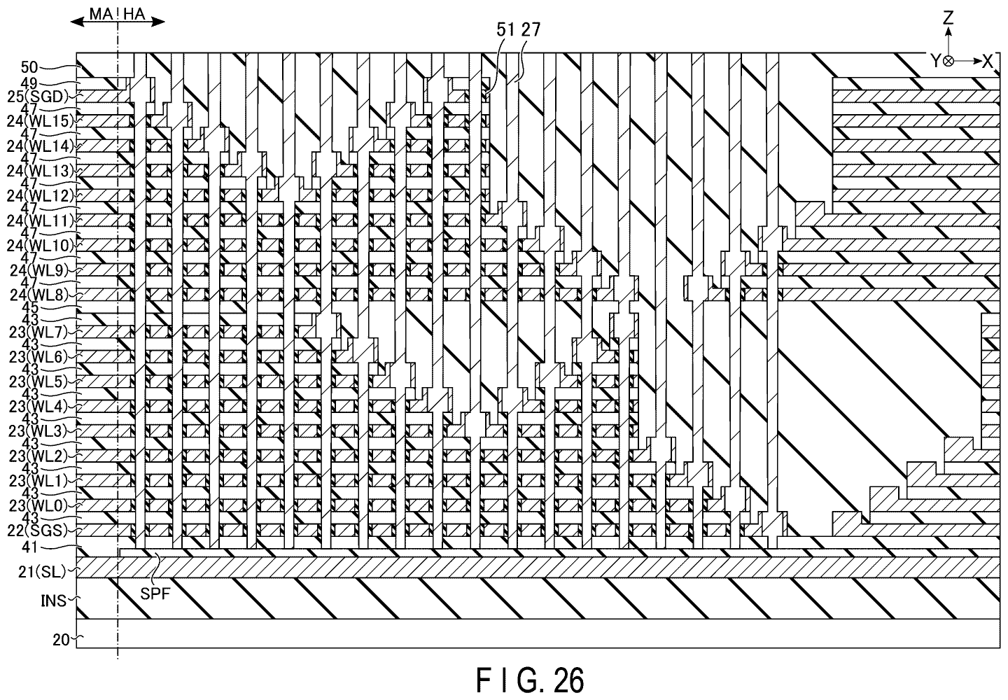

Finally, the processing of S117 is performed. As illustrated in FIG. 26, replacement processing of the sacrificial member 52 filling the hole CH is performed, and the contact CC is formed.

Specifically, first, the sacrificial members 52 filling each hole CH are removed by wet etching. Then, the hole CH is filled with the plurality of conductors 27. Each conductor 27 is horizontally in contact with the interconnect layers 22, 23, 24, and 25 in the groove formed at each terrace portion TER in these interconnect layers 22, 23, 24, and 25. In addition, each conductor 27 is in contact with the stop member SPF on the lower surface. Finally, the conductor formed on the upper surface of the stacked structure is removed by, for example, CMP, so that the surfaces corresponding to the upper ends of the plurality of contacts CC are exposed.

The structure of the hookup area HA in the memory cell array 10 is formed by the manufacturing process described above. Note that the manufacturing process described above is merely an example, and the present invention is not limited thereto. For example, other processing may be inserted between the manufacturing steps, or some steps may be omitted or integrated with each other. In addition, each manufacturing step may be interchanged within the possible range.

### 1.3 Effects According to First Embodiment

The first embodiment can provide a semiconductor memory device that can be manufactured with less man-hours and provide a reduced chip area. This effect will be described in detail below.

The semiconductor memory device 3 according to the first embodiment can overlap a part of the stepped area of the upper stacked interconnect U and a part of the stepped area of the lower stacked interconnect L in the Z direction of the memory cell array 10. Specifically, the front steps F_SP and the back steps B_SP can be disposed so as to be staggered between the upper stacked interconnect U and the lower stacked interconnect L as viewed in the Z direction. The front steps F_SP of the upper stacked interconnect U and the front steps F_SP of the lower stacked interconnect L do not overlap each other in the Z direction. In other words, the back steps B_SP of the upper stacked interconnect U may overlap the front steps F_SP of the lower stacked interconnect L in the Z direction. The back steps B_SP of the lower stacked interconnect L may overlap the front steps F_SP of the upper stacked interconnect U in the Z direction. With this structure, the CC coupling portions CCT of the respective interconnect layers can be provided overlapping in the Z direction. This can suppress an increase in the length of the memory cell array 10 in one direction (e.g., the X direction) due to the arrangement of the terrace portion TER of the interconnect layers in the direction, and can reduce (suppress the expansion of) the chip area of the semiconductor memory device 3.

In addition, as to the two-sided stepped structure of the memory cell array 10 included in the semiconductor memory device 3 according to the first embodiment, a plurality of two-sided stepped structures can be simultaneously formed by performing processing using slimming and multistage processing. For example, the two-sided stepped structures respectively included in the stepped areas LSTP1 and LSTP2 can be simultaneously formed. The two-sided stepped structures respectively included in the stepped areas USTP1 and USTP2 can be simultaneously formed. As a result, man-hours at the time of manufacturing the semiconductor memory device 3 can be reduced, and the manufacturing cost of the semiconductor memory device 3 can be cut back.

### 1.4 Modifications of First Embodiment

The semiconductor memory device 3 according to the first embodiment described above can be variously modified. Hereinafter, differences from the first embodiment will be described as to a first modification, a second modification, a third modification, and a fourth modification of the first embodiment.

### 1.4.1 First Modification of First Embodiment

### 1.4.1.1 Structure of Hookup Area

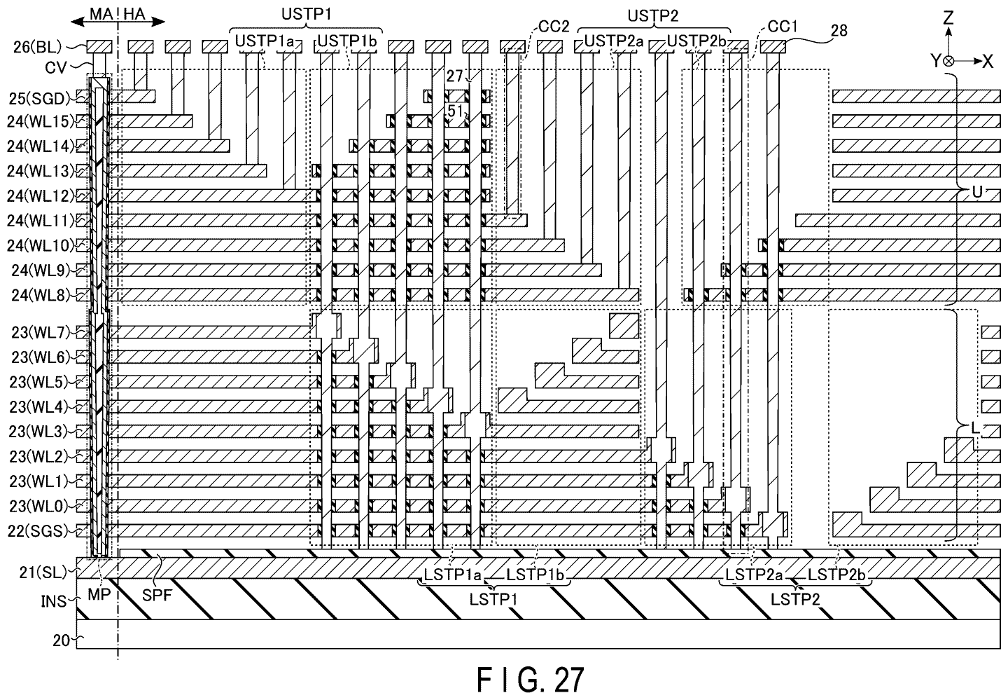

FIG. 27 is a sectional view illustrating an example of a sectional structure in the hookup area HA of the memory cell array 10 included in the semiconductor memory device 3 according to the first modification of the first embodiment. In FIG. 27, in addition to the hookup area HA corresponding to one block BLK, a part of the memory area MA near the hookup area HA is also illustrated.

As illustrated in FIG. 27, the plurality of contacts CC of the present modification includes a plurality of contacts CC1 and CC2.

The plurality of contacts CC1 are through contacts extending through the upper stacked interconnect U and the lower stacked interconnect L. The contact CC1 corresponds to the interconnect layers 22 and 23 included in the lower stacked interconnect L. Each contact CC1 couples one of the interconnect layers 22 and 23 and the corresponding interconnect layer 28. In the present modification, the terrace portion TER is not provided in each upper stacked interconnect U. Therefore, the contact CC1 is not coupled to the upper stacked interconnect U.

By using the contact CC1, even in a case where other interconnect layers (e.g., the interconnect layers 24 and 25) are provided at upper layers, the contact CC1 can be coupled to a target interconnect layer.

The plurality of contacts CC2 are contacts provided on the tread of the front steps F_SP provided in the upper stacked interconnect U. Each contact CC2 corresponds to any one of the interconnect layers 24 and 25 included in the upper stacked interconnect U. The tread of the front steps F_SP formed by each of the interconnect layers 24 and 25 functions as the respective one of CC coupling portions CCT. Each contact CC2 is provided extending in the Z direction between the tread of the front steps F_SP of each of the interconnect layers 24 and 25 and the corresponding interconnect layer 28, and couples them. Each contact CC2 does not extend through any interconnect layer among the interconnect layers 22, 23, 24, and 25 in the Z direction.

Since no stacked interconnect is provided between the CC coupling portion CCT of the interconnect layer 24 or 25 included in the upper stacked interconnect U and the corresponding interconnect layer 28, the contact CC2 can be coupled to a target interconnect layer without using a through contact.

Note that, in the example illustrated in FIG. 27, the terrace portion TER is not provided in the plurality of interconnect layers 24 and 25 included in the upper stacked interconnect U, but the terrace portion TER may be provided.

### 1.4.2 Second Modification of First Embodiment

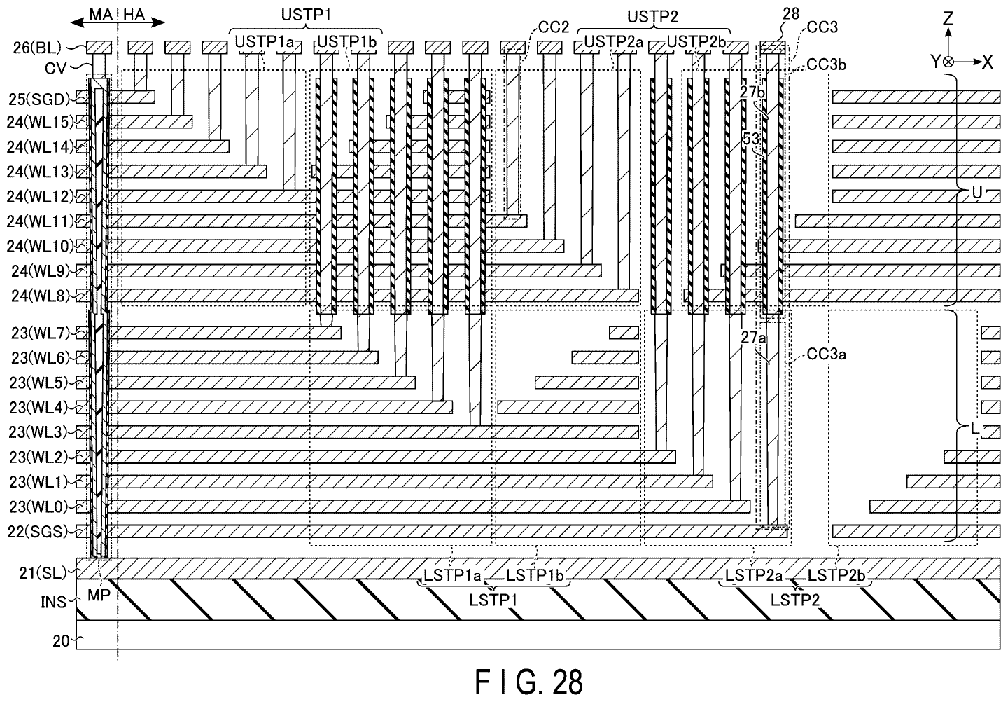

FIG. 28 is a sectional view illustrating an example of a sectional structure in the hookup area HA of the memory cell array 10 included in the semiconductor memory device 3 according to the second modification of the first embodiment. In FIG. 28, in addition to the hookup area HA corresponding to one block BLK, a part of the memory area MA near the hookup area HA is also illustrated.

As illustrated in FIG. 28, the plurality of contacts CC of the present modification includes a plurality of contacts CC2 and CC3.

The plurality of contacts CC2 are contacts having the same structure as the plurality of contacts CC2 in the first modification of the first embodiment.

The plurality of contacts CC3 are contacts provided on the tread of the front steps F_SP provided in the lower stacked interconnect L. Each contact CC3 corresponds to any one of the interconnect layers 22 and 23 included in the lower stacked interconnect L. The tread of the front steps F_SP formed by each of the interconnect layers 22 and 23 functions as the respective one of the CC coupling portions CCT.

Each contact CC3 includes a first portion CC3a and a second portion CC3b. The first portion CC3a includes a conductor 27a. The conductor 27a is provided extending in the Z direction. The conductor 27a includes: a lower surface in contact with the tread of the front steps F_SP of the corresponding interconnect layer 22 or 23; and an upper surface in contact with the lower surface of the second portion CC3b. The conductor 27a contains, for example, tungsten. Each first portion CC3a does not extend through any interconnect layer among the interconnect layers 22, 23, 24, and 25 in the Z direction. The second portion CC3b is a through contact provided extending through the upper stacked interconnect U in the Z direction. The second portion CC3b includes a conductor 27b and an insulator 53. The conductor 27b passes through a hole provided at a position corresponding to the contact CC3 in the upper stacked interconnect U in the Z direction. The conductor 27b includes: a lower surface in contact with the conductor 27a of the first portion CC3a; and an upper surface in contact with the lower surface of the interconnect layer 28 at the upper surface. The insulator 53 is provided in the upper stacked interconnect U so as to cover the conductor 27b from the side surface and fill the corresponding hole. The insulator 53 insulates the conductor 27b from the upper stacked interconnect U.

By using the contact CC3, even in a case where other interconnect layers (e.g., the interconnect layers 24 and 25) are provided at upper layers of the corresponding interconnect layer (e.g., the interconnect layer 22 or 23), the contact CC3 can be coupled to a target interconnect layer.

### 1.4.3 Third Modification of First Embodiment

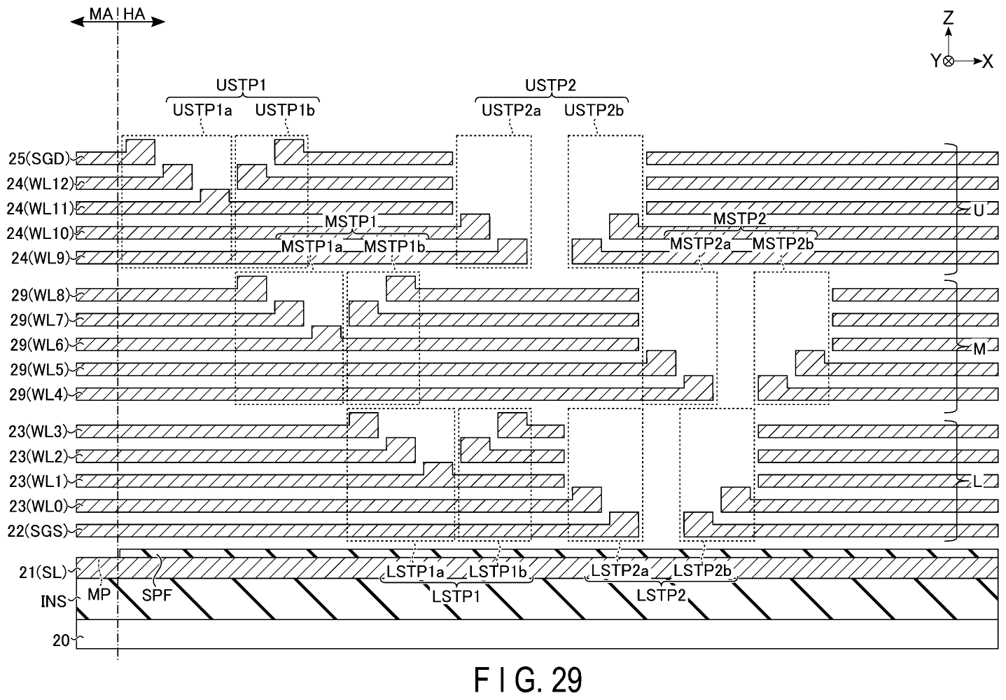

FIG. 29 is a schematic view schematically illustrating an example of a sectional structure of the stacked interconnect in the hookup area HA of the memory cell array 10 included in the semiconductor memory device 3 according to a third modification of the first embodiment. In FIG. 29, for simplification of description, the memory pillar MP, the contact CV and the interconnect layer provided above the stacked interconnect, the contact CC, and the like are omitted.

As illustrated in FIG. 29, the memory cell array 10 included in the semiconductor memory device 3 according to the third modification of the first embodiment includes the upper stacked interconnect U, a middle stacked interconnect M, and the lower stacked interconnect L. The interconnect layer 22 corresponding to the select gate line SGS and the interconnect layers 23 corresponding to the word lines WL0 to WL3 correspond to the lower stacked interconnect L. Interconnect layers 29 corresponding to the word lines WL4 to WL8 correspond to the middle stacked interconnect M. The interconnect layers 24 corresponding to the word lines WL9 to WL12 and the interconnect layer 25 corresponding to the select gate line SGD correspond to the upper stacked interconnect U.

The hookup area HA includes stepped areas MSTP1 and MSTP2 in addition to the stepped areas USTP1, USTP2, LSTP1, and LSTP2. The stepped areas MSTP1 and MSTP2 are areas where the respective ends of the interconnect layers 29 are extended to form a step shape. The middle stacked interconnect M may include any number of stepped areas. The stepped areas MSTP1 and MSTP2 are included in the stepped area STP and include a two-sided stepped structure.

The stepped area MSTP1 includes a front stepped area MSTP1a and a back stepped area MSTP1b. The front stepped area MSTP1a and the back stepped area MSTP1b are arranged in the X direction. The front stepped area MSTP1a is provided on the memory area MA side with respect to the back stepped area MSTP1b.

The stepped area MSTP2 includes a front stepped area MSTP2a and a back stepped area MSTP2b. The front stepped area MSTP2a and the back stepped area MSTP2b are arranged in the X direction. The front stepped area MSTP2a is provided on the memory area MA side with respect to the back stepped area MSTP2b.

The front stepped area and the back stepped area of each stepped area are arranged such that two or more front stepped areas do not overlap each other as viewed in the Z direction. The front stepped area may overlap a plurality of back stepped areas as viewed in the Z direction. For example, the front stepped area USTP1a is provided above an area where a stepped structure is not formed in the middle stacked interconnect M or the lower stacked interconnect L. The front stepped area MSTP1a is provided below the back stepped area USTP1b. The front stepped area LSTP1a is provided below the back stepped area MSTP1b. The front stepped area USTP2a is provided above the back stepped area LSTP1b. The front stepped area LSTP2a is provided below the back stepped area USTP2b. The front stepped area MSTP2a is provided above the back stepped area LSTP2b. A stepped structure is not formed in the upper stacked interconnect U above the back stepped area MSTP2b, and the lower stacked interconnect L below the back stepped area MSTP2b. Note that the above arrangement is an example, and the arrangement of the stepped area is not limited thereto.

In the third modification of the first embodiment, the stacked interconnect is divided into three of the upper stacked interconnect U, the middle stacked interconnect M, and the lower stacked interconnect L, and the stepped area STP is provided in each of them. However, the number of divisions of the stacked interconnect may be four or more.

Furthermore, in the third modification of the first embodiment, the same configurations as the first modification and the second modification of the first embodiment may be applied. For example, in the third modification, the contacts CC1 and CC2, or the contacts CC2 and CC3 may be used instead of the contact CC.

### 1.4.4 Fourth Modification of First Embodiment

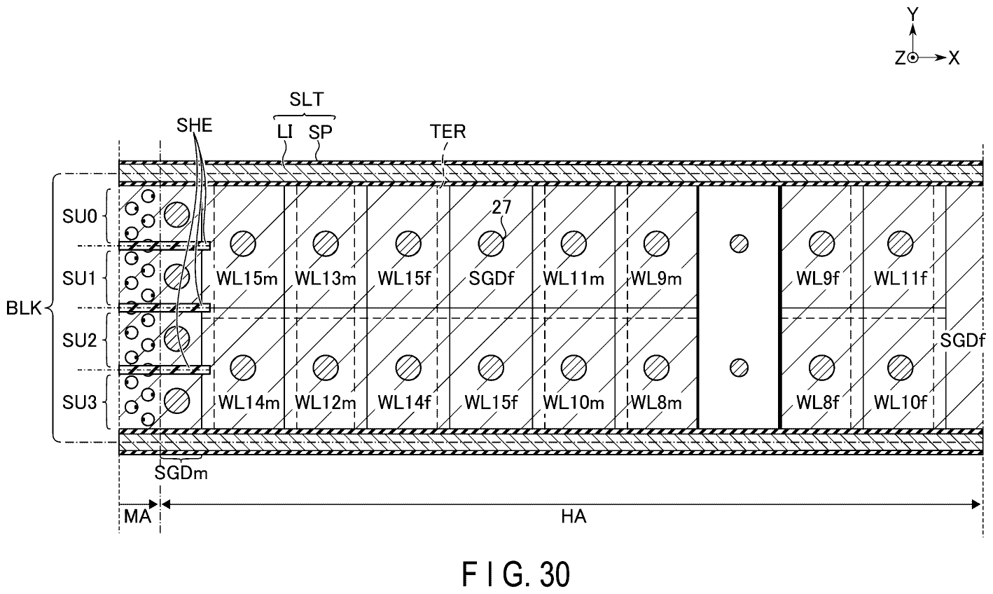

FIG. 30 is a plan view illustrating an example of a planar layout of the upper stacked interconnect U in the hookup area HA of the memory cell array 10 included in the semiconductor memory device 3 according to a fourth modification of the first embodiment. In FIG. 30, the boundary between the stacked portion LYR and the terrace portion TER in the interconnect layer corresponding to each of the word lines WL8 to WL15 is indicated by a broken line.

As illustrated in FIG. 30, the select gate line SGD and the word lines WL8 to WL15 included in the upper stacked interconnect U are provided, for example, in a step shape having two columns in the Y direction and including one level difference in the Y direction and a two-sided stepped structure formed in the X direction. Although not illustrated, the word lines WL0 to WL7 included in the lower stacked interconnect L are similarly provided in a step shape having two columns in the Y direction and including one level difference in the Y direction and a two-sided stepped structure formed in the X direction.

Each terrace portion TER of the word lines WL8 to WL14 is spaced away in the X direction from the side surface portion of the terrace portion TER of the word line WL or the selection gate line SGD provided two layers above the interconnect layer. Each terrace portion TER of the word line WL(2×i) (i is an integer of satisfying 4≤i≥7) is spaced away in the Y direction from the side surface portion of the terrace portion TER of the word line WL provided one layer above the interconnect layer. The terrace portion TER of the second portion WL15f of the word line WL15 provided side by side in the Y direction with the terrace portion of a second portion SGDf of the select gate line SGD is spaced away in the Y direction from the side surface portion of the terrace portion TER of the second portion SGDf of the select gate line SGD. Each terrace portion TER of the select gate line SGD and the word lines WL8 to WL15 functions as the CC coupling portion CCT.

Although not illustrated, each terrace portion TER of the word lines WL0 to WL5 is similarly spaced away in the X direction from the side surface portion of the terrace portion TER of the word line WL provided two layers above the interconnect layer. Each terrace portion TER of the word line WL(2×j) (j is an integer of satisfying 0≤i≤3) is spaced away in the Y direction from a side surface portion of the terrace portion TER of the word line WL provided one layer above the interconnect layer. Each terrace portion TER of the word lines WL0 to WL7 functions as the CC coupling portion CCT.

The terrace portion TER of the interconnect layer 22 corresponding to the selection gate line SGS is provided, for example, at a position aligned with the two-column stepped structure in the X direction. The terrace portion TER of the interconnect layer 22 is spaced away in the X direction from the side surface portion of each terrace portion TER of the interconnect layer 23 provided one layer above the interconnect layer 22 and the interconnect layer 23 provided two layers above the interconnect layer 22.

In the fourth modification of the first embodiment, the terrace portions TER of the respective interconnect layers are provided by arranging in two columns in the Y direction, but the number of columns in the Y direction may be three or more.

Furthermore, in the fourth modification of the first embodiment, the same configurations as the first modification, the second modification, and the third modification of the first embodiment may be applied. For example, in the fourth modification, the contacts CC1 and CC2, or the contacts CC2 and CC3 may be used instead of the contact CC. In the fourth modification, the stacked interconnect may be divided into three or more parts, and the stepped area STP may be provided in each part.

### 2. Second Embodiment

Next, a semiconductor memory device 3 according to a second embodiment will be described. The semiconductor memory device 3 according to the second embodiment is different from the semiconductor memory device 3 according to the first embodiment in that a hookup area HA of the semiconductor memory device 3 according to the second embodiment is provided in the central portion sandwiched between two memory areas MA1 and MA2. Hereinafter, description about configurations and manufacturing methods equivalent to those of the first embodiment will be omitted, and configurations and manufacturing methods different from those of the first embodiment will be mainly described.

### 2.1 Configurations

### 2.1.1 Outline of Planar Layout of Memory Cell Array

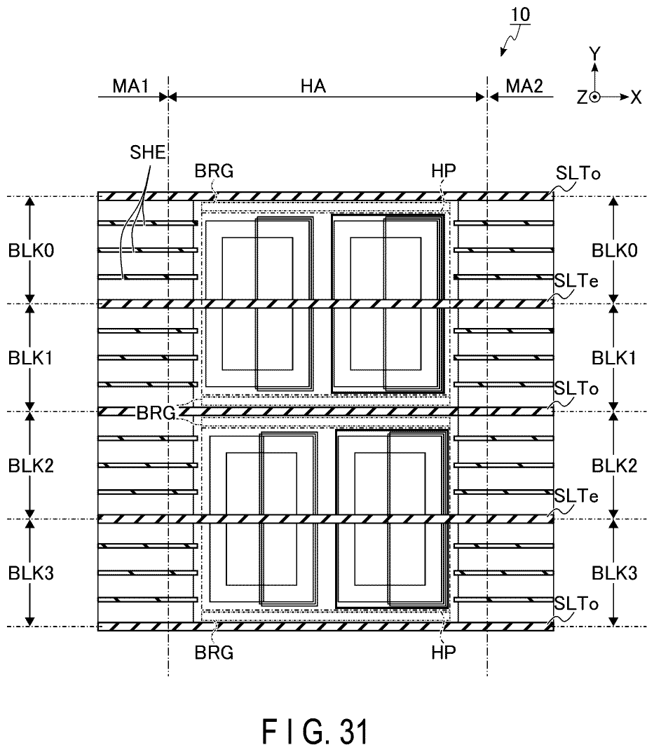

FIG. 31 is a plan view illustrating an example of a planar layout of a memory cell array 10 included in the semiconductor memory device 3 according to the second embodiment. FIG. 31 illustrates areas corresponding to four blocks BLK0 to BLK3.

As illustrated in FIG. 31, the planar layout of the memory cell array 10 is divided into, for example, the memory areas MA1 and MA2 and the hookup area HA in the X direction. The memory areas MA1 and MA2 are provided side by side so as to sandwich the hookup area HA in the X direction.

The memory cell array 10 includes a stacked interconnect, a plurality of members SLT, and a plurality of members SHE.

The plurality of members SLT cross the memory areas MA1 and MA2 and the hookup area HA in the X direction in the boundary area between the adjacent blocks BLK. Each of the areas partitioned by the member SLT corresponds to one block BLK in the memory cell array 10. Each member SLT has, for example, a structure filled with an insulator and a plate-shaped contact. Each member SLT divides the stacked interconnects adjacent to each other with the member SLT interposed therebetween.

In the present embodiment, among the plurality of members SLT arranged in the Y direction, the members SLT disposed in odd-numbered positions are referred to as “SLTo”, and the members SLT disposed in even-numbered positions are referred to as “SLTe”. In the memory cell array 10, a plurality of sets of the members SLTo and SLTe are arranged in the Y direction.

The plurality of members SHE are disposed in each of the memory areas MA1 and MA2. The plurality of members SHE corresponding to the memory area MA1 are each provided to cross the memory area MA1 and are arranged in the Y direction. The plurality of members SHE corresponding to the memory area MA2 are each provided to cross the memory area MA2 and are arranged in the Y direction.

The hookup area HA includes a plurality of hookup portions HP and a plurality of bridge portions BRG arranged in the Y direction. Each hookup portion HP is disposed for each two blocks BLK adjacent to each other in the Y direction with the member SLTe interposed therebetween. In other words, each hookup portion HP is disposed in an area sandwiched between two members SLTo sandwiching adjacent two of the blocks BLK in the hookup area HA. Each bridge portion BRG is disposed in an area sandwiched between the member SLTo and the hookup portion HP in the Y direction for each one block BLK.

### 2.1.2 Hookup Area

### (Sectional Structure)

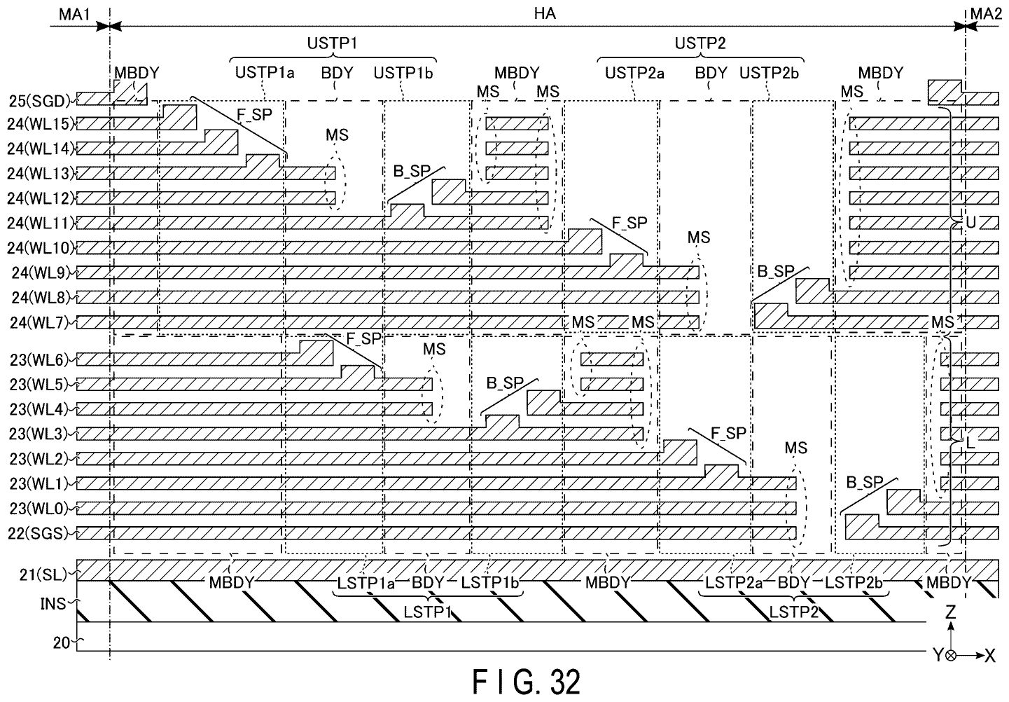

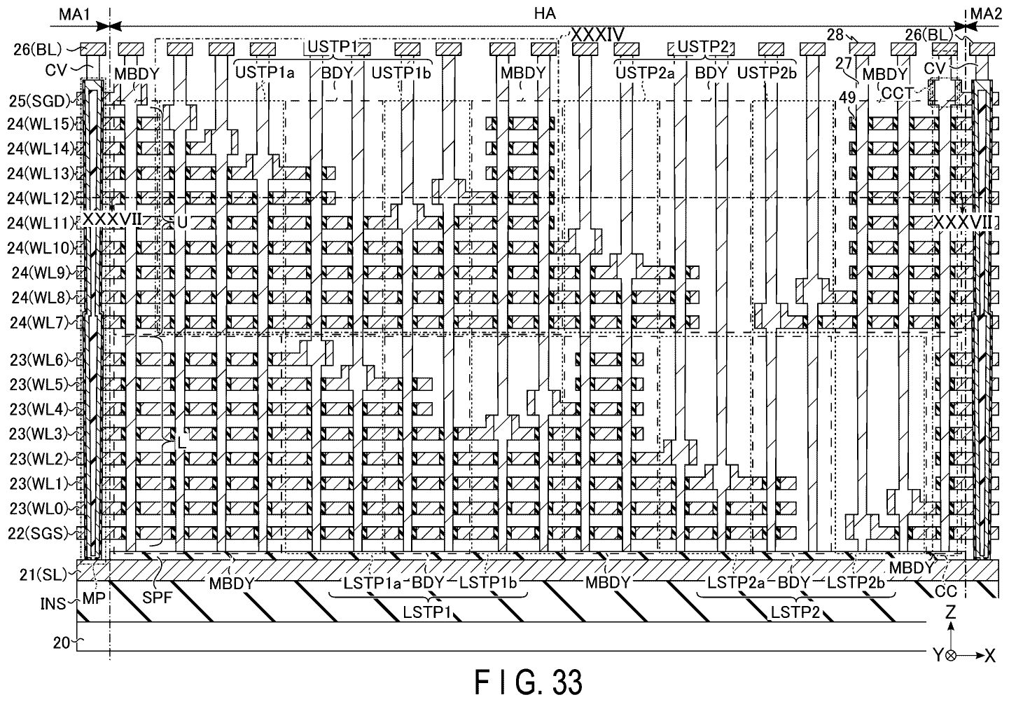

FIG. 32 is a schematic view schematically illustrating an example of a sectional structure in the hookup area HA of the memory cell array 10 included in the semiconductor memory device 3 according to the second embodiment. FIG. 33 is a sectional view illustrating an example of a sectional structure in the hookup area HA of the memory cell array 10 included in the semiconductor memory device 3 according to the second embodiment. In FIGS. 32 and 33, in addition to the hookup area HA corresponding to one block BLK, a part of the memory areas MA1 and MA2 near the hookup area HA is also illustrated. FIG. 32 illustrates each area included in the hookup area HA of the memory cell array 10. In FIG. 32, for simplification of description, a memory pillar MP, a contact CV and the interconnect layer provided above the stacked interconnect, a contact CC, and the like are omitted. FIG. 33 illustrates details of a sectional structure in the hookup area HA of the memory cell array 10.

In the second embodiment, the stacked interconnect included in the memory cell array 10 includes an upper stacked interconnect U and a lower stacked interconnect L. The lower stacked interconnect L includes an interconnect layer 22 corresponding to a select gate line SGS and a plurality of interconnect layers 23 corresponding to word lines WL0 to WL6. The upper stacked interconnect U includes interconnect layers 24 corresponding to word lines WL7 to WL15. In the second embodiment, front steps F_SP demonstrates a stepped structure in which a part of the plurality of interconnect layers is extended so as to form descending steps from the memory area MA1 side to the memory area MA2 side in the X direction. Back steps B_SP demonstrates a stepped structure in which a part of the plurality of interconnect layers is extended so as to form ascending steps from the memory area MA1 side to the memory area MA2 side in the X direction.

As illustrated in FIG. 32, the hookup area HA includes, for example, four stepped areas USTP1, USTP2, LSTP1, and LSTP2 and a boundary area MBDY. Each stepped area includes a front stepped area, a back stepped area, and a boundary area BDY provided between the front stepped area and the back stepped area.

The stepped areas USTP1 and USTP2 are provided in the upper stacked interconnect U. The stepped areas USTP1 and USTP2 are areas where the respective ends of the interconnect layers 24 are extended to form a step shape. The stepped areas LSTP1 and LSTP2 are provided in the lower stacked interconnect L. The stepped areas LSTP1 and LSTP2 are areas where the respective ends of the interconnect layers 22 and 23 are extended to form a step shape. Note that the upper stacked interconnect U and the lower stacked interconnect L may include any number of stepped areas. In the case where any of the stepped area USTP1, USTP2, LSTP1, and LSTP2 is not specified, it is hereinafter referred to as a “stepped area STP”.

The stepped area STP includes a variant-height two-sided stepped structure. The variant-height two-sided stepped structure is a two-sided stepped structure in which the interconnect layers respectively corresponding to the front steps F_SP and the back steps B_SP are different from each other. For example, the lowest stepped portion (tread) of the front steps F_SP is provided at an upper layer with respect to the highest stepped portion (tread) of the back steps B_SP. The variant-height two-sided stepped structure is formed, for example, by performing multistage processing on a portion corresponding to the back steps B_SP of the two-sided stepped structure. At this time, the multi-stacked boundary included in the variant-height two-sided stepped structure is collectively referred to as a multi-stacked portion MS. A part of the multi-stacked portion MS includes a boundary obtained by performing multistage processing a plurality of times.

Specifically, the stepped area USTP1 includes a front stepped area USTP1a, a back stepped area USTP1b, and the boundary area BDY. The front stepped area USTP1a, the boundary area BDY, and the back stepped area USTP1b are arranged in this order in the X direction. The boundary area BDY is provided between the front stepped area USTP1a and the back stepped area USTP1b in the X direction. The front stepped area USTP1a is provided on the memory area MA1 side, and the back stepped area USTP1b is provided on the memory area MA2 side. The stepped area USTP1 has, for example, a variant-height two-sided stepped structure provided in five of the interconnect layers 24 respectively corresponding to the word lines WL11 to WL15. The front steps F_SP of the front stepped area USTP1a is provided in three of the interconnect layers 24 respectively corresponding to the word lines WL13 to WL15. The back steps B_SP of the back stepped area USTP1b is provided in two of the interconnect layers 24 respectively corresponding to the word lines WL11 and WL12. The multi-stacked portion MS is provided in the boundary area BDY.

The stepped area USTP2 includes a front stepped area USTP2a, a back stepped area USTP2b, and the boundary area BDY. The front stepped area USTP2a, the boundary area BDY, and the back stepped area USTP2b are arranged in this order in the X direction. The boundary area BDY is provided between the front stepped area USTP2a and the back stepped area USTP2b in the X direction. The front stepped area USTP2a is provided on the memory area MA1 side, and the back stepped area USTP2b is provided on the memory area MA2 side. The stepped area USTP2 has, for example, a variant-height two-sided stepped structure provided in four of the interconnect layers 24 respectively corresponding to the word lines WL7 to WL10. The front steps F_SP of the front stepped area USTP2a is provided in two of the interconnect layers 24 respectively corresponding to the word lines WL9 and WL10. The back steps B_SP of the back stepped area USTP2b is provided in two of the interconnect layers 24 respectively corresponding to the word lines WL7 and WL8. The multi-stacked portion MS is provided in the boundary area BDY. In the boundary area BDY, a part of the interconnect layer 24 corresponding to the word line WL7 is removed, and the boundary area BDY includes an open portion. Note that the open portion may not be provided.

The stepped area LSTP1 includes a front stepped area LSTP1a, a back stepped area LSTP1b, and the boundary area BDY. The front stepped area LSTP1a, the boundary area BDY, and the back stepped area LSTP1b are arranged in this order in the X direction. The boundary area BDY is provided between the front stepped area LSTP1a and the back stepped area LSTP1b in the X direction. The front stepped area LSTP1a is provided on the memory area MA1 side, and the back stepped area LSTP1b is provided on the memory area MA2 side. The stepped area LSTP1 has, for example, a variant-height two-sided stepped structure provided in four of the interconnect layers 23 respectively corresponding to the word lines WL3 to WL6. The front steps F_SP of the front stepped area LSTP1a is provided in two of the interconnect layers 23 respectively corresponding to the word lines WL5 and WL6. The back steps B_SP of the back stepped area LSTP1b is provided in two of the interconnect layers 23 respectively corresponding to the word lines WL3 and WL4. The multi-stacked portion MS is provided in the boundary area BDY.

The stepped area LSTP2 includes a front stepped area LSTP2a, a back stepped area LSTP2b, and the boundary area BDY. The front stepped area LSTP2a, the boundary area BDY, and the back stepped area LSTP2b are arranged in this order in the X direction. The boundary area BDY is provided between the front stepped area LSTP2a and the back stepped area LSTP2b in the X direction. The front stepped area LSTP2a is provided on the memory area MA1 side, and the back stepped area LSTP2b is provided on the memory area MA2 side. The stepped area LSTP2 has, for example, a variant-height two-sided stepped structure provided in the interconnect layer 22 corresponding to the select gate line SGS and three of the interconnect layers 23 respectively corresponding to the word lines WL0 to WL2. The front steps F_SP of the front stepped area LSTP2a is provided in two of the interconnect layers 23 respectively corresponding to the word lines WL1 and WL2. The back steps B_SP of the back stepped area LSTP2b is provided in the interconnect layer 22 corresponding to the select gate line SGS and the interconnect layer 23 corresponding to the word lines WL0. The multi-stacked portion MS is provided in the boundary area BDY. In the boundary area BDY, a part of the interconnect layer 22 corresponding to the select gate line SGS is removed, and the boundary area BDY includes an open portion. Note that the open portion may not be provided.

The boundary areas MBDY include: an area sandwiched between the memory area MA and the stepped area STP in the X direction; and an area sandwiched between two of the stepped areas STP in the X direction. Specifically, the boundary area MBDY is provided between the memory area MA1 and the stepped area USTP1, between the stepped areas USTP1 and USTP2, and between the stepped area USTP2 and the memory area MA2. The boundary area MBDY is provided between the memory area MA1 and the stepped area LSTP1, between the stepped areas LSTP1 and LSTP2, and between the stepped area LSTP2 and the memory area MA2. The multi-stacked portion MS is provided in each boundary area MBDY.

The front stepped area and the back stepped area of each stepped area STP are disposed at positions not overlapping each other between the upper stacked interconnect U and the lower stacked interconnect L as viewed in the Z direction. The front stepped areas USTP1a and USTP2a and the back stepped areas USTP1b and USTP2b corresponding to the upper stacked interconnect U are not provided above the front stepped areas LSTP1a and LSTP2a and the back stepped areas LSTP1b and LSTP2b corresponding to the lower stacked interconnect L. In other words, the front stepped areas USTP1a and USTP2a and the back stepped areas USTP1b and USTP2b corresponding to the upper stacked interconnect U are provided above the boundary area MBDY or BDY in the lower stacked interconnect L. The front stepped areas LSTP1a and LSTP2a and the back stepped areas LSTP1b and LSTP2b corresponding to the lower stacked interconnect L are not provided below the front stepped areas USTP1a and USTP2a and the back stepped areas USTP1b and USTP2b corresponding to the upper stacked interconnect U. In other words, the front stepped areas LSTP1a and LSTP2a and the back stepped areas LSTP1b and LSTP2b corresponding to the lower stacked interconnect L are provided below the boundary area MBDY or BDY in the upper stacked interconnect U.

For example, the front stepped area USTP1a is provided above the boundary area MBDY of the lower stacked interconnect L. The front stepped area LSTP1a is provided below the boundary area BDY in the stepped area USTP1. The back stepped area USTP1b is provided above the boundary area BDY in the stepped area LSTP1. The back stepped area LSTP1b is provided below the boundary area MBDY of the upper stacked interconnect U. The front stepped area USTP2a is provided above the boundary area MBDY of the lower stacked interconnect L. The front stepped area LSTP2a is provided below the boundary area BDY in the stepped area USTP2. The back stepped area USTP2b is provided above the boundary area BDY in the stepped area LSTP2. The back stepped area LSTP2b is provided below the boundary area MBDY of the upper stacked interconnect U.

As illustrated in FIG. 33, in the hookup area HA, the memory cell array 10 further includes a plurality of the contacts CC, interconnect layers 28, and a stop member SPF.

The plurality of contacts CC are, for example, through contacts. The plurality of contacts CC are provided corresponding to the select gate lines SGS and SGD and the word lines WL0 to WL15, respectively. In the example illustrated in FIG. 33, the plurality of contacts CC correspond to the select gate line SGD, the word lines WL15, WL14, WL13, WL6, WL5, WL11, WL12, WL3, WL4, WL10, WL9, WL2, WL1, WL7, and WL8, the select gate line SGS, the word line WL0, and the select gate line SGD in order from the memory area MA1 side. Each contact CC extends in the Z direction. Each contact CC extends (passes) through an interconnect layer provided at a position where the contact CC is provided in plan view among the interconnect layers 22, 23, 24, and 25 and insulating layers (not illustrated) in the Z direction. The lower surface of each contact CC is in contact with the stop member SPF.

Each contact CC extends through one stepped area STP in the Z direction except for the contact CC corresponding to the select gate line SGD. Each of the contacts CC is coupled to any one of CC coupling portions CCT of the interconnect layers 22, 23, and 24 in the stepped areas STP through which the contact CC passes in the Z direction.

Each contact CC is provided so as to extend through any of the CC coupling portions CCT of the interconnect layer 22, 23, 24, or 25 in the Z direction, and is coupled to the interconnect layer on the side surface. Each contact CC corresponds to the interconnect layer 22, 23, 24, or 25 coupled at the CC coupling portion CCT.

Specifically, the back stepped area LSTP2b of the stepped area LSTP2 includes the CC coupling portions CCT of the interconnect layer 22 corresponding to the select gate line SGS and the interconnect layer 23 corresponding to the word line WL0. The front stepped area LSTP2a of the stepped area LSTP2 includes the CC coupling portions CCT of the two interconnect layers 23 respectively corresponding to the word lines WL1 and WL2. The back stepped area LSTP1b of the stepped area LSTP1 includes the CC coupling portions CCT of the two interconnect layers 23 respectively corresponding to the word lines WL3 and WL4. The front stepped area LSTP1a of the stepped area LSTP1 includes the CC coupling portions CCT of the two interconnect layers 23 respectively corresponding to the word lines WL5 and WL6. The back stepped area USTP2b of the stepped area USTP2 includes the CC coupling portions CCT of the two interconnect layers 24 respectively corresponding to the word lines WL7 and WL8. The front stepped area USTP2a of the stepped area USTP2 includes the CC coupling portions CCT of the two interconnect layers 24 respectively corresponding to the word lines WL9 and WL10. The back stepped area USTP1b of the stepped area USTP1 includes the CC coupling portions CCT of the two interconnect layers 24 respectively corresponding to the word lines WL11 and WL12. The front stepped area USTP1a of the stepped area USTP1 includes the CC coupling portions CCT of the three interconnect layers 24 respectively corresponding to the word lines WL13 to WL15. Different contacts CC are coupled to the respective CC coupling portions CCT. Note that the configuration of the contact CC is not limited to the above configuration as long as the contact CC is coupled to the corresponding CC coupling portion CCT of a respective one interconnect layer and is insulated from other interconnect layers.

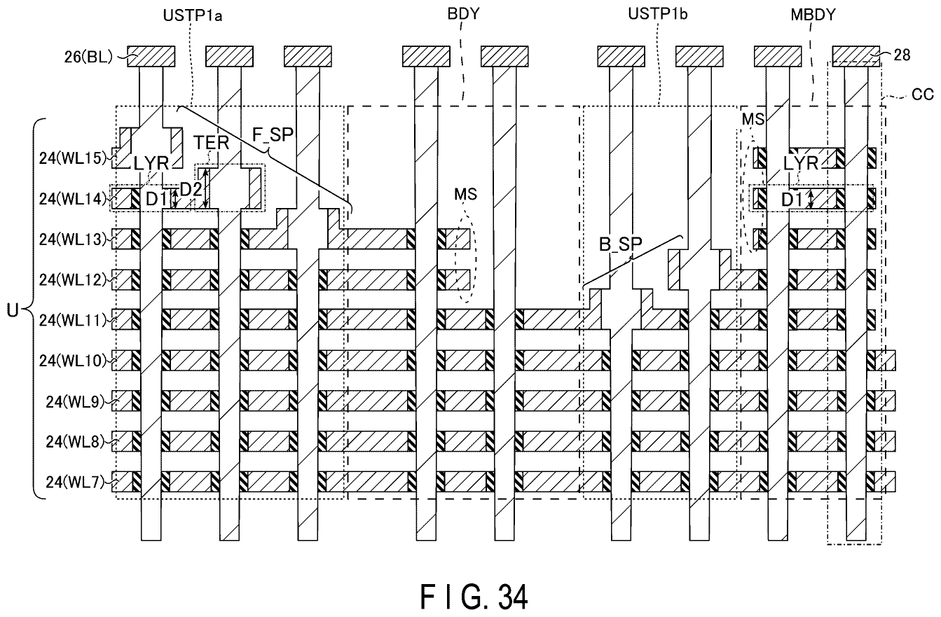

FIG. 34 is an enlarged view of area XXXIV in FIG. 33. FIG. 34 corresponds to a sectional view of the stepped area USTP1. Details of coupling between the contact CC and the CC coupling portion CCT as well as the multi-stacked portion MS will be described with reference to FIG. 34.

As illustrated in FIG. 34, the interconnect layer 24 includes a stacked portion LYR and a terrace portion TER. The same applies to the interconnect layers 22, 23, and 25 (not illustrated).

For example, the terrace portion TER is provided on a tread of any of the front steps F_SP or the back steps B_SP. The terrace portion TER is not provided in the boundary area BDY. One terrace portion TER is provided in each of the interconnect layers 22, 23, and 24. The structures of the stacked portion LYR and the terrace portion TER are similar to those of the first embodiment. The terrace portion TER functions as the CC coupling portion CCT.

The multi-stacked portion MS is provided in the boundary area MBDY or the boundary area BDY of each stepped area STP. The multi-stacked portion MS may be positioned at any portion in the boundary area MBDY or BDY as long as the formation of the contacts CC and other components is not hindered. The multi-stacked portion MS may include, for example, a slope-shaped configuration having an inclination in a downward direction.

### (Planar Layout)

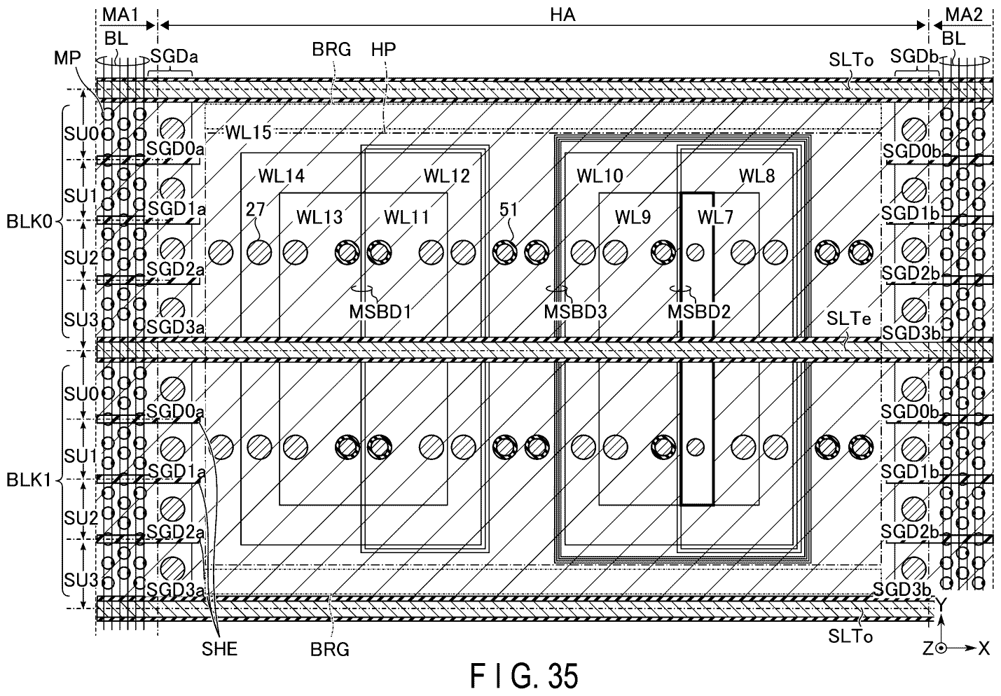

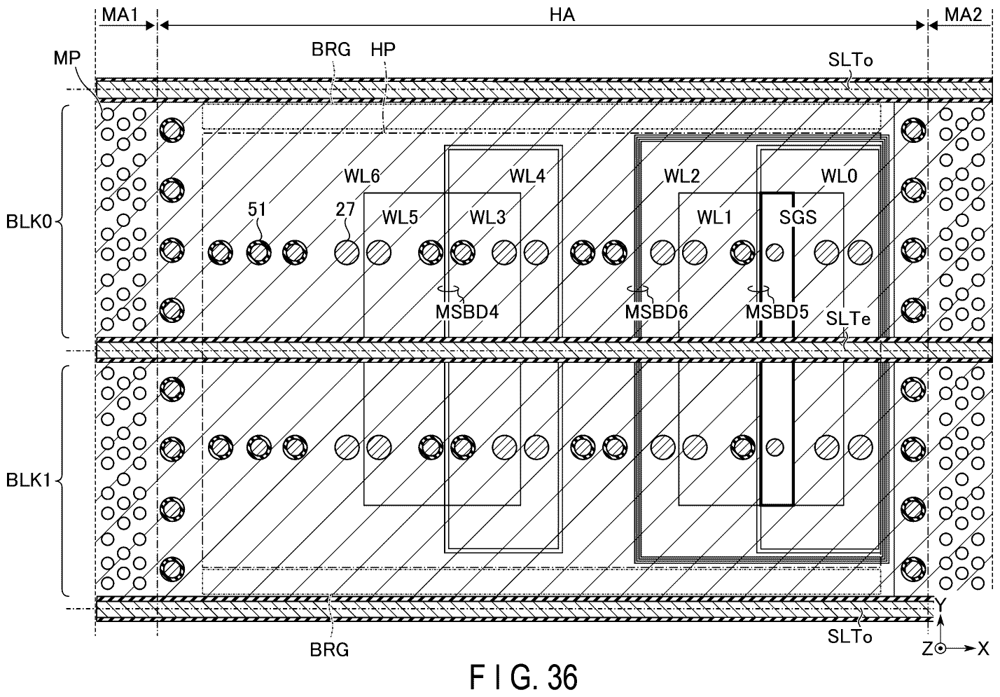

FIG. 35 is a plan view illustrating a planar layout of the upper stacked interconnect U in the hookup area HA of the memory cell array 10 included in the semiconductor memory device 3 according to the second embodiment. FIG. 36 is a plan view illustrating a planar layout of the lower stacked interconnect L in the hookup area HA of the memory cell array 10 included in the semiconductor memory device 3 according to the second embodiment. FIGS. 35 and 36 illustrate the hookup area HA and a part of the memory areas MA1 and MA2 near the hookup area HA. Note that FIGS. 35 and 36 omit the stacked portion LYR, the terrace portion TER and the like of each interconnect layer for simplification of description. In FIGS. 35 and 36, the interconnect layers 24 and 25 respectively corresponding to the word lines WL8 to WL15 and the select gate line SGD are hatched.

As illustrated in FIG. 35, the select gate line SGD includes a first portion SGDa coupled to the memory area MA1 and a second portion SGDb coupled to the memory area MA2. The first portion SGDa and the second portion SGDb of the select gate line SGD are insulated from each other. In addition, the select gate line SGD has portions divided in the Y direction by the plurality of members SHE in each of the first portion SGDa and the second portion SGDb. In each block BLK, the first portion SGDa of the select gate line SGD divided by three of the members SHE are defined as select gate lines SGD0a to SGD3a from the upper side of the page. The select gate lines SGD0a to SGD3a are insulated from each other by the plurality of members SHE. The second portion SGDb of the select gate line SGD divided by three of the members SHE are defined as select gate lines SGD0b to SGD3b from the upper side of the page. That is, in one block BLK, the select gate line SGD is divided into eight parts. One contact CC is provided for each part of the eight divided select gate lines SGD.

As illustrated in FIGS. 35 and 36, in each stepped area STP, the variant-height two-sided stepped structure is provided so as to straddle the member SLTe and has a symmetrical structure with respect to the member SLTe.

As illustrated in FIG. 35, each hookup portion HP includes multi-stacked boundaries MSBD1, MSBD2, and MSBD3 in the upper stacked interconnect U. The multi-stacked boundaries MSBD1, MSBD2, and MSBD3 are level differences provided in a rectangular shape in plan view and including end portions of a plurality of continuous interconnect layers. Note that FIG. 35 illustrates the end portions of the respective interconnect layers having a level difference side by side for clarification of the level difference. The multi-stacked boundaries MSBD1, MSBD2, and MSBD3 are formed by multistage processing. The multi-stacked boundaries MSBD1, MSBD2, and MSBD3 are formed for each one hookup portion HP.

The multi-stacked boundary MSBD1 is a level difference formed by side surfaces of two interconnect layers. The multi-stacked boundary MSBD1 is provided straddling the member SLTe so as to surround the terrace portions TER of the word lines WL11 and WL12. The multi-stacked boundary MSBD1 includes the multi-stacked portion MS.

The multi-stacked boundary MSBD2 is a level difference formed by side surfaces of two interconnect layers. The multi-stacked boundary MSBD2 is provided straddling the member SLTe so as to surround the terrace portions TER of the word lines WL7 and WL8. The multi-stacked boundary MSBD2 includes the multi-stacked portion MS.

The multi-stacked boundary MSBD3 is a level difference formed by side surfaces of four interconnect layers. The multi-stacked boundary MSBD3 is provided straddling the member SLTe so as to surround the terrace portions TER of the word lines WL7 to WL10 and the multi-stacked boundary MSBD2. The multi-stacked boundary MSBD3 includes the multi-stacked portion MS.

Note that the number of interconnect layers constituting the multi-stacked boundaries MSBD1, MSBD2, and MSBD3 can vary depending on the number of interconnect layers in which the variant-height two-sided stepped structure is provided. At this time, the number j of interconnect layers constituting the multi-stacked boundary MSBD3 is equal to or greater than a number m of interconnect layers constituting the multi-stacked boundary MSBD1 (j≥m). Note that the number j of interconnect layers constituting the multi-stacked boundary MSBD3 is preferably greater than the number m of interconnect layers constituting the multi-stacked boundary MSBD1 (j>m).

As illustrated in FIG. 36, each hookup portion HP includes multi-stacked boundaries MSBD4, MSBD5, and MSBD6 in the lower stacked interconnect L. The multi-stacked boundaries MSBD4, MSBD5, and MSBD6 are level differences provided in a rectangular shape in plan view and including end portions of a plurality of continuous interconnect layers. Note that FIG. 36 illustrates the end portions of the respective interconnect layers having a level difference side by side for clarification of the level difference. The multi-stacked boundaries MSBD4, MSBD5, and MSBD6 are formed by multistage processing. The multi-stacked boundaries MSBD4, MSBD5, and MSBD6 are formed for each one hookup portion HP.

The multi-stacked boundary MSBD4 is a level difference formed by side surfaces of two interconnect layers. The multi-stacked boundary MSBD4 is provided straddling the member SLTe so as to surround the terrace portions TER of the word lines WL3 and WL4. The multi-stacked boundary MSBD4 includes the multi-stacked portion MS.

The multi-stacked boundary MSBD5 is a level difference formed by side surfaces of two interconnect layers. The multi-stacked boundary MSBD5 is provided straddling the member SLTe so as to surround the terrace portions TER of the select gate line SGS and the word lines WL0. The multi-stacked boundary MSBD5 includes the multi-stacked portion MS.

The multi-stacked boundary MSBD6 is a level difference formed by side surfaces of four interconnect layers. The multi-stacked boundary MSBD6 is provided straddling the member SLTe so as to surround the terrace portions TER of the select gate line SGS and the word lines WL0 to WL2 and the multi-stacked boundary MSBD5. The multi-stacked boundary MSBD6 includes the multi-stacked portion MS.

Note that the number of interconnect layers constituting the multi-stacked boundaries MSBD4, MSBD5, and MSBD6 can vary depending on the number of interconnect layers in which the variant-height two-sided stepped structure is provided. At this time, the number k of interconnect layers constituting the multi-stacked boundary MSBD6 is equal to or greater than a number n of interconnect layers constituting the multi-stacked boundary MSBD4 (k>n). Note that the number k of interconnect layers constituting the multi-stacked boundary MSBD6 is preferably greater than the number n of interconnect layers constituting the multi-stacked boundary MSBD4 (k>n).

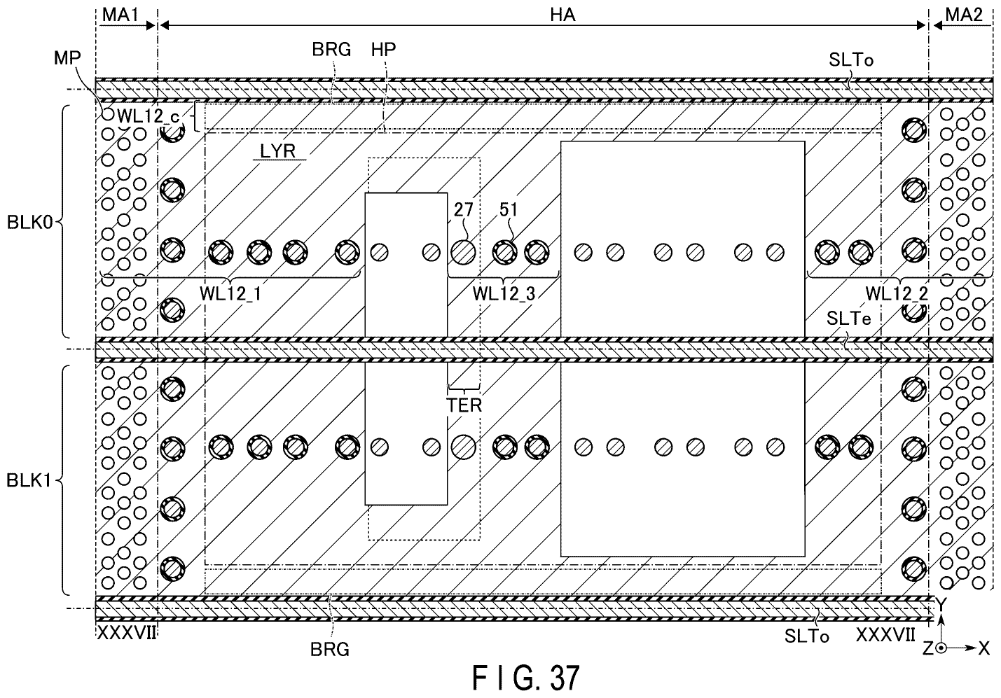

Next, as an example of the interconnect layer in which the terrace portion TER is provided in the back steps B_SP, a planar layout of the interconnect layer 24 corresponding to the word line WL12 will be described. FIG. 37 is a plan view illustrating an example of a plane taken along line XXXVII-XXXVII in FIG. 33 in the hookup area HA of the memory cell array 10 included in the semiconductor memory device 3 according to the second embodiment. FIG. 37 corresponds to the planar structure of the interconnect layer 24 corresponding to the word line WL12. FIG. 37 illustrates the hookup area HA and a part of the memory areas MA1 and MA2 near the hookup area HA. In FIG. 37, the interconnect layer 24 corresponding to the word line WL12 is hatched, and the boundary between the stacked portion LYR and the terrace portion TER is indicated by a broken line. In the second embodiment, a portion of the interconnect layer where the back steps B_SP are provided is coupled to the other portion of the interconnect layer.

As illustrated in FIG. 37, the word line WL12 includes a first portion WL12_1, a second portion WL12_2, a third portion WL12_3, and a coupling portion WL12_c. The first portion WL12_1 includes the memory area MA1. The second portion WL12_2 includes the memory area MA2. The third portion WL12_3 includes the terrace portion TER. The third portion WL12_3 is provided between the first portion WL12_1 and the second portion WL12_2 in the X direction. An insulating layer (not illustrated) is interposed between the first portion WL12_1 and the third portion WL12_3 and between the second portion WL12_2 and the third portion WL12_3. The coupling portion WL12_c is provided in the bridge portion BRG. The first portion WL12_1, the second portion WL12_2, and the third portion WL12_3 are coupled to one another via the coupling portion WL12_c provided in the bridge portion BRG. That is, the word line WL12 is not divided in the X direction between the memory areas MA1 and MA2.

In the terrace portion TER provided in the third portion WL12_3, the word line WL12 is coupled to a conductor 27 of the contact CC corresponding to the word line WL12. That is, a voltage corresponding to the word line WL12 is applied from a row decoder module 15 to the word line WL12 via the contact CC. The contact CC supplies a voltage (current) to the memory areas MA1 and MA2 via the terrace portion TER provided in the back steps B_SP. That is, the terrace portion TER provided in the back steps B_SP functions as a path through which a voltage (current) is supplied to the memory areas MA1 and MA2.

Similarly, the select gate line SGS and the other word lines WL0 to WL11 and WL13 to WL15 are coupled to both the memory areas MA1 and MA2 via coupling portions provided in the bridge portion BRG. Each of the plurality of contacts CC supplies a voltage (current) to the memory areas MA1 and MA2 via the terrace portion TER of the corresponding select gate line SGS or the corresponding one of the word lines WL0 to WL13 and WL15.

### 2.2 Manufacturing Method of Hookup Area

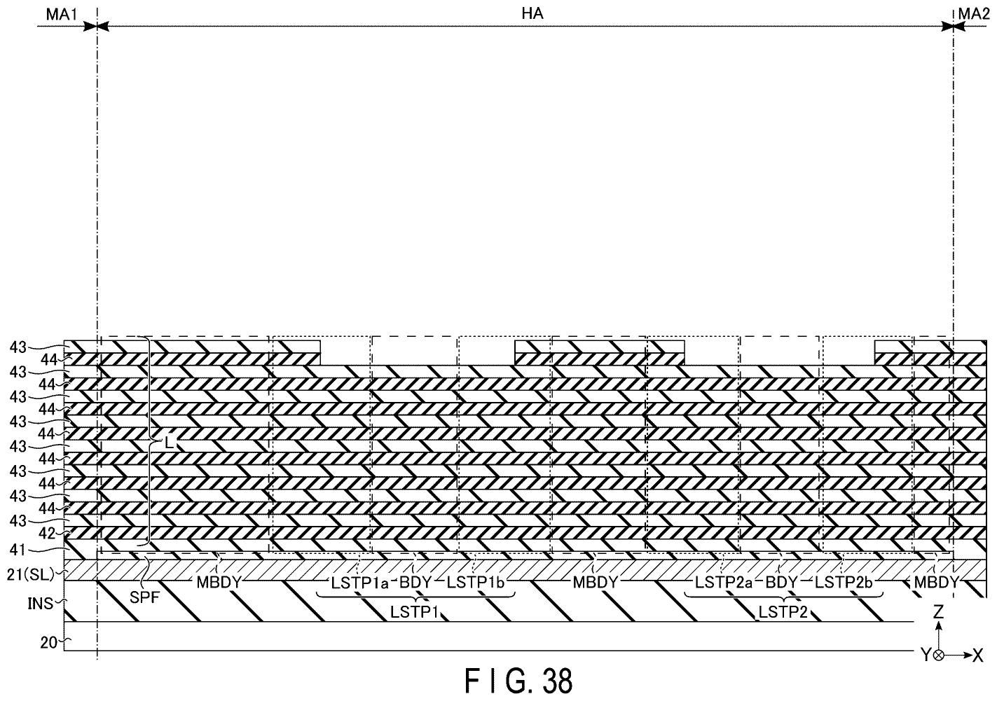

Each of FIGS. 38 to 45 illustrates an example of a sectional structure of the memory cell array 10 included in the semiconductor memory device 3 according to the second embodiment in the middle of manufacturing. The sectional structures illustrated in FIGS. 38 to 45 each present an area corresponding to FIG. 33. The manufacturing method of the hookup area HA of the memory cell array 10 included in the semiconductor memory device 3 according to the second embodiment is similar to the manufacturing method of the hookup area HA of the memory cell array 10 included in the semiconductor memory device 3 according to the first embodiment illustrated in FIG. 12. Hereinafter, portions different from those of the first embodiment will be described with reference to the flowchart illustrated in FIG. 12 and FIGS. 38 to 45 as necessary.

First, the stepped structure of the lower stacked structure illustrated in FIG. 38 is formed through the processing of S101 and S102.

Thereafter, in the present embodiment, the multistage processing is performed twice in S103.

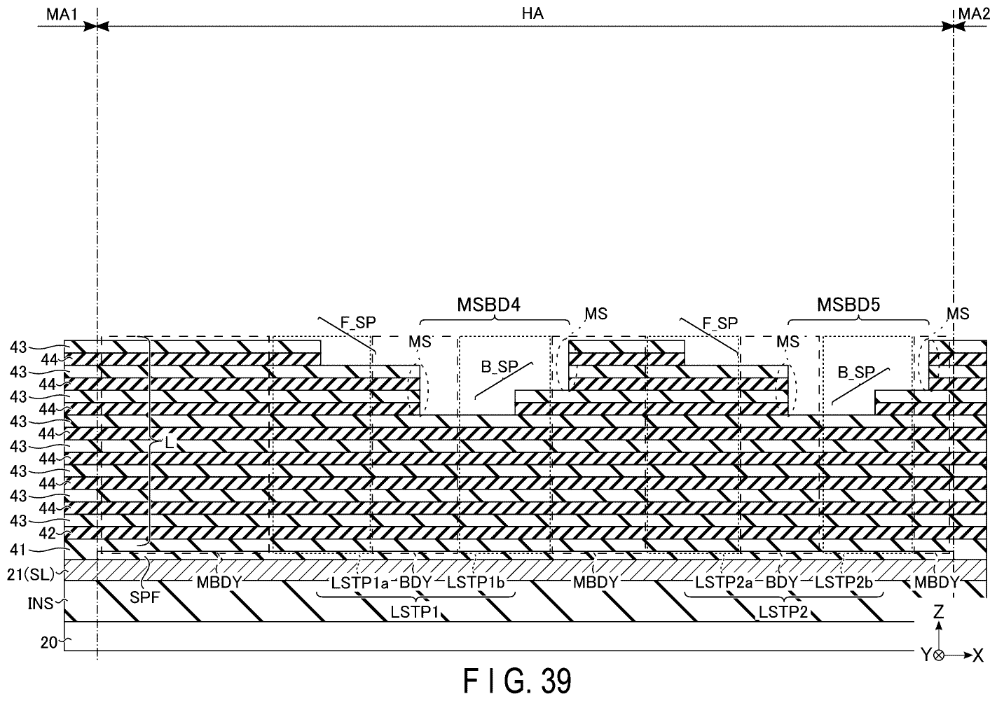

First, as illustrated in FIG. 39, the first round of multistage processing is performed on one stepped structure (back steps) of the two-sided stepped structure. Specifically, multistage processing is performed on a portion corresponding to each of the multi-stacked boundaries MSBD4 and MSBD5. By the first round of multistage processing, the back steps B_SP are processed so as to correspond to the lower interconnect layer with respect to the front steps F_SP, and the variant-height two-sided stepped structure is formed. By the first round of multistage processing, the multi-stacked portion MS is formed in each of the corresponding boundary areas MBDY and BDY.

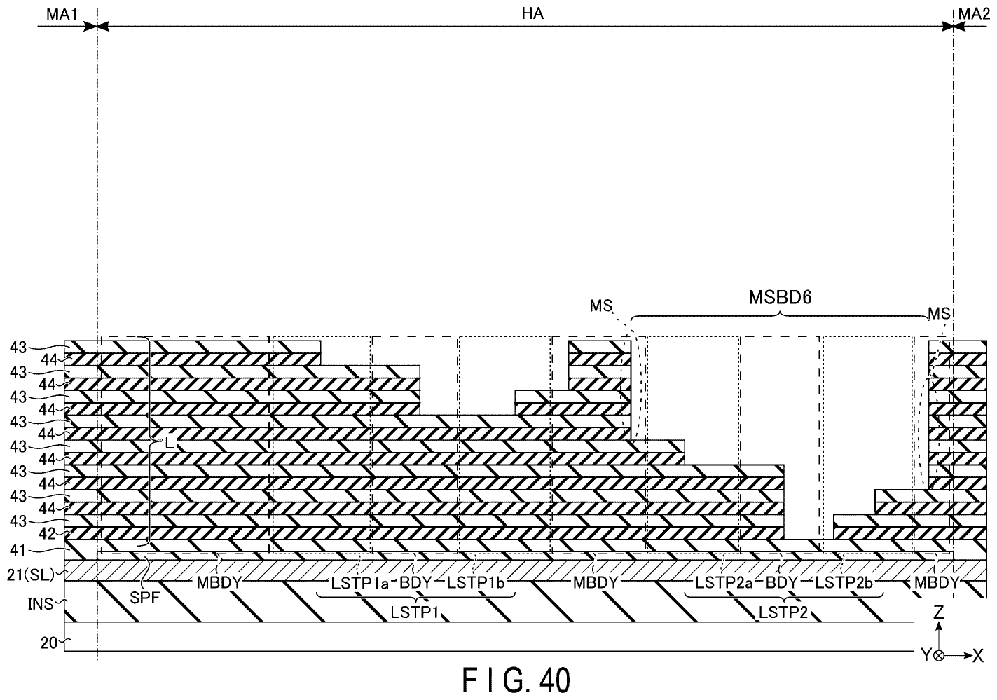

Next, the second round of multistage processing is performed on the variant-height two-sided stepped structure formed in the stepped area LSTP2. Specifically, multistage processing is performed on a portion corresponding to the multi-stacked boundary MSBD6. By the second round of multistage processing, the variant-height two-sided stepped structure formed in the stepped area LSTP2 is processed so as to correspond to the lower interconnect layer with respect to the variant-height two-sided stepped structure formed in the stepped area LSTP1. By the second round of multistage processing, the multi-stacked portion MS is formed in each of the corresponding boundary areas MBDY. Thereafter, as illustrated in FIG. 40, in the boundary area BDY included in the stepped area LSTP2, parts of a sacrificial member 42 and an insulating layer 43 provided one layer above the sacrificial member 42 are removed, and an open portion is formed.

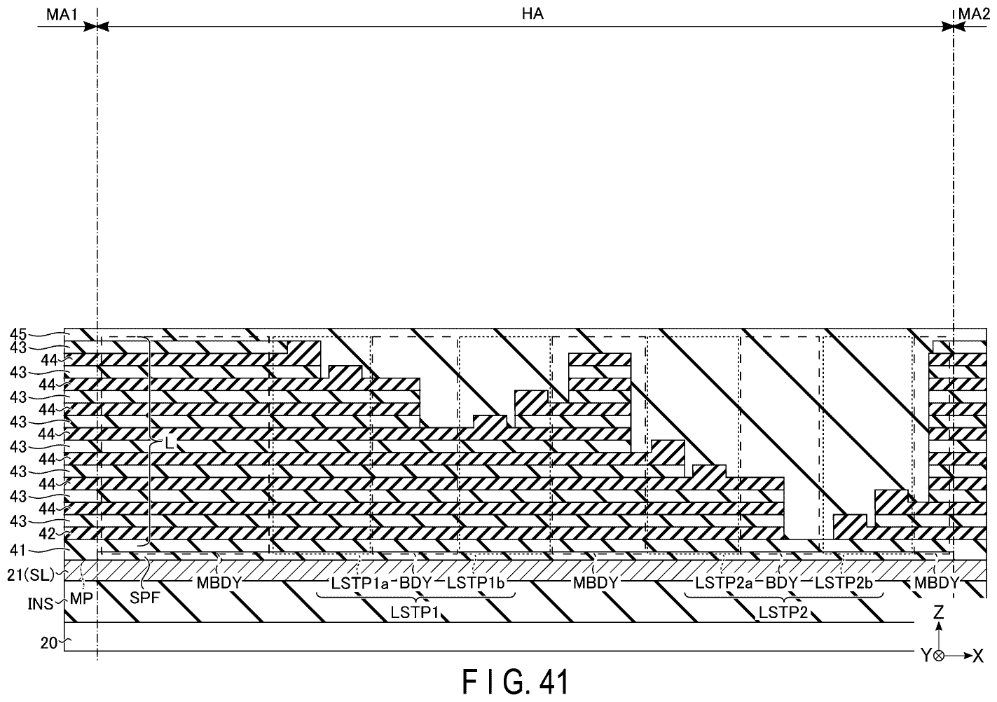

Next, as illustrated in FIG. 41, a portion corresponding to the terrace portion TER of the lower stacked structure is formed in S104.

Specifically, in the stepped areas LSTP1 and LSTP2, the insulating layer 43 exposed on the upper surface of the variant-height two-sided stepped structure is removed. Thereafter, sacrificial members respectively corresponding to the sacrificial member 42 and a sacrificial member 44 are formed at portions from which the insulating layers 43 are removed, and films of the sacrificial members are thickened. The thickness in the Z direction of the sacrificial members 42 and 44 in the film-thickened portion is equal to a second thickness D2. Thereafter, the sacrificial member formed on the uppermost insulating layer 43 is removed. Moreover, in the present embodiment, of the film-thickened portions of the sacrificial members 42 and 44, a portion provided in the boundary area BDY is removed, in addition to a portion in contact with the side surface portion of the sacrificial member 44 provided one layer above the sacrificial member 42 or 44 with the insulating layer 43 interposed therebetween.

Thereafter, the stepped areas LSTP1 and LSTP2 of the lower stacked structure are filled with an insulating layer 45.

Next, through S105 to S108, the upper interconnect structure is formed, the variant-height two-sided stepped structure is formed in the stepped areas USTP1 and USTP2, and the terrace portion TER is formed. Hereinafter, portions different from the processing in the lower interconnect structure will be described.

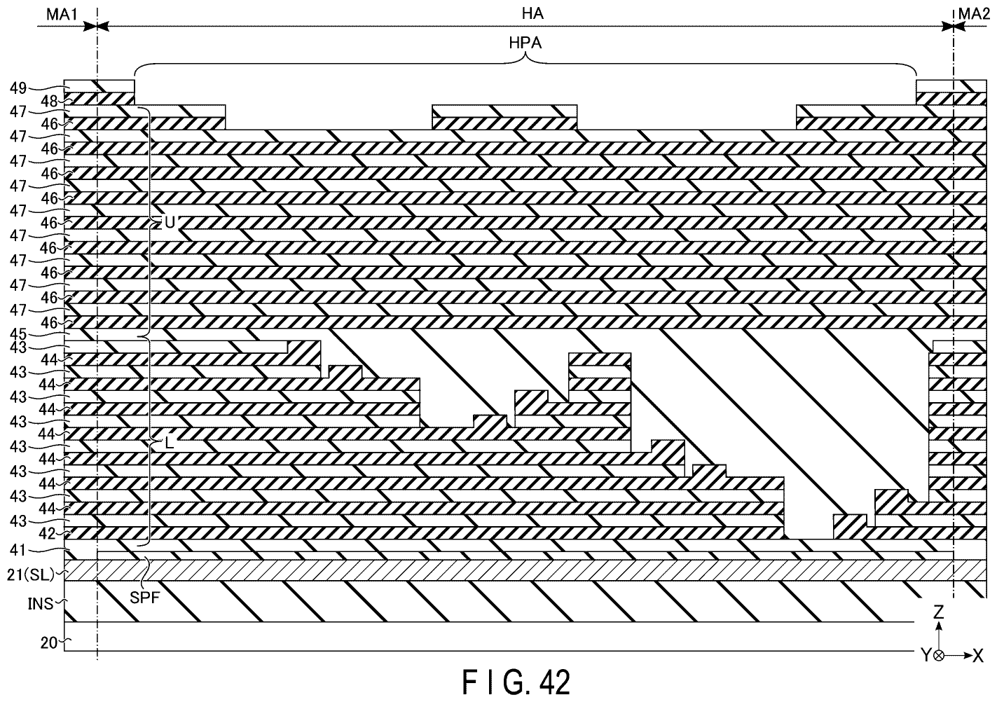

In S106, in the present embodiment, at the time of forming the stepped structure of the upper interconnect structure is formed, the two-sided stepped structure is formed in the stepped areas USTP1 and USTP2 of the hookup portion HP. Thereafter, as illustrated in FIG. 42, the stepped structure that corresponds to one stage of a sacrificial member 46 corresponding to the word line WL15 is formed. Specifically, a mask in which a process area HPA excluding a portion corresponding to the select gate line SGD in the hookup area HA is open is formed by photolithography or the like. Then, a sacrificial member 48 and an insulating layer 49 are removed by anisotropic etching using the mask. This process divides the sacrificial member 48 on the memory area MA1 side and the sacrificial member 48 on the memory area MA2 side in the X direction. Note that the two-sided stepped structure may be formed in the stepped areas USTP1 and USTP2 after the stepped structure of the sacrificial member 46 corresponding to the word line WL15 is processed.

Next, in the present embodiment, the multistage processing is performed twice in S107.

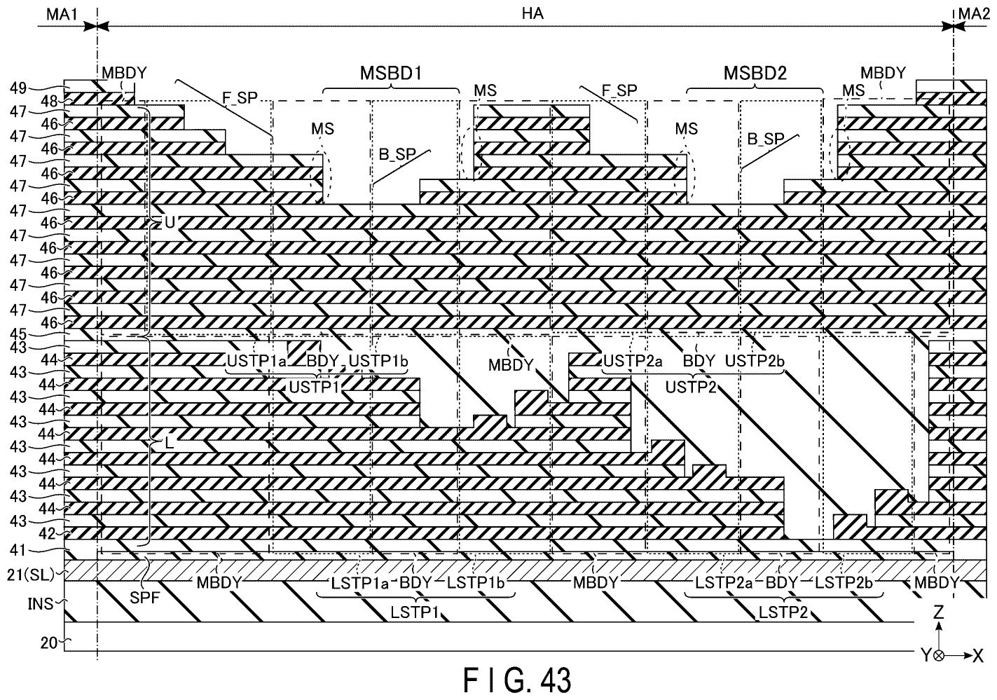

First, as illustrated in FIG. 43, the first round of multistage processing is performed on one stepped structure (back steps) of the two-sided stepped structure. Specifically, multistage processing is performed on a portion corresponding to each of the multi-stacked boundaries MSBD1 and MSBD2. By the first round of multistage processing, the back steps B_SP are processed so as to correspond to the lower interconnect layer with respect to the front steps F_SP, and the variant-height two-sided stepped structure is formed. By the first round of multistage processing, the multi-stacked portion MS is formed in each of the corresponding boundary areas MBDY and BDY.

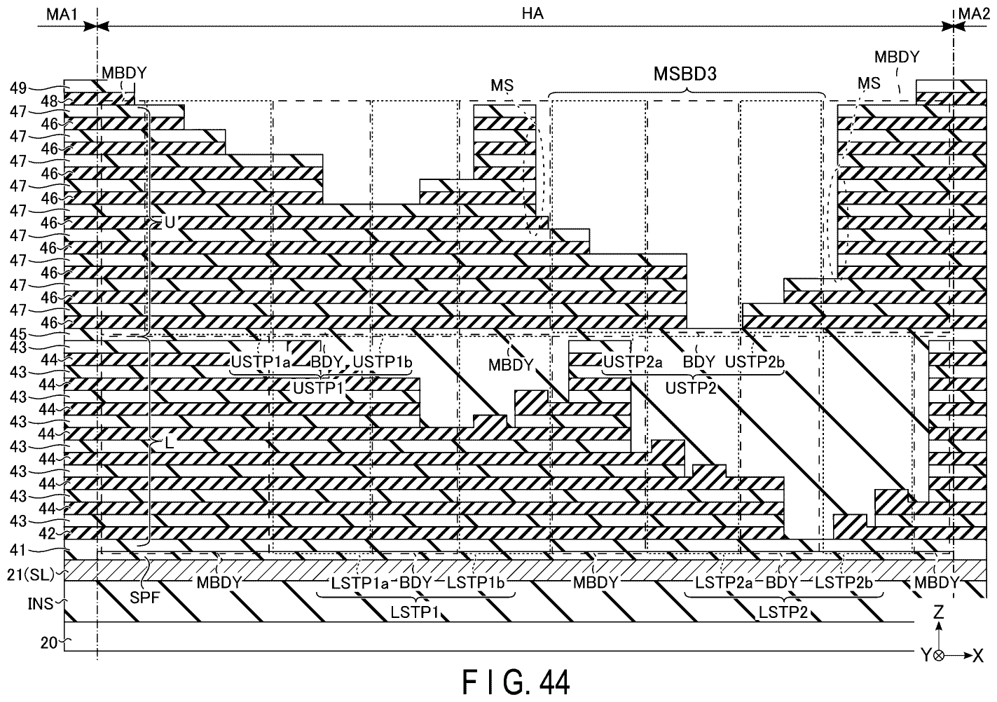

Next, the second round of multistage processing is performed on the variant-height two-sided stepped structure formed in the stepped area USTP2. Specifically, multistage processing is performed on a portion corresponding to the multi-stacked boundary MSBD3. By the second round of multistage processing, the variant-height two-sided stepped structure formed in the stepped area USTP2 is processed so as to correspond to the lower interconnect layer with respect to the variant-height two-sided stepped structure formed in the stepped area USTP1. By the second round of multistage processing, the multi-stacked portion MS is formed in each of the corresponding boundary areas MBDY. Thereafter, as illustrated in FIG. 44, in the boundary area BDY included in the stepped area USTP2, parts of the lowermost sacrificial member 46 and an insulating layer 47 provided one layer above the sacrificial member 46 are removed, and an open portion is formed.

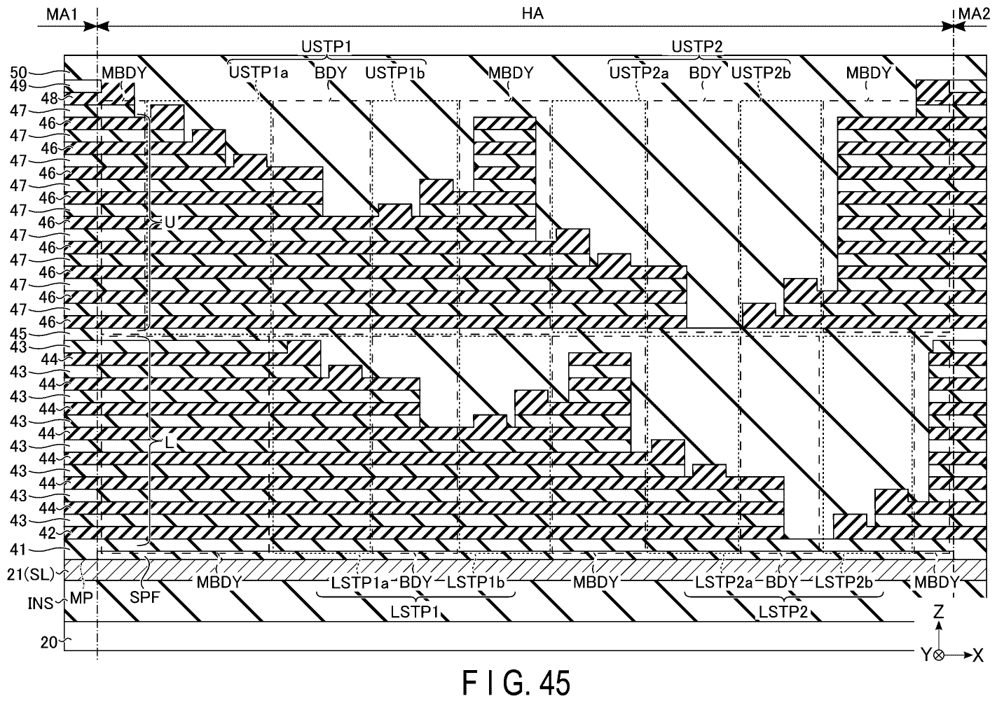

Next, as illustrated in FIG. 45, a portion corresponding to the terrace portion TER of the upper stacked structure is formed in S108.

Specifically, in the stepped areas USTP1 and USTP2, the insulating layers 47 and 49 exposed on the upper surface of the variant-height two-sided stepped structure are removed. Thereafter, sacrificial members respectively corresponding to the sacrificial members 46 and 48 are formed at portions from which the insulating layers 47 and 49 are removed, and films of the sacrificial members are thickened. The thickness in the Z direction of the sacrificial members 46 and 48 in the film-thickened portion is equal to the second thickness D2. Thereafter, the sacrificial member formed on the uppermost insulating layer 49 is removed. Moreover, in the present embodiment, of the film-thickened portions of the sacrificial members 46 and 48, portions provided in the boundary areas MBDY and BDY are removed, in addition to a portion in contact with the side surface portion of the sacrificial member 46 or 48 provided one layer above the sacrificial member 46 or 48 with the insulating layer 47 interposed therebetween.

Thereafter, the processing of S109 to S117 is performed. The processing of S109 to S117 is similar to that of the first embodiment.

The structure of the hookup area HA in the memory cell array 10 is formed by the manufacturing process described above. Note that the manufacturing process described above is merely an example, and the present invention is not limited thereto. For example, other processing may be inserted between the manufacturing steps, or some steps may be omitted or integrated with each other. In addition, each manufacturing step may be interchanged within the possible range.

### 2.3 Effects According to Second Embodiment

Similarly to the first embodiment, the second embodiment can provide a semiconductor memory device that can be manufactured with less man-hours and provide a reduced chip area.

Specifically, in the memory cell array 10 according to the second embodiment, the CC coupling portion CCT can be provided above or below the boundary areas MBDY and BDY of the stacked interconnect. This can suppress an increase in the length of the memory cell array 10 in the X direction, corresponding to the boundary areas MBDY and BDY of the stacked interconnects, and can reduce (suppress the expansion of) the chip area of the semiconductor memory device 3.

In the memory cell array 10 according to the second embodiment, the memory areas MA1 and MA2 are provided on both sides of the hookup area in the X direction. Accordingly, the memory pillars MP can be efficiently distributed and disposed in the memory areas MA1 and MA2, and thus the number of memory pillars MP per chip area can be increased. Therefore, the semiconductor memory device 3 having a large capacity can be provided while suppressing an increase in the chip area.

Furthermore, with the memory cell array 10 according to the second embodiment, the extension of the bridge portion BRG in the X direction can be suppressed. Therefore, the extension of the interconnect length of the circuit depending on the length of the bridge portion BRG can be suppressed, and an increase in the electrical resistance in the memory cell array 10 can be suppressed.

### 2.4 Modifications of Second Embodiment

The semiconductor memory device 3 according to the second embodiment described above can be variously modified. Hereinafter, differences from the second embodiment will be described as to the first modification, the second modification, the third modification, and the fourth modification of the second embodiment.

### 2.4.1 First Modification

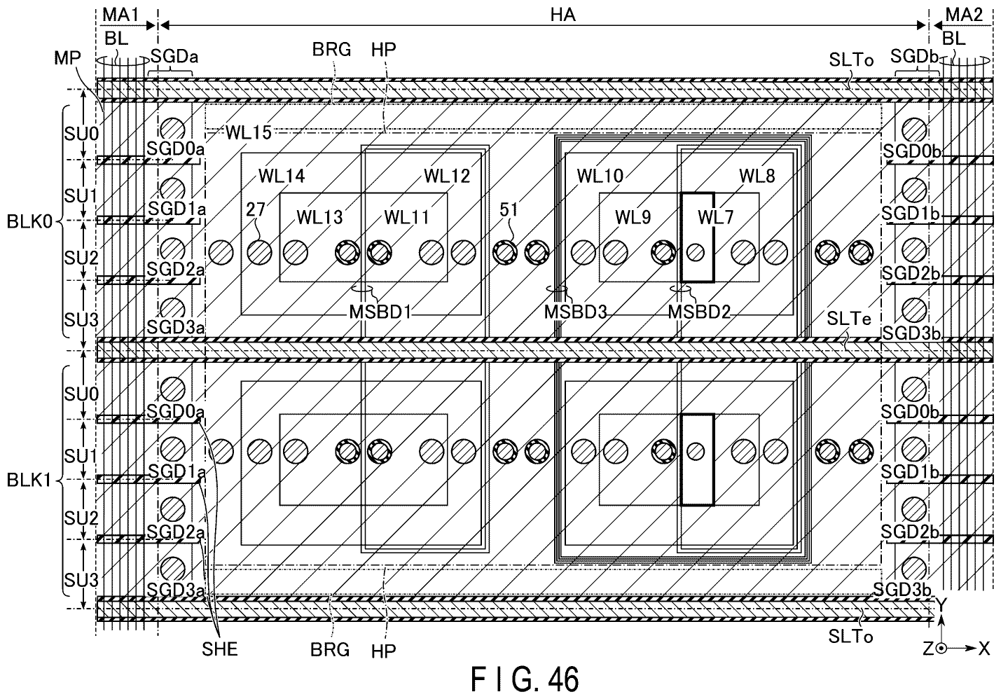

FIG. 46 is a plan view illustrating an example of a planar layout of the upper stacked interconnect U in the hookup area HA of the memory cell array 10 included in the semiconductor memory device 3 according to a first modification of the second embodiment. In FIG. 46, in addition to the hookup area HA corresponding to one block BLK, a part of the memory areas MA1 and MA2 near the hookup area HA is also illustrated. Note that, in FIG. 46, the stacked portion LYR and the terrace portion TER of each interconnect layer are omitted for simplification of description.

As illustrated in FIG. 46, the hookup portion HP of the present modification is provided for each one block BLK. The variant-height two-sided stepped structure corresponding to the CC coupling portion CCT of the word lines WL7 to WL14 in the upper stacked interconnect U is formed for each one hookup portion HP. On the other hand, similarly to the second embodiment, multistage processing is performed for each two blocks BLK adjacent to each other in the Y direction with the member SLTe interposed therebetween. The multi-stacked boundaries MSBD1, MSBD2, and MSBD3 are provided over two hookup portions HP adjacent to each other in the Y direction so as to straddle the member SLTe.

Although not illustrated, the variant-height two-sided stepped structure corresponding to the CC coupling portion CCT of the select gate line SGS and the word lines WL0 to WL6 in the lower stacked interconnect L is formed for each one hookup portion HP. On the other hand, the multi-stacked boundaries MSBD4, MSBD5, and MSBD6 are provided over two hookup portions HP adjacent to each other in the Y direction so as to straddle the member SLTe.

### 2.4.2 Second Modification

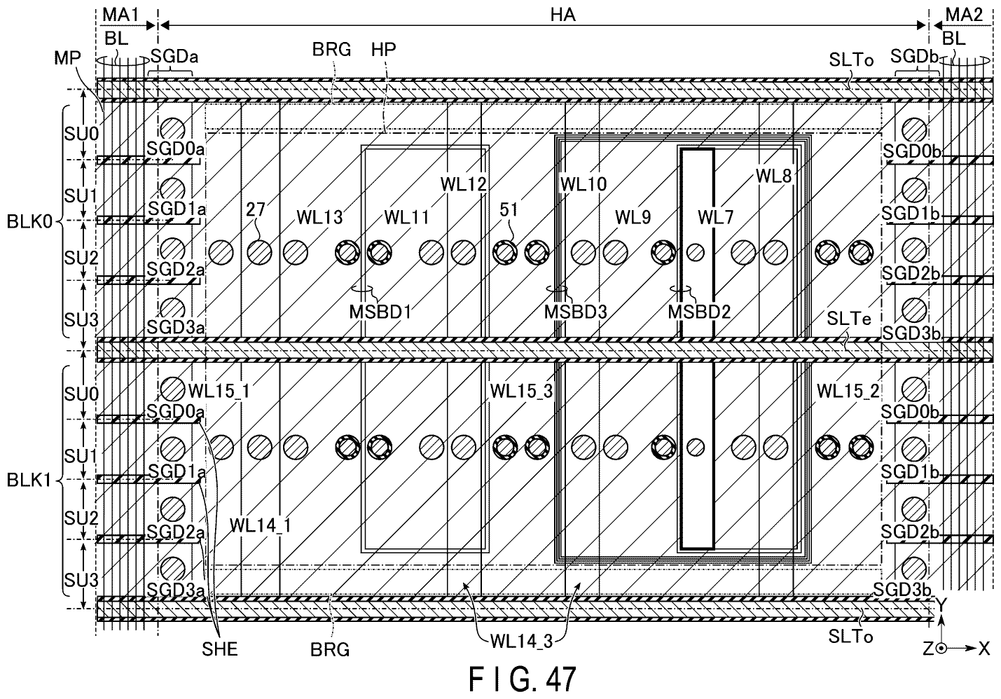

FIG. 47 is a plan view illustrating an example of a planar layout of the upper stacked interconnect U in the hookup area HA of the memory cell array 10 included in the semiconductor memory device 3 according to a second modification of the second embodiment. In FIG. 47, in addition to the hookup area HA corresponding to one block BLK, a part of the memory areas MA1 and MA2 near the hookup area HA is also illustrated. Note that, in FIG. 47, the stacked portion LYR and the terrace portion TER of each interconnect layer are omitted for simplification of description.

As illustrated in FIG. 47, in the present modification, the variant-height two-sided stepped structure corresponding to the CC coupling portion CCT of the word lines WL7 to WL14 in the upper stacked interconnect U is provided over all the blocks BLK included in the memory cell array 10. On the other hand, similarly to the second embodiment, multistage processing is performed for each two blocks BLK adjacent to each other in the Y direction with the member SLTe interposed therebetween. The multi-stacked boundaries MSBD1, MSBD2, and MSBD3 are formed for each hookup portion HP.

In the configuration described in the second modification, the word lines WL14 and WL15 are respectively divided into first portions WL14_1 and WL15_1 coupled to the memory area MA1, second portions WL14_2 (not illustrated) and WL15_2 coupled to the memory area MA2, and third portions WL14_3 and WL15_3 coupled to neither the memory area MA1 nor the memory area MA2. The first portion WL14_1 and the second portion WL14_2 are coupled to each other via an upper layer interconnect (not illustrated). Alternatively, the third portion WL14_3 may be coupled to the first portion WL14_1 and the second portion WL14_2 via an upper layer interconnect (not illustrated). The first portion WL15_1 and the second portion WL15_2 are coupled to each other via an upper layer interconnect (not illustrated). Alternatively, the third portion WL15_3 may be coupled to the first portion WL15_1 and the second portion WL15_2 via an upper layer interconnect (not illustrated).

Although not illustrated, the variant-height two-sided stepped structure corresponding to the CC coupling portion CCT of the select gate line SGS and the word lines WL0 to WL6 is provided over all the blocks BLK included in the memory cell array 10 also in the lower stacked interconnect L. On the other hand, similarly to the second embodiment, multistage processing is performed for each two blocks BLK adjacent to each other in the Y direction with the member SLTe interposed therebetween. The multi-stacked boundaries MSBD4, MSBD5, and MSBD6 are formed for each hookup portion HP.

Some interconnect layers included in the lower stacked interconnect L are divided into a first portion coupled to the memory area MA1, a second portion coupled to the memory area MA2, and a third portion coupled to neither the memory area MA1 nor the memory area MA2. In each of the divided interconnect layers, the first portion and the second portion are coupled to each other via an upper layer interconnect (not illustrated). In each of the divided interconnect layers, the third portion may be coupled to the first portion and the second portion via an upper layer interconnect (not illustrated).

### 2.4.3 Third Modification

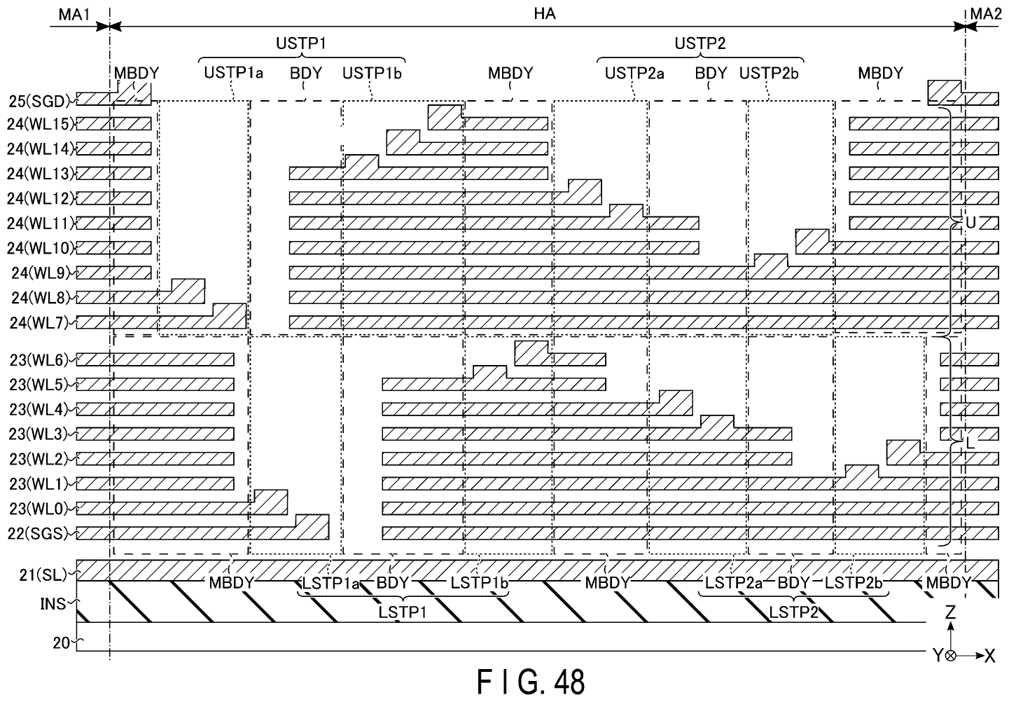

FIG. 48 is a schematic view schematically illustrating an example of a sectional structure in the hookup area HA of the memory cell array 10 included in the semiconductor memory device 3 according to a third modification of the second embodiment. In FIG. 48, for simplification of description, the memory pillar MP, the contact CV and the interconnect layer provided above the stacked interconnect, the contact CC, and the like are omitted.

As illustrated in FIG. 48, in the present modification, the two variant-height two-sided stepped structures corresponding to the CC coupling portions CCT of the word lines WL7 to WL14 in the upper stacked interconnect U are provided such that the stepped structure of a portion close to the boundary area MBDY corresponds to the CC coupling portion CCT of the upper interconnect layer. Specifically, for example, the CC coupling portions CCT of the word lines WL13 to WL15 are provided in the back stepped area USTP1b. The CC coupling portions CCT of the word lines WL11 and WL12 are provided in the front stepped area USTP2a. The CC coupling portions CCT of the word lines WL9 and WL10 are provided in the back stepped area USTP2b. The CC coupling portions CCT of the word lines WL7 and WL8 are provided in the front stepped area USTP1a.

The two variant-height two-sided stepped structures corresponding to the CC coupling portions CCT of the select gate line SGS and the word lines WL0 to WL6 in the lower stacked interconnect L are provided such that the stepped structure of a portion close to the boundary area MBDY corresponds to the CC coupling portion CCT of the upper interconnect layer. Specifically, for example, the CC coupling portions CCT of the word lines WL5 and WL6 are provided in the back stepped area LSTP1b. The CC coupling portions CCT of the word lines WL3 and WL4 are provided in the front stepped area LSTP2a. The CC coupling portions CCT of the word lines WL1 and WL2 are provided in the back stepped area LSTP2b. The CC coupling portions CCT of the select gate line SGS and the word line WL0 are provided in the front stepped area LSTP1a.

### 2.4.4 Fourth Modification

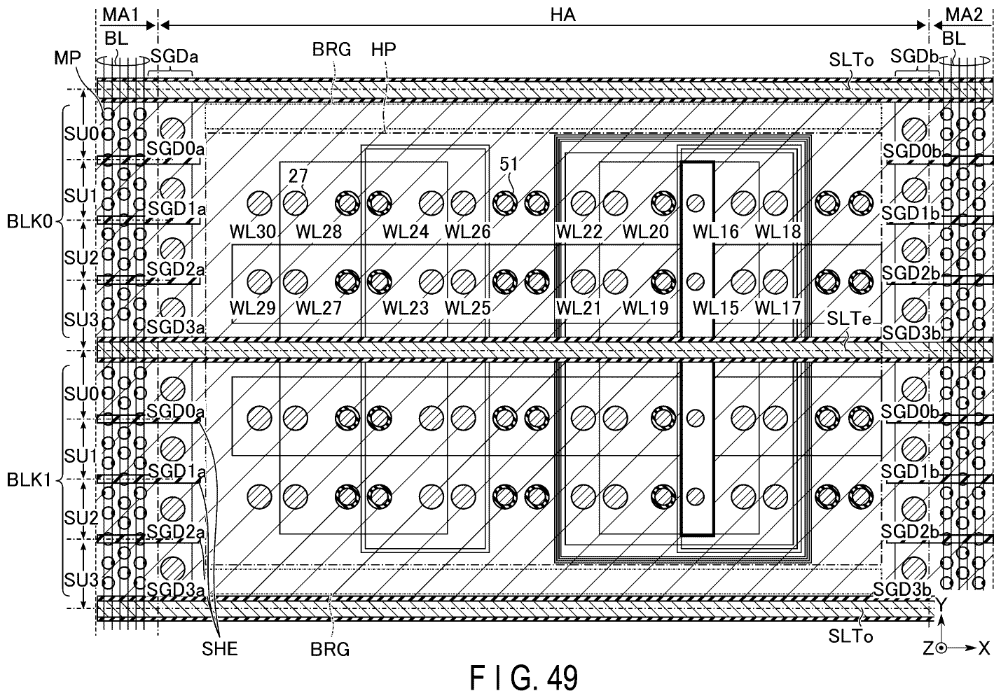

FIG. 49 is a plan view illustrating an example of a planar layout of the upper stacked interconnect U in the hookup area HA of the memory cell array 10 included in the semiconductor memory device 3 according to a fourth modification of the second embodiment. In FIG. 49, in addition to the hookup area HA corresponding to one block BLK, a part of the memory areas MA1 and MA2 near the hookup area HA is also illustrated. Note that, in FIG. 49, the stacked portion LYR and the terrace portion TER of each interconnect layer are omitted for simplification of description.

FIG. 49 illustrates a case where the memory cell array 10 according to the fourth modification of the second embodiment includes 31 word lines WL. In this case, the lower stacked interconnect L includes the select gate line SGS and the word lines WL0 to WL14, and the upper stacked interconnect U includes word lines WL15 to WL30.

As illustrated in FIG. 49, the word lines WL15 to WL30 included in the upper stacked interconnect U are provided, for example, in a step shape having two columns in the Y direction and including one level difference in the Y direction and a two-sided stepped structure formed in the X direction. Although not illustrated, the select gate line SGS and the word lines WL0 to WL14 included in the lower stacked interconnect L are similarly provided in a step shape having two columns in the Y direction and including one level difference in the Y direction and a two-sided stepped structure formed in the X direction.

In the fourth modification of the second embodiment, the terrace portions TER of the respective interconnect layers are provided by arranging in two columns in the Y direction, but the number of columns in the Y direction may be three or more.

### 2.4.5 Other Modifications

Although the first to fourth modifications of the second embodiment have been described above, various other modifications are assumed.

For example, the shape of the contact CC may be changed similarly to the first modification and the second modification of the first embodiment. The difference in the structure of the memory cell array 10 at this time follows the first modification and the second modification of the first embodiment.

Similarly to the third modification of the first embodiment, the stacked interconnect may be divided into three or more parts, and the stepped area STP may be provided in each part. The difference in the structure of the memory cell array 10 at this time follows the third modification of the first embodiment.

### 3. Others

In the first and second embodiments and the modifications thereof described above, an example in which four or six stepped areas STP are provided is described, but the number of stepped areas STP is not limited thereto. For example, seven or more of the stepped area STP may be provided.

In the first embodiment and the second embodiment described above, two stepped areas STP are provided in each of the upper stacked interconnect U and the lower stacked interconnect L, but the number of stepped areas provided in each may be three or more.

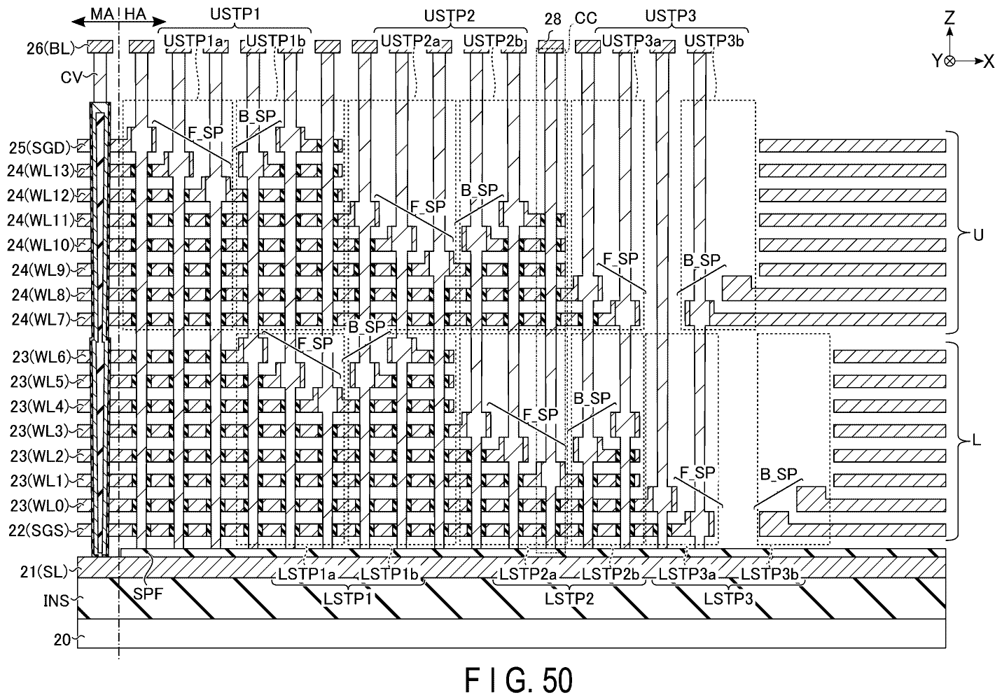

FIG. 50 is a sectional view illustrating an example of a sectional structure in the hookup area of the memory cell array included in the semiconductor memory device according to a fifth modification of the first embodiment. In the present modification, three stepped areas USTP1, USTP2, and USTP3 are provided in the upper stacked interconnect U, and three stepped areas LSTP1, LSTP2, and LSTP3 are provided in the lower stacked interconnect L. The front stepped area LSTP1a of the stepped area LSTP1 is provided at a position overlapping the back stepped area USTP1b of the stepped area USTP1 in the Z direction. The front stepped area USTP2a of the stepped area USTP2 is provided at a position overlapping the back stepped area LSTP1b of the stepped area LSTP1 in the Z direction. The front stepped area LSTP2a of the stepped area LSTP2 is provided at a position overlapping the back stepped area USTP2b of the stepped area USTP2 in the Z direction. A front stepped area USTP3a of the stepped area USTP3 is provided at a position overlapping the back stepped area LSTP2b of the stepped area LSTP2 in the Z direction.

FIG. 50 illustrates a case where the memory cell array 10 according to the fifth modification of the first embodiment includes 14 word lines WL. In this case, the lower stacked interconnect L includes the select gate line SGS and the word lines WL0 to WL6, and the upper stacked interconnect U includes word lines WL7 to WL13 and the select gate line SGD.

Each stepped area STP includes a two-sided stepped structure, and the terrace portions TER of the respective interconnect layers 22, 23, 24, and 25 are provided on treads of each two-sided stepped structure. The front steps F_SP are formed in each of the front stepped areas USTP1a, USTP2a, USTP3a, LSTP1a, and LSTP2a, and a front stepped area LSTP3a. The back steps B_SP are formed in each of the back stepped areas USTP1b, USTP2b, LSTP1b, and LSTP2b, and back stepped areas USTP3b and LSTP3b. In each stepped area STP, each terrace portion TER of the interconnect layers 22, 23, 24, and 25, excluding the terrace portions TER of the interconnect layers 22 and 23 formed in the back steps B_SP of the back stepped area LSTP3b and the interconnect layer 24 corresponding to word line WL8 formed in the back steps B_SP of the back stepped area USTP3b, functions as the CC coupling portion CCT.

The plurality of contacts CC are provided one by one in accordance with the terrace portions TER provided in the front steps F_SP, and each contact CC passes through the terrace portion TER in the Z direction for ensuring electrical coupling. Each of some of the plurality of contacts CC further passes through, in the Z direction, the terrace portion TER provided in the back steps B_SP at a position overlapping the front steps F_SP in the Z direction for ensuring electrical coupling. Specifically, in the back stepped area USTP1b, two of the contacts CC each coupled to the CC coupling portion CCT are also each coupled to the CC coupling portion CCT formed in the front stepped area LSTP1a on the lower side. In the back stepped area LSTP1b, two of the contacts CC each coupled to the CC coupling portion CCT are also each coupled to the CC coupling portion CCT formed in the front stepped area USTP2a on the upper side. In the back stepped area USTP2b, two of the contacts CC each coupled to the CC coupling portion CCT are also each coupled to the CC coupling portion CCT formed in the front stepped area LSTP2a on the lower side. In the back stepped area LSTP2b, two of the contacts CC each coupled to the CC coupling portion CCT are also each coupled to the CC coupling portion CCT formed in the front stepped area USTP3a on the upper side. In the back stepped area USTP3b, one of the contacts CC coupled to the CC coupling portion CCT is also coupled to the CC coupling portion CCT formed in the front stepped area LSTP3a on the lower side.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first interconnect layer;
a plurality of second interconnect layers that are provided above the first interconnect layer and apart from each other in a first direction,
wherein the second interconnect layers are provided over a first area and a second area that are arranged in a second direction intersecting the first direction as viewed in the first direction, and
each of the second interconnect layers includes a plurality of first terrace portions that are provided not overlapping any of the second interconnect layers at a respective upper layer in the first direction in the first area;
a plurality of third interconnect layers that are provided above the second interconnect layers and apart from each other in the first direction,
wherein the third interconnect layers are provided over the first area and the second area,
each of the third interconnect layers includes a plurality of second terrace portions that are provided not overlapping any of the third interconnect layers at a respective upper layer in the first direction in the first area and a part of which is provided overlapping the first terrace portions in the first direction,
each of the second terrace portions includes
a plurality of third terrace portions that are provided descending in a direction away from the second area in the second direction in a first stepped area, and
a plurality of fourth terrace portions that are provided ascending in the direction away from the second area in the second direction in a second stepped area, and
each of the third terrace portions and each of the fourth terrace portions that are provided at a same interconnect layer of the third interconnect layers are electrically insulated from each other;
a first memory pillar that extends in the first direction in the second area, includes an end in contact with the first interconnect layer, and passes through the second interconnect layers and the third interconnect layers; and
a first contact that extends in the first direction in the first area, passes through one of the fourth terrace portions, and is electrically coupled to one of the first terrace portions,
wherein each of the third terrace portions and the fourth terrace portions is thicker in the first direction than a portion of the third interconnect layers where the third terrace portions or the fourth terrace portions are not provided.

2. The semiconductor memory device according to claim 1, wherein
the first terrace portions each include
a plurality of fifth terrace portions that are provided descending in the direction away from the second area in the second direction in a third stepped area, and
a plurality of sixth terrace portions that are provided ascending in the direction away from the second area in the second direction in a fourth stepped area,
each of the fifth terrace portions and each of the sixth terrace portions that are provided at a same interconnect layer among the plurality of second interconnect layers are electrically insulated from each other,
the semiconductor memory device further comprises
a second contact that extends in the first direction in the first area, passes through one of the sixth terrace portions, and is electrically coupled to one of the second terrace portions, and
each of the fifth terrace portions and the sixth terrace portions is thicker in the first direction than a portion of the second interconnect layers where the fifth terrace portions or the sixth terrace portions are not provided.

3. The semiconductor memory device according to claim 2, wherein
the first stepped area and the second stepped area are arranged in this order in the direction away from the second area in the second direction, and
the third stepped area and the fourth stepped area are arranged in this order in the direction away from the second area in the second direction.

4. The semiconductor memory device according to claim 2, wherein
the first stepped area and the fourth stepped area are provided at positions overlapping each other in the first direction.

5. The semiconductor memory device according to claim 2, wherein
the second stepped area and the third stepped area are provided at positions overlapping each other in the first direction.

6. The semiconductor memory device according to claim 2, wherein
each of the third terrace portions and the fourth terrace portions has a length greater in the second direction than a length of the first contact in the second direction, and
each of the fifth terrace portions and the sixth terrace portions has a length greater in the second direction than a length of the second contact in the second direction.

7. The semiconductor memory device according to claim 4, wherein
the second contact is further electrically coupled to the one of the sixth terrace portions at a position where the first stepped area and the fourth stepped area overlap each other in the first direction.

8. The semiconductor memory device according to claim 5, wherein
the first contact is further electrically coupled to the one of the fourth terrace portions at a position where the second stepped area and the third stepped area overlap each other in the first direction.

9. The semiconductor memory device according to claim 1, further comprising
a third contact that extends in the first direction in the first area, is in contact with an upper surface of one of the third terrace portions and electrically coupled to the one of the third terrace portions, and does not pass through the second interconnect layers or the third interconnect layers in the first direction.

10. The semiconductor memory device according to claim 9, wherein
the third interconnect layers include a hole at a position overlapping the first contact in the first direction in the first area, and
the first contact passes through the third interconnect layers in the first direction through the hole.

11. The semiconductor memory device according to claim 2, wherein
the fifth terrace portion is provided by setting a fourth interconnect layer included in the second interconnect layers as a lowermost stage,
the sixth terrace portion is provided by setting an interconnect layer provided at an upper layer with respect to the fourth interconnect layer as a lowermost stage, and
a portion provided in the third stepped area and a portion provided in the fourth stepped area of the fourth interconnect layer are in contact with each other in the second direction.

12. The semiconductor memory device according to claim 11, further comprising
a fifth contact that extends in the first direction in the first area, passes through the third interconnect layers, and is electrically coupled to the fifth terrace portion of the fourth interconnect layer.

13. A semiconductor memory device comprising:
a first interconnect layer,
a plurality of second interconnect layers that are provided above the first interconnect layer and apart from each other in a first direction,
wherein the second interconnect layers are provided over a first area, a second area, and a third area that are arranged in a second direction intersecting the first direction as viewed in the first direction,
the first area includes a fourth area and a fifth area that are provided being sandwiched between the second area and the third area in the second direction and are arranged in a third direction intersecting the first direction and the second direction, and
each of the second interconnect layers includes a plurality of first terrace portions that are provided not overlapping any of the second interconnect layers at a respective upper layer in the first direction in a first stepped area in the fourth area;
a plurality of third interconnect layers that are provided above the second interconnect layers and apart from each other in the first direction and include a second stepped area including a portion overlapping the first stepped area in the first direction in the fourth area,
wherein the third interconnect layers are provided over the first area, the second area, and the third area,
the second stepped area includes
a first sub-stepped area,
a second sub-stepped area, and
a first boundary area that is provided being sandwiched between the first sub-stepped area and the second sub-stepped area in the second direction,
each of the third interconnect layers includes a plurality of second terrace portions that are provided not overlapping any of the third interconnect layers at a respective upper layer in the first direction in the second stepped area,
the second terrace portions include
a plurality of third terrace portions that are provided descending in a direction away from the second area in the second direction in the first sub-stepped area, and
a plurality of fourth terrace portions that are provided ascending in the direction away from the second area in the second direction in the second sub-stepped area, and
the third interconnect layers include n interconnect layers continuously stacked in the first direction and including a first end surface intersecting the second direction in the first boundary area, where n is an integer of two or more;
a first memory pillar and a second memory pillar, each of which extends in the first direction in each of the second area and the third area, includes an end in contact with the first interconnect layer, and passes through the second interconnect layers and the third interconnect layers; and
a first contact that extends in the first direction at a position where the first stepped area and the first boundary area overlap each other in the fourth area, passes through the third interconnect layers, and is electrically coupled to one of the first terrace portions.

14. The semiconductor memory device according to claim 13, wherein
the first stepped area includes
a third sub-stepped area,
a fourth sub-stepped area, and
a second boundary area that is provided being sandwiched between the third sub-stepped area and the fourth sub-stepped area in the second direction,
the first terrace portions include
a plurality of fifth terrace portions that are provided descending in the direction away from the second area in the second direction in the third sub-stepped area, and
a plurality of sixth terrace portions that are provided ascending in the direction away from the second area in the second direction in the fourth sub-stepped area,
the second interconnect layers include m interconnect layers continuously stacked in the first direction and including a second end surface intersecting the second direction in the second boundary area, where m is an integer of two or more, and
the semiconductor memory device further comprises
a second contact that extends in the first direction at a position where the second boundary area and the second stepped area overlap each other in the fourth area, passes through the second interconnect layers, and is electrically coupled to one of the second terrace portions.

15. The semiconductor memory device according to claim 14, wherein
The third terrace portions and the fourth terrace portions are arranged in this order in the direction away from the second area in the second direction, and
the fifth terrace portions and the sixth terrace portions are arranged in this order in the direction away from the second area in the second direction.

16. The semiconductor memory device according to claim 14, wherein
the second sub-stepped area and the second boundary area are provided at positions overlapping each other in the first direction,
the third sub-stepped area and the first boundary area are provided at positions overlapping each other in the first direction,
the first contact is electrically coupled to one of the fifth terrace portions, and
the second contact is electrically coupled to one of the fourth terrace portions.

17. The semiconductor memory device according to claim 14, wherein
the first sub-stepped area and the second boundary area are provided at positions overlapping each other in the first direction,
the fourth sub-stepped area and the first boundary area are provided at positions overlapping each other in the first direction,
the first contact is electrically coupled to one of the sixth terrace portions, and
the second contact is electrically coupled to one of the third terrace portions.

18. The semiconductor memory device according to claim 14, wherein
each of the third terrace portions and the fourth terrace portions is thicker in the first direction than a portion of the third interconnect layers where the third terrace portions or the fourth terrace portions are not provided, and
each of the fifth terrace portions and the sixth terrace portions is thicker in the first direction than a portion of the second interconnect layers where the fifth terrace portions or the sixth terrace portions are not provided.

19. The semiconductor memory device according to claim 13, wherein
the third interconnect layers further include
a third stepped area that is provided on a side in the direction away from the second area with respect to the second stepped area in the fourth area, and
a third boundary area that is provided being sandwiched between the second stepped area and the third stepped area in the second direction,
each of the third interconnect layers includes a plurality of seventh terrace portions that are provided not overlapping any of the third interconnect layers at a respective upper layer in the first direction in the third stepped area,
the third interconnect layers include k interconnect layers continuously stacked in the first direction and including a third end surface intersecting the second direction in the third boundary area, where k is an integer satisfying k>n, and
the semiconductor memory device further comprises
a third contact that extends in the first direction at a position where the first stepped area and the third boundary area overlap each other in the fourth area, passes through the third interconnect layers, and is electrically coupled to another one of the first terrace portions.

20. The semiconductor memory device according to claim 14, wherein
the second interconnect layers further include
a fourth stepped area that is provided on a side in a direction away from the third area with respect to the first stepped area in the fourth area, and
a fourth boundary area that is provided being sandwiched between the first stepped area and the fourth stepped area in the second direction,
each of the second interconnect layers includes a plurality of eighth terrace portions that are provided not overlapping any of the second interconnect layers at a respective upper layer in the first direction in the fourth stepped area,
the second interconnect layers include j interconnect layers continuously stacked in the first direction and including a fourth end surface intersecting the second direction in the fourth boundary area, where j is an integer satisfying j>m, and
the semiconductor memory device further comprises
a fourth contact that extends in the first direction at a position where the second stepped area and the fourth boundary area overlap each other in the fourth area, passes through the second interconnect layers, and is electrically coupled to another one of the second terrace portions.
